(19) United States
(12) Patent Application Publication
(10) Pub. No.: US 2014/0183414 A1
(43) Pub. Date: Jul. 3, 2014

(54) POLYMER COMPOUND AND LIGHT EMITTING DEVICE USING SAME

(71) Applicants: Yoshikazu Umemoto, Kawasaki-shi (JP); Tomoya Nakatani, Osaka-shi (JP)

(72) Inventors: Yoshikazu Umemoto, Kawasaki-shi (JP); Tomoya Nakatani, Osaka-shi (JP)

(73) Assignee: SUMITOMO CHEMICAL COMPANY, LIMITED, Chuo-ku, Tokyo (JP)

(21) Appl. No.: 14/238,892

(22) PCT Filed: Aug. 10, 2012
(86) PCT No.: PCT/JP2012/070864

§ 371 Date: Mar. 4, 2014

(30) Foreign Application Priority Data
Aug. 22, 2011 (JP) 2011-180288

(51) Int. Cl. H01L 51/00

(52) U.S. Cl. CPC H01L 51/0043; H01L 51/0039; H01L 51/0035
USPC 252/500; 528/8

(57) ABSTRACT

A polymer compound comprising a repeating unit represented by the formula (1):

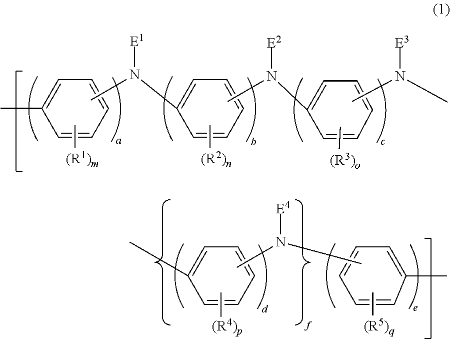

wherein,
E¹, E², E³ and E⁴ represent each independently an aryl group, a mono-valent heterocyclic group or the like,
a, b, c, d and e represent each independently 1 or 2, and f represents an integer of 0 to 3, and when f=0, then, 5≦a+b+c+e≦8 and at least one of b and c is 2, and when there are a plurality of d, these may be the same or different,
m, n, o, p, q and l represent each independently an integer of 0 to 4, and when there are a plurality of m, n, o, p and q, these may be the same or different, respectively,
j and k represent each independently an integer of 0 to 5.

### TECHNICAL FIELD

The present invention relates to a polymer compound and a light emitting device using the same.

### BACKGROUND ART

Light emitting materials of high molecular weight are soluble in a solvent and capable of forming a light emitting layer of a light emitting device by a coating method, hence, variously investigated. As examples thereof, polymer compounds comprising repeating units having two or three nitrogen atoms all three connecting bonds of which are linked to aromatic rings are known.

As such polymer compounds, those comprising a repeating unit represented by the following formula as a repeating unit having two nitrogen atoms are known (International Publication WO99/54385).

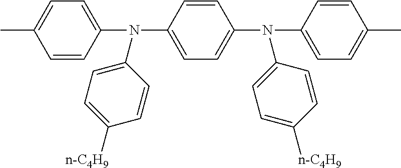

As such polymer compounds, those comprising a repeating unit represented by the following formula as a repeating unit having three nitrogen atoms are known (JP-A No. 2004-162059).

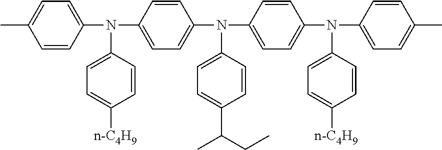

### SUMMARY OF THE INVENTION

However, a light emitting device fabricated by using the above-described polymer compound has a problem that the luminance life (particularly, luminance half life) thereof is not yet sufficient.

Accordingly, the present invention has an object of providing a polymer compound useful for fabrication of a light emitting device having sufficiently long luminance life.

In a first aspect, the present invention provides a polymer compound comprising a repeating unit represented by the formula (1):

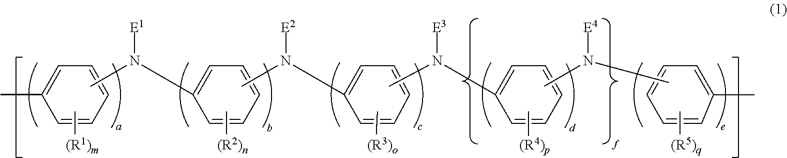

[wherein,

E¹, E², E³ and E⁴ represent each independently an aryl group, a mono-valent heterocyclic group or a group represented by the formula (2), and these groups may have a substituent. When there are a plurality of E⁴, these may be the same or different.

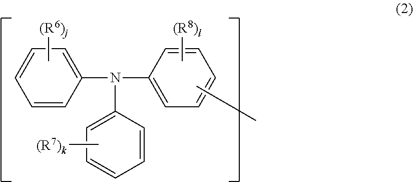

R¹, R², R³, R⁴, R⁵, R⁶, R⁷ and R⁸ represent each independently a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent. When there are a plurality of R¹, R², R³, R⁴, R⁵, R⁶, R⁷ and R⁸, these may be the same or different, respectively.

a, b, c, d and e represent each independently 1 or 2, and f represents an integer of 0 to 3. When f=0, then, 5≦a+b+c+e≦8 and at least one of b and c is 2. When there are a plurality of d, these may be the same or different.

m, n, o, p, q and l represent each independently an integer of 0 to 4, and when there are a plurality of m, n, o, p and q, these may be the same or different, respectively.

j and k represent each independently an integer of 0 to 5.].

In a second aspect, the present invention provides a composition and a film each comprising the polymer compound, and a light emitting device having (that is, equipped with) the film.

### MODES FOR CARRYING OUT THE INVENTION

In the present specification, Me represents a methyl group, Et represents an ethyl group, and Bu represents a butyl group. Further, the prefix “p-” represents para, and the prefix “iso” represents iso.

In the present specification, “repeating unit” denotes a unit present once or more times in one molecule, and is in general referred to as “constitutional unit” in some cases. This “repeating unit” is preferably a unit present repeatedly twice or more times in one molecule.

In the present specification, the substituent in the description “may have a substituent” includes, unless otherwise stated, halogen atoms, hydrocarbyl groups having 1 to 30 carbon atoms and hydrocarbyloxy groups having 1 to 30 carbon atoms as examples, and of them, halogen atoms, hydrocarbyl groups having 1 to 18 carbon atoms or hydrocarbyloxy groups having 1 to 18 carbon atoms are preferable, halogen atoms, hydrocarbyl groups having 1 to 12 carbon atoms or hydrocarbyloxy groups having 1 to 12 carbon atoms are more preferable, halogen atoms or hydrocarbyl groups having 1 to 12 carbon atoms are further preferable, halogen atoms or hydrocarbyl groups having 1 to 6 carbon atoms are particularly preferable.

### <Polymer Compound>

The polymer compound of the present invention is a polymer compound comprising a repeating unit represented by the above-described formula (1). The polymer compound of the present invention may contain only one repeating unit represented by the above-described formula (1), and from the standpoint of hole transportability, may contain two or more repeating units represented by the above-described formula (1).

The aryl group represented by E¹ to E⁴ in the above-described formula (1) is an atomic group remaining after removing one hydrogen atom from an aromatic hydrocarbon (preferably, an atomic group remaining after removing one hydrogen atom linking directly to a carbon atom constituting a ring), and this group may have a substituent.

The aromatic hydrocarbon includes those having a condensed ring and those obtained by linking two or more selected from independent benzene rings and condensed rings, directly or via a group such as a vinylene group and the like.

The aryl group has a number of carbon atoms of usually 6 to 60 (this number of carbon atoms does not include the number of carbon atoms of a substituent.), preferably 6 to 20. The aryl group includes, for example, a phenyl group, C₁ to C₁₂ alkoxyphenyl groups (C₁ to C₁₂ means that the number of carbon atoms thereof is 1 to 12. The same shall apply hereinafter.), C₁ to C₁₂ alkylphenyl groups, C₁ to C₁₂ alkylthiophenyl groups, a 1-naphthyl group, a 2-naphthyl group, a 1-anthracenyl group, a 2-anthracenyl group, a 9-anthracenyl group, a phenanthrene-yl group, a pyrene-yl group, a perylene-yl group, a pentafluorophenyl group and the like, and preferable are C₁ to C₁₂ alkoxyphenyl groups, C₁ to C₁₂ alkylphenyl groups and C₁ to C₁₂ alkylthiophenyl groups.

The C₁ to C₁₂ alkoxyphenyl group includes, for example, a methoxyphenyl group, an ethoxyphenyl group, a propyloxyphenyl group, an isopropyloxyphenyl group, a butoxyphenyl group, an isobutoxyphenyl group, a tert-butoxyphenyl group, a pentyloxyphenyl group, a hexyloxyphenyl group, a cyclohexyloxyphenyl group, a heptyloxyphenyl group, an octyloxyphenyl group, a 2-ethylhexyloxyphenyl group, a nonyloxyphenyl group, a decyloxyphenyl group, a 3,7-dimethyloctyloxyphenyl group and a lauryloxyphenyl group.

The C₁ to C₁₂ alkylphenyl group includes, for example, a methylphenyl group, an ethylphenyl group, a propylphenyl group, an isopropylphenyl group, a butylphenyl group, an isobutylphenyl group, a tert-butylphenyl group, a pentylphenyl group, a hexylphenyl group, a cyclohexylphenyl group, a heptylphenyl group, an octylphenyl group, a 2-ethylhexylphenyl group, a nonylphenyl group, a decylphenyl group, a 3,7-dimethyloctylphenyl group and a laurylphenyl group.

The C₁ to C₁₂ alkylthiophenyl group includes, for example, a methylthiophenyl group, an ethylthiophenyl group, a propylthiophenyl group, an isopropylthiophenyl group, a butylthiophenyl group, an isobutylthiophenyl group, a tert-butylthiophenyl group, a pentylthiophenyl group, a hexylthiophenyl group, a cyclohexylthiophenyl group, a heptylthiophenyl group, an octylthiophenyl group, a 2-ethylhexylthiophenyl group, a nonylthiophenyl group, a decylthiophenyl group, a 3,7-dimethyloctylthiophenyl group and a laurylthiophenyl group.

The mono-valent heterocyclic group represented by E¹ to E⁴ in the above-described formula (1) is an atomic group remaining after removing one hydrogen atom from a heterocyclic compound (preferably, an atomic group remaining after removing one hydrogen atom linking directly to a carbon atom constituting a ring), and this group may have a substituent.

The mono-valent heterocyclic group has a number of carbon atoms of usually 4 to 60 (this number of carbon atoms does not include the number of carbon atoms of a substituent.), preferably 4 to 20. Here, the heterocyclic compound includes organic compounds having a cyclic structure in which elements constituting the ring include not only a carbon atom but also a hetero atom such as an oxygen atom, a sulfur atom, a nitrogen atom, a phosphorus atom, a boron atom, an arsenic acid and the like contained in the ring, and includes those having a condensed ring and those obtained by directly linking two or more selected from independent single rings and condensed rings.

The mono-valent heterocyclic group is preferably a mono-valent aromatic heterocyclic group. The mono-valent aromatic heterocyclic group is an atomic group remaining after removing one hydrogen atom from an aromatic heterocyclic compound (preferably, an atomic group remaining after removing one hydrogen atom linking directly to a carbon atom constituting a ring). The aromatic heterocyclic compound includes, for example, compounds in which a hetero atom-containing hetero ring itself shows aromaticity such as oxadiazole, thiadiazole, thiazole, oxazole, thiophene, pyrrole, phosphole, furan, pyridine, pyrazine, pyrimidine, triazine, pyridazine, quinoline, isoquinoline, carbazole, dibenzophosphole, dibenzofuran, dibenzothiophene and the like, and, compounds in which a hetero atom-containing hetero ring itself shows no aromaticity but an aromatic ring is condensed to the hetero ring such as phenoxazine, phenothiazine, dibenzoborole, dibenzosilole, benzopyran and the like.

The substituent which the aryl group and the mono-valent heterocyclic group represented by E¹ to E⁴ in the above-described formula (1) may have includes, for example, halogen atoms, alkyl groups, alkoxy groups, alkylthio groups, aryl groups, aryloxy groups, arylthio groups, arylalkyl groups, arylalkoxy groups, arylalkylthio groups, acyl groups, acyloxy groups, amide groups, acid imide groups, imine residues, substituted amino groups, substituted silyl groups, substituted silyloxy groups, substituted silylthio groups, substituted silylamino groups, mono-valent heterocyclic groups, heteroaryloxy groups, heteroarylthio groups, arylalkenyl groups, arylalkynyl groups, substituted carboxyl groups and a cyano group, and these groups have the same meaning as groups represented by R¹ to R⁸ described later.

R⁶ to R⁸ in the group represented by the above-described formula (1) represent each independently a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent. When there are a plurality of R⁶ to R⁸, these may be the same or different, respectively. From the standpoint of the solubility of the polymer compound of the present invention, R⁶ to R⁸ represent preferably an alkyl group, an alkoxy group or a halogen atom, more preferably an alkyl group or a halogen atom, further preferably an alkyl group.

E¹ to E⁴ in the above-described formula (1) represent preferably an aryl group, from the standpoint of stability and easiness of synthesis of the polymer compound of the present invention.

In the above-described formula (1), R¹ to R⁵ represent each independently a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent. When there are a plurality of R¹ to R⁵, these may be the same or different, respectively. From the standpoint of the solubility of the polymer compound of the present invention, R¹ to R⁵ represent preferably an alkyl group, an alkoxy group or a halogen atom, more preferably an alkyl group or a halogen atom, further preferably an alkyl group.

The halogen atom represented by the above-described R¹ to R⁸ includes a fluorine atom, a chlorine atom, a bromine atom and an iodine atom.

The alkyl group represented by the above-described R¹ to R⁸ may be any of linear, branched and cyclic, and may have a substituent. This alkyl group has a number of carbon atoms of usually 1 to 20 (this number of carbon atoms does not include the number of carbon atoms of a substituent.), and examples thereof include a methyl group, an ethyl group, a propyl group, an isopropyl group, a butyl group, an isobutyl group, a tert-butyl group, a pentyl group, a hexyl group, a cyclohexyl group, a heptyl group, an octyl group, a 2-ethylhexyl group, a nonyl group, a decyl group, a 3,7-dimethyloctyl group, a lauryl group, a trifluoromethyl group, a pentafluoroethyl group, a perfluorobutyl group, a perfluorohexyl group and a perfluorooctyl group.

The alkoxy group represented by the above-described R¹ to R⁸ may be any of linear, branched and cyclic, and may have a substituent. This alkoxy group has a number of carbon atoms of usually 1 to 20 (this number of carbon atoms does not include the number of carbon atoms of a substituent.), and examples thereof include a methoxy group, an ethoxy group, a propyloxy group, an isopropyloxy group, a butoxy group, an isobutoxy group, a tert-butoxy group, a pentyloxy group, a hexyloxy group, a cyclohexyloxy group, a heptyloxy group, an octyloxy group, a 2-ethylhexyloxy group, a nonyloxy group, a decyloxy group, a 3,7-dimethyloctyloxy group, a lauryloxy group, a trifluoromethoxy group, a pentafluoroethoxy group, a perfluorobutoxy group, a perfluorohexyloxy group, a perfluorooctyloxy group, a methoxymethyloxy group and a 2-methoxyethyloxy group.

The alkylthio group represented by the above-described R¹ to R⁸ may be any of linear, branched and cyclic, and may have a substituent. This alkylthio group has a number of carbon atoms of usually 1 to 20 (this number of carbon atoms does not include the number of carbon atoms of a substituent.), and examples thereof include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group and a trifluoromethylthio group.

The aryl group represented by the above-described R¹ to R⁸ includes the same groups as the mono-valent aryl group represented by the above-described E¹ to E⁴.

The aryloxy group represented by the above-described R¹ to R⁸ may have a substituent, and has a number of carbon atoms of usually 6 to 60 (this number of carbon atoms does not include the number of carbon atoms of a substituent.), and examples thereof include a phenoxy group, C₁ to C₁₂ alkoxyphenoxy groups, C₁ to C₁₂ alkylphenoxy groups, a 1-naphthyloxy group, a 2-naphthyloxy group and a pentafluorophenyloxy group, and preferable are C₁ to C₁₂alkoxyphenoxy groups and C₁ to C₁₂alkylphenoxy groups.

The C₁ to C₁₂ alkoxyphenoxy group includes, for example, a methoxyphenoxy group, an ethoxyphenoxy group, a propyloxyphenoxy group, an isopropyloxyphenoxy group, a butoxyphenoxy group, an isobutoxyphenoxy group, a tert-butoxyphenoxy group, a pentyloxyphenoxy group, a hexyloxyphenoxy group, a cyclohexyloxyphenoxy group, a heptyloxyphenoxy group, an octyloxyphenoxy group, a 2-ethylhexyloxyphenoxy group, a nonyloxyphenoxy group, a decyloxyphenoxy group, a 3,7-dimethyloctyloxyphenoxy group and a lauryloxyphenoxy group.

The C₁ to C₁₂ alkylphenoxy group includes, for example, a methylphenoxy group, an ethylphenoxy group, a dimethylphenoxy group, a propylphenoxy group, a 1,3,5-trimethylphenoxy group, a methylethylphenoxy group, an isopropylphenoxy group, a butylphenoxy group, a sec-butylphenoxy group, an isobutylphenoxy group, a tert-butylphenoxy group, a pentylphenoxy group, an isoamylphenoxy group, a hexylphenoxy group, a heptylphenoxy group, an octylphenoxy group, a nonylphenoxy group, a decylphenoxy group and a dodecylphenoxy group.

The arylthio group represented by the above-described R¹ to R⁸ may have a substituent, and has a number of carbon atoms of usually 3 to 60 (this number of carbon atoms does not include the number of carbon atoms of a substituent.), and examples thereof include a phenylthio group, C₁ to C₁₂ alkoxyphenylthio groups, C₁ to C₁₂ alkylphenylthio groups, a 1-naphthylthio group, a 2-naphthylthio group and a pentafluorophenylthio group, and preferable are C₁ to C₁₂ alkoxyphenylthio groups and C₁ to C₁₂ alkylphenylthio groups.

The arylalkyl group represented by the above-described R¹ to R⁸ may have a substituent and has a number of carbon atoms of usually 7 to 60 (this number of carbon atoms does not include the number of carbon atoms of a substituent.), and examples thereof include phenyl C₁ to C₁₂ alkyl groups, C₁ to C₁₂ alkoxyphenyl C₁ to C₁₂ alkyl groups, C₁ to C₁₂ alkylphenyl C₁ to C₁₂ alkyl groups, 1-naphthyl C₁ to C₁₂ alkyl groups and 2-naphthyl C₁ to C₁₂ alkyl groups, and preferable are C₁ to C₁₂ alkoxyphenyl C₁ to C₁₂ alkyl groups and C₁ to C₁₂ alkylphenyl C₁ to C₁₂ alkyl groups.

The arylalkoxy group represented by the above-described R¹ to R⁸ may have a substituent and has a number of carbon atoms of usually 7 to 60 (this number of carbon atoms does not include the number of carbon atoms of a substituent.), and examples thereof include phenyl C₁ to C₁₂ alkoxy groups such as a phenylmethoxy group, a phenylethoxy group, a phenylbutoxy group, a phenylpentyloxy group, a phenylhexyloxy group, a phenylheptyloxy group, a phenyloctyloxy group and the like, C₁ to C₁₂ alkoxyphenyl C₁ to C₁₂ alkoxy groups, C₁ to C₁₂ alkylphenyl C₁ to C₁₂ alkoxy groups, 1-naphthyl C₁ to C₁₂ alkoxy groups and 2-naphthyl C₁ to C₁₂ alkoxy groups, and preferable are C₁ to C₁₂ alkoxyphenyl C₁ to C₁₂ alkoxy groups and C₁ to C₁₂ alkylphenyl C₁ to C₁₂ alkoxy groups.

The arylalkylthio group represented by the above-described R¹ to R⁸ may have a substituent and has a number of carbon atoms of usually 7 to 60 (this number of carbon atoms does not include the number of carbon atoms of a substituent.), and examples thereof include phenyl C₁ to C₁₂ alkylthio groups, C₁ to C₁₂ alkoxyphenyl C₁ to C₁₂ alkylthio groups, C₁ to C₁₂ alkylphenyl C₁ to C₁₂ alkylthio groups, 1-naphthyl C₁ to C₁₂ alkylthio groups and 2-naphthyl C₁ to C₁₂ alkylthio groups, and preferable are C₁ to C₁₋₂ alkoxyphenyl C₁ to C₁₋₂ alkylthio groups and C₁ to C₁₂ alkylphenyl C₁ to C₁₂ alkylthio groups.

The acyl group represented by the above-described R¹ to R⁸ may have a substituent and has a number of carbon atoms of usually 2 to 20 (this number of carbon atoms does not include the number of carbon atoms of a substituent.), and examples thereof include an acetyl group, a propionyl group, a butyryl group, an isobutyryl group, a pivaloyl group, a benzoyl group, a trifluoroacetyl group and a pentafluorobenzoyl group.

The acyloxy group represented by the above-described R¹ to R⁸ may have a substituent and has a number of carbon atoms of usually 2 to 20 (this number of carbon atoms does not include the number of carbon atoms of a substituent.), and examples thereof include an acetoxy group, a propionyloxy group, a butyryloxy group, an isobutyryloxy group, a pivaloyloxy group, a benzoyloxy group, a trifluoroacetyloxy group and a pentafluorobenzoyloxy group.

The amide group represented by the above-described R¹ to R⁸ may have a substituent and has a number of carbon atoms of usually 2 to 20 (this number of carbon atoms does not include the number of carbon atoms of a substituent.), preferably 2 to 18. This amide group includes, for example, a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group and a dipentafluorobenzamide group.

The acid imide group represented by the above-described R¹ to R⁸ includes residues obtained by removing from an acid imide a hydrogen atom linked to its nitrogen atom, may have a substituent and has a number of carbon atoms of usually 4 to 20 (this number of carbon atoms does not include the number of carbon atoms of a substituent.), and examples thereof include the following groups.

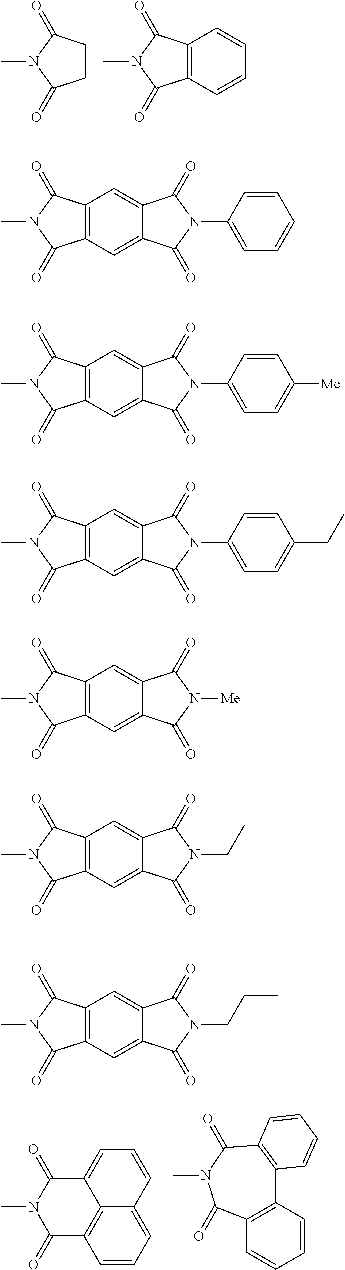

The imine residue represented by the above-described R¹ to R⁸ includes residues obtained by removing one hydrogen atom from an imine compound (meaning an organic compound having —N═C— in the molecule, and examples thereof include aldimines, ketimines and compounds obtained by substituting a hydrogen atom on a nitrogen atom (N) of these compounds with an alkyl group and the like). This imine residue may have a substituent and has a number of carbon atoms of 2 to 20 (this number of carbon atoms does not include the number of carbon atoms of a substituent.), and examples thereof include the following groups.

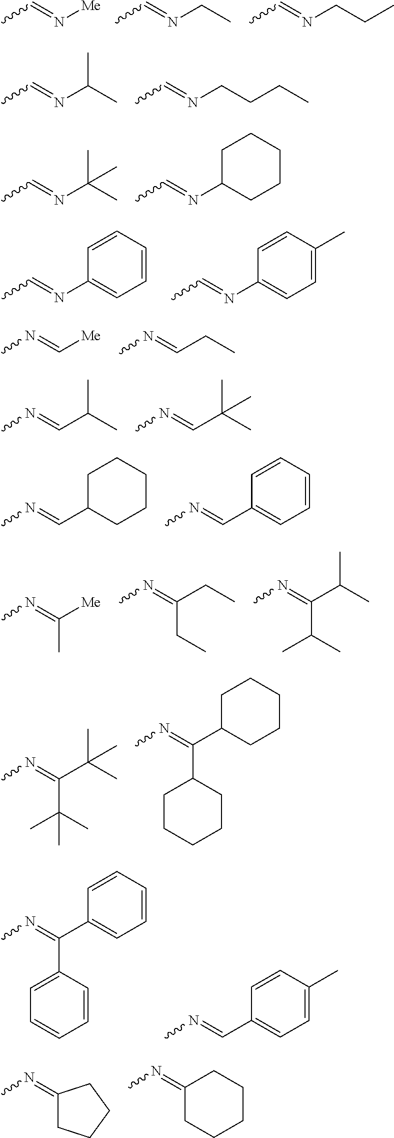

The substituted amino group represented by the above-described R¹ to R⁸ includes amino groups obtained by substituting one or two hydrogen atoms of amino groups by one or two groups selected from alkyl groups, aryl groups, arylalkyl groups and mono-valent heterocyclic groups, and the alkyl group, the aryl group, the arylalkyl group and the mono-valent heterocyclic group may have a substituent. This substituted amino group has a number of carbon atoms of usually 1 to 60 (not including the number of carbon atoms of a substituent of the alkyl group, the aryl group, the arylalkyl group and the mono-valent heterocyclic group). The substituted amino group includes, for example, a methylamino group, a dimethylamino group, an ethylamino group, a diethylamino group, a propylamino group, a dipropylamino group, an isopropylamino group, a diisopropylamino group, a butylamino group, an isobutylamino group, a tert-butylamino group, a pentylamino group, a hexylamino group, a cyclohexylamino group, a heptylamino group, an octylamino group, a 2-ethylhexylamino group, a nonylamino group, a decylamino group, a 3,7-dimethyloctylamino group, a laurylamino group, a cyclopentylamino group, a dicyclopentylamino group, a cyclohexylamino group, a dicyclohexylamino group, a pyrrolidyl group, a piperidyl group, a ditrifluoromethylamino group, a phenylamino group, a diphenylamino group, C₁ to C₁₂ alkoxyphenylamino groups, di (C₁ to C₁₂ alkoxyphenyl)amino groups, di (C₁ to C₁₂ alkylphenyl)amino groups, a 1-naphthylamino group, a 2-naphthylamino group, a pentafluorophenylamino group, a pyridylamino group, a pyridazinylamino group, a pyrimidylamino group, a pyrazylamino group, a triazylamino group, phenyl C₁ to C₁₂ alkylamino groups, C₁ to C₁₂ alkoxyphenyl C₁ to C₁₂ alkylamino groups, C₁ to C₁₂ alkylphenyl C₁ to C₁₂ alkylamino groups, di (C₁ to C₁₂ alkoxyphenyl C₁ to C₁₂ alkyl)amino groups, di (C₁ to C₁₂ alkylphenyl C₁ to C₁₂ alkyl)amino groups, 1-naphthyl C₁ to C₁₂ alkylamino groups and 2-naphthyl C₁ to C₁₂ alkylamino groups.

The substituted silyl group represented by the above-described R¹ to R⁸ includes silyl groups obtained by substituting one, two or three hydrogen atoms of silyl groups by one, two or three groups selected from alkyl groups, aryl groups, arylalkyl groups and mono-valent heterocyclic groups, and the alkyl group, the aryl group, the arylalkyl group and the mono-valent heterocyclic group may have a substituent. This substituted amino group has a number of carbon atoms of usually 1 to 60 (not including the number of carbon atoms of a substituent of the alkyl group, the aryl group, the arylalkyl group and the mono-valent heterocyclic group). The substituted silyl group includes, for example, a trimethylsilyl group, a triethylsilyl group, a tripropylsilyl group, a tri-isopropylsilyl group, a dimethyl-isopropylsilyl group, a diethyl-isopropylsilyl group, a tert-butylsilyldimethylsilyl group, a pentyldimethylsilyl group, a hexyldimethylsilyl group, a heptyldimethylsilyl group, an octyldimethylsilyl group, a 2-ethylhexyldimethylsilyl group, a nonyldimethylsilyl group, a decyldimethylsilyl group, a 3,7-dimethyloctyldimethylsilyl group, a lauryldimethylsilyl group, phenyl C₁ to C₁₂ alkylsilyl groups, C₁ to C₁₂ alkoxyphenyl C₁ to C₁₂ alkylsilyl groups, C₁ to C₁₂ alkylphenyl C₁ to C₁₂ alkylsilyl groups, 1-naphthyl C₁ to C₁₂ alkylsilyl groups, 2-naphthyl C₁ to C₁₂ alkylsilyl groups, phenyl C₁ to C₁₂ alkyldimethylsilyl groups, a triphenylsilyl group, a tri-p-xylylsilyl group, a tribenzylsilyl group, a diphenylmethylsilyl group, a tert-butyldiphenylsilyl group and a dimethylphenylsilyl group.

The substituted silyloxy group represented by the above-described R¹ to R⁸ includes silyloxy groups obtained by substituting one, two or three hydrogen atoms of silyloxy groups by one, two or three groups selected from alkyl groups, aryl groups, arylalkyl groups and mono-valent heterocyclic groups, and the alkyl group, the aryl group, the arylalkyl group and the mono-valent heterocyclic group may have a substituent. This substituted amino group has a number of carbon atoms of usually 1 to 60 (not including the number of carbon atoms of a substituent of the alkyl group, the aryl group, the arylalkyl group and the mono-valent heterocyclic group). The substituted silyloxy group includes, for example, a trimethylsilyloxy group, a triethylsilyloxy group, a tripropylsilyloxy group, a tri-isopropylsilyloxy group, a dimethylisopropylsilyloxy group, a diethylisopropylsilyloxy group, a tert-butylsilyldimethylsilyloxy group, a pentyldimethylsilyloxy group, a hexyldimethylsilyloxy group, a heptyldimethylsilyloxy group, an octyldimethylsilyloxy group, a 2-ethylhexyldimethylsilyloxy group, a nonyldimethylsilyloxy group, a decyldimethylsilyloxy group, a 3,7-dimethyloctyldimethylsilyloxy group, a lauryldimethylsilyloxy group, phenyl C₁ to C₁₂ alkylsilyloxy groups, C₁ to C₁₂ alkoxyphenyl C₁ to C₁₂ alkylsilyloxy groups, C₁ to C₁₂ alkylphenyl C₁ to C₁₂ alkylsilyloxy groups, 1-naphthyl C₁ to C₁₂ alkylsilyloxy groups, 2-naphthyl C₁ to C₁₂ alkylsilyloxy groups, phenyl C₁ to C₁₂ alkyldimethylsilyloxy groups, a triphenylsilyloxy group, a tri-p-xylylsilyloxy group, a tribenzylsilyloxy group, a diphenylmethylsilyloxy group, a tert-butyldiphenylsilyloxy group, a dimethylphenylsilyloxy group, a trimethoxysilyloxy group, a triethoxysilyloxy group, a tripropyloxysilyloxy group, a tri-isopropylsilyloxy group, a dimethylisopropylsilyloxy group, a methyldimethoxysilyloxy group and an ethyldimethoxysilyloxy group.

The substituted silylthio group represented by the above-described R¹ to R⁸ includes silylthio groups obtained by substituting one, two or three hydrogen atoms of silyloxy groups by one, two or three groups selected from alkyl groups, aryl groups, arylalkyl groups and mono-valent heterocyclic groups, and the alkyl group, the aryl group, the arylalkyl group and the mono-valent heterocyclic group may have a substituent. This substituted silylthio group has a number of carbon atoms of usually 1 to 60 (this number of carbon atoms does not include the number of carbon atoms of a substituent.), preferably 3 to 48. The substituted silylthio group includes, for example, a trimethylsilylthio group, a triethylsilylthio group, a tripropylsilylthio group, a tri-isopropylsilylthio group, an isopropyldimethylsilylthio group, a diethylisopropylsilylthio group, a tert-butyldimethylsilylthio group, a dimethylpentylsilylthio group, a hexyldimethylsilylthio group, a heptyldimethylsilylthio group, a dimethyloctylsilylthio group, a 2-ethylhexyldimethylsilylthio group, a dimethylnonylsilylthio group, a decyldimethylsilylthio group, a 3,7-dimethyloctyldimethylsilylthio group, a lauryldimethylsilylthio group, phenyl C₁ to C₁₂ alkylsilylthio groups, C₁ to C₁₂ alkoxyphenyl C₁ to C₁₂ alkylsilylthio groups, C₁ to C₁₂ alkylphenyl C₁ to C₁₂ alkylsilylthio groups, 1-naphthyl C₁ to C₁₂ alkylsilylthio groups, 2-naphthyl C₁ to C₁₂ alkylsilylthio groups, phenyl C₁ to C₁₂ alkyldimethylsilylthio groups, a triphenylsilylthio group, a tri(p-tolyl)silylthio group, a tribenzylsilylthio group, a methyldiphenylsilylthio group, a tert-butyldiphenylsilylthio group and a dimethylphenylsilylthio group.

The substituted silylamino group represented by the above-described R¹ to R⁸ includes silylamino groups obtained by substituting one, two or three hydrogen atoms of silylamino groups by one, two or three groups selected from alkyl groups, aryl groups, arylalkyl groups and mono-valent heterocyclic groups, and the alkyl group, the aryl group, the arylalkyl group and the mono-valent heterocyclic group may have a substituent. This substituted silylamino group has a number of carbon atoms of usually 1 to 60 (this number of carbon atoms does not include the number of carbon atoms of a substituent.), preferably 3 to 48. The substituted silylamino group includes, for example, a trimethylsilylamino group, a triethylsilylamino group, a tripropylsilylamino group, a tri-isopropylsilylamino group, a dimethylisopropylsilylamino group, a diethylisopropylsilylamino group, a tert-butyldimethylsilylamino group, a pentyldimethylsilylamino group, a hexyldimethylsilylamino group, a heptyldimethylsilylamino group, an octyldimethylsilylamino group, a 2-ethylhexyldimethylsilylamino group, a nonyldimethylsilylamino group, a decyldimethylsilylamino group, a 3,7-dimethyloctyldimethylsilylamino group, a lauryldimethylsilylamino group, phenyl C₁ to C₁₂ alkylsilyloxy groups, C₁ to C₁₂ alkoxyphenyl C₁ to C₁₂ alkylsilylamino groups, C₁ to C₁₂ alkylphenyl C₁ to C₁₂ alkylsilylamino groups, 1-naphthyl C₁ to C₁₂ alkylsilylamino groups, 2-naphthyl C₁ to C₁₂ alkylsilylamino groups, phenyl C₁ to C₁₂ alkyldimethylsilylamino groups, a triphenylsilylamino group, a tri(p-tolyl)silylamino group, a tribenzylsilylamino group, a diphenylmethylsilylamino group, a tert-butyldiphenylsilylamino group and a dimethylphenylsilylamino group.

The mono-valent heterocyclic group represented by the above-described R¹ to R⁸ includes the same groups as the mono-valent heterocyclic group represented by the above-described E¹ to E⁴.

The heteroaryloxy group represented by the above-described R¹ to R⁸ may have a substituent, and has a number of carbon atoms of usually 6 to 60 (this number of carbon atoms does not include the number of carbon atoms of a substituent.), preferably 7 to 48. The heteroaryloxy group includes, for example, a thienyloxy group, C₁ to C₁₂ alkoxythienyloxy groups, C₁ to C₁₂ alkylthienyloxy groups, C₁ to C₁₂ alkoxypyridyloxy groups, C₁ to C₁₂ alkylpyridyloxy groups and an isoquinolyloxy group, and preferable are C₁ to C₁₂ alkoxypyridyloxy groups and C₁ to C₁₂ alkylpyridyloxy groups.

The C₁ to C₁₂ alkoxypyridyloxy group includes, for example, a methoxypyridyloxy group, an ethoxypyridyloxy group, a propyloxypyridyloxy group, an isopropyloxypyridyloxy group, a butoxypyridyloxy group, an isobutoxypyridyloxy group, a tert-butoxypyridyloxy group, a pentyloxypyridyloxy group, a hexyloxypyridyloxy group, a cyclohexyloxypyridyloxy group, a heptyloxypyridyloxy group, an octyloxypyridyloxy group, a 2-ethylhexyloxypyridyloxy group, a nonyloxypyridyloxy group, a decyloxypyridyloxy group, a 3,7-dimethyloctyloxypyridyloxy group and a lauryloxypyridyloxy group.

The C₁ to C₁₂ alkylpyridyloxy group includes, for example, a methylpyridyloxy group, an ethylpyridyloxy group, a dimethylpyridyloxy group, a propylpyridyloxy group, a 1,3,5-trimethylpyridyloxy group, a methylethylpyridyloxy group, an isopropylpyridyloxy group, a butylpyridyloxy group, a sec-butylpyridyloxy group, an isobutylpyridyloxy group, a tert-butylpyridyloxy group, a pentylpyridyloxy group, an isoamylpyridyloxy group, a hexylpyridyloxy group, a heptylpyridyloxy group, an octylpyridyloxy group, a nonylpyridyloxy group, a decylpyridyloxy group and a dodecylpyridyloxy group.

The heteroarylthio group represented by the above-described R¹ to R⁸ may have a substituent, and has a number of carbon atoms of usually 6 to 60 (this number of carbon atoms does not include the number of carbon atoms of a substituent.), preferably 7 to 48. The heteroarylthio group includes a pyridylthio group, C₁ to C₁₂ alkoxypyridylthio groups, C₁ to C₁₂ alkylpyridylthio groups, an isoquinolylthio group and the like, and preferable are C₁ to C₁₂ alkoxypyridylthio groups and C₁ to C₁₋₂ alkylpyridylthio groups.

The arylalkenyl group represented by the above-described R¹ to R⁸ may have a substituent, and has a number of carbon atoms of usually 8 to 60 (this number of carbon atoms does not include the number of carbon atoms of a substituent.). The arylalkenyl group includes, for example, phenyl C₂ to C₁₂ alkenyl groups, C₁ to C₁₂ alkoxyphenyl C₂ to C₁₂ alkenyl groups, C₁ to C₁₂ alkylphenyl C₂ to C₁₂ alkenyl groups, 1-naphthyl C₂ to C₁₂ alkenyl groups and 2-naphthyl C₂ to C₁₂ alkenyl groups, and preferable are C₁ to C₁₂ alkoxyphenyl C₂ to C₁₂ alkenyl groups and C₂ to C₁₂ alkylphenyl C₁ to C₁₂ alkenyl groups.

The arylalkynyl group represented by the above-described R¹ to R⁸ may have a substituent, and has a number of carbon atoms of usually 8 to 60 (this number of carbon atoms does not include the number of carbon atoms of a substituent.). The arylalkynyl group includes, for example, phenyl C₂ to C₁₂ alkynyl groups, C₁ to C₁₂ alkoxyphenyl C₂ to C₁₂ alkynyl groups, C₁ to C₁₂ alkylphenyl C₂ to C₁₂ alkynyl groups, 1-naphthyl C₂ to C₁₂ alkynyl groups and 2-naphthyl C₂ to C₁₂ alkynyl groups, and preferable are C₁ to C₁₂ alkoxyphenyl C₂ to C₁₂ alkynyl groups and C₁ to C₁₂ alkylphenyl C₂ to C₁₂ alkynyl groups.

The substituted carboxyl group represented by the above-described R¹ to R⁸ includes carboxyl groups obtained by substituting a hydrogen atom of a carboxyl group by an alkyl group, an aryl group, an arylalkyl group or a mono-valent heterocyclic group, and the alkyl group, the aryl group, the arylalkyl group and the mono-valent heterocyclic group may have a substituent. The substituted carboxyl group has a number of carbon atoms of usually 2 to 60 (this number of carbon atoms does not include the number of carbon atoms of a substituent of the alkyl group, the aryl group, the arylalkyl group and the mono-valent heterocyclic group.). The substituted carboxyl group includes, for example, a methoxycarboxyl group, an ethoxycarboxyl group, a propoxycarboxyl group, an isopropoxycarboxyl group, a butoxycarboxyl group, an isobutoxycarboxyl group, a tert-butoxycarboxyl group, a pentyloxycarboxyl group, a hexyloxycarboxyl group, a cyclohexyloxycarboxyl group, a heptyloxycarboxyl group, an octyloxycarboxyl group, a 2-ethylhexyloxycarboxyl group, a nonyloxycarboxyl group, a decyloxycarboxyl group, a 3,7-dimethyloctyloxycarboxyl group, a dodecyloxycarboxyl group, a trifluoromethoxycarboxyl group, a pentafluoroethoxycarboxyl group, a perfluorobutoxycarboxyl group, a perfluorohexyloxycarboxyl group, a perfluorooctyloxycarboxyl group, a phenoxycarboxyl group, a naphthoxycarboxyl group and a pyridyloxycarboxyl group.

In the repeating unit represented by the above-described formula (1), a, b, c, d and e represent each independently 1 or 2, and f represents an integer of 0 to 3. It is preferable that c and d are 1.

When f=0, then, 5≦a+b+c+e≦8 and at least one of b and c is 2, and it is preferable that 5≦a+b+c+e≦6 and at least one of b and c is 2.

When f=1, then, 5≦a+b+c+d+e≦10, and it is preferable that 5≦a+b+c+d+e≦8.

From the standpoint of the hole transportability of the polymer compound of the present invention, it is preferable that f=0 or f=1, it is more preferable that f=1.

m, n, o, p, q and l are preferably 0 or 1, more preferably 0.

j and k are preferably an integer of 1 to 3, more preferably 1 or 3, further preferably 1.

In the polymer compound of the present invention, it is desirable that repeating units represented by the above-described formula (1) are not substantially adjacent to each other, from the standpoint of luminance life of light emitting device in which the polymer compound of the present invention is used. Here, “not substantially adjacent to each other” denotes that the proportion of the number of mutual bonds of repeating units represented by the above-described formula (1) to the number of all bonds of repeating units represented by the above-described formula (1) is less than 0.05, and this proportion is preferably less than 0.03, more preferably less than 0.01.

The repeating unit represented by the above-described formula (1) is preferably a repeating unit represented by the formula (1-a).

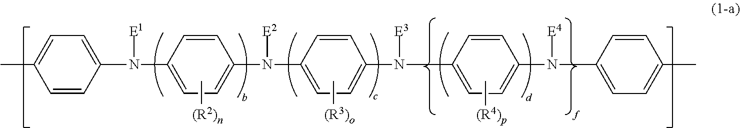

[wherein,

E¹ to E⁴ and R² to R⁴ have the same meaning as described above.

b, c, d and f have the same meaning as described above. n, o and p have the same meaning as described above.].

Specific examples (f=0) of the repeating unit represented by the above-described formula (1) include the following repeating units.

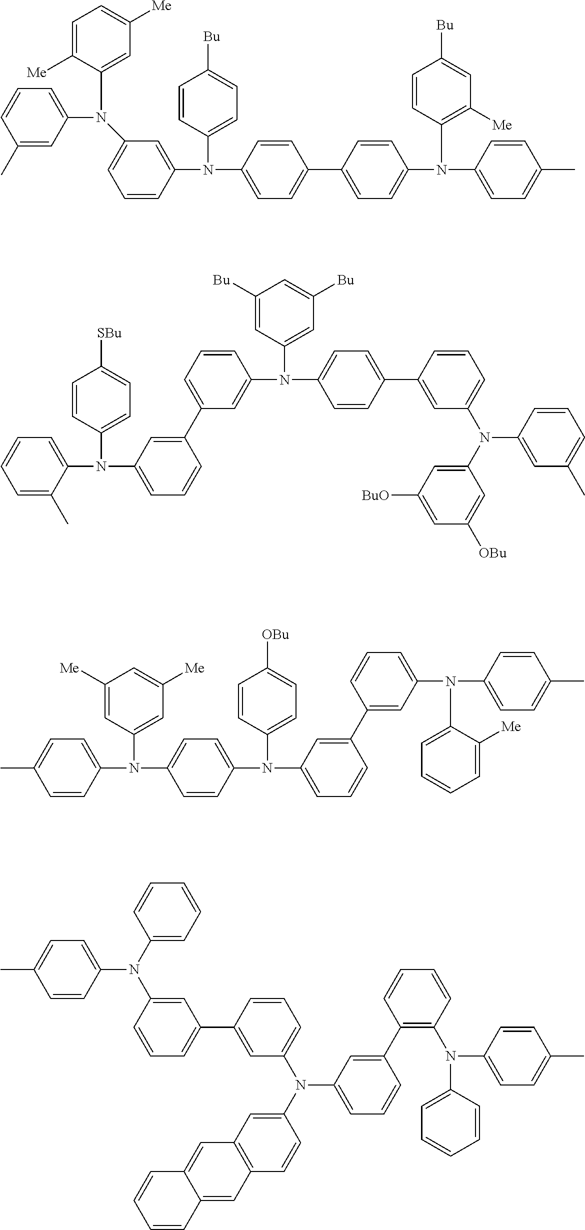

Specific examples (f=0) of the repeating unit represented by the above-described formula (1-a) include the following repeating units.

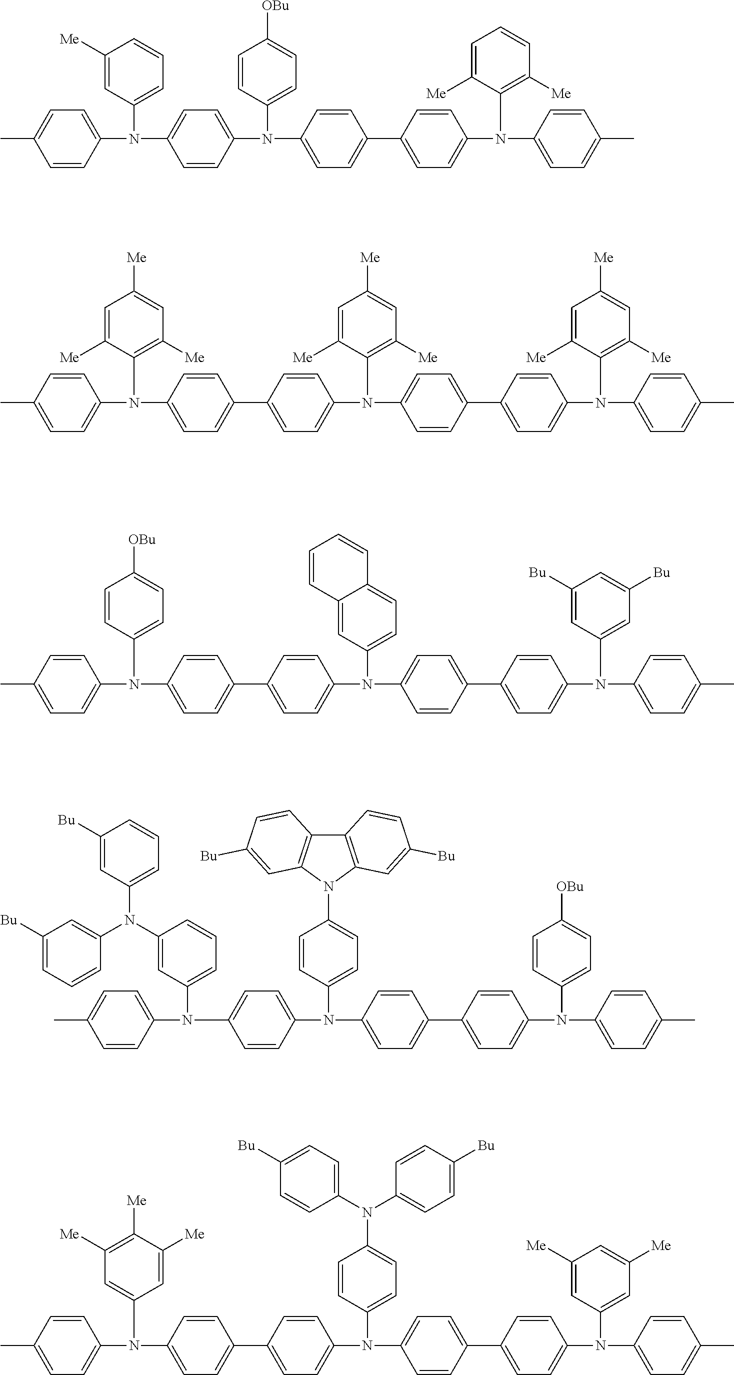

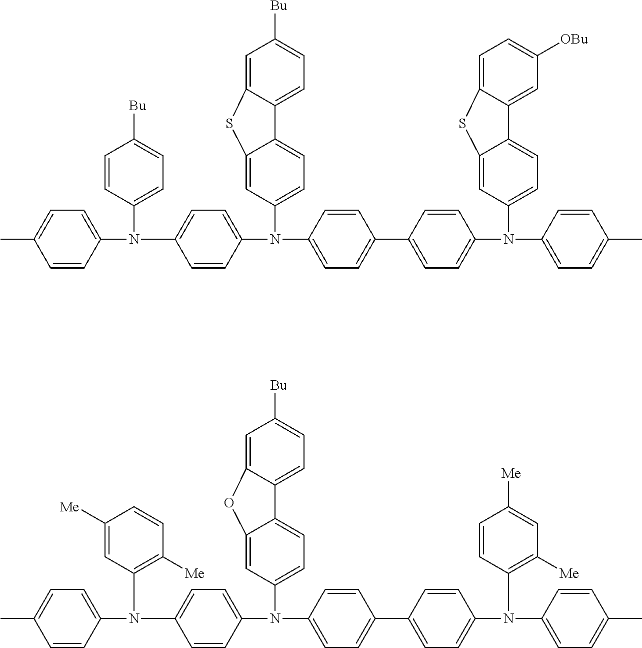

Specific examples (f=1) of the repeating unit represented by the above-described formula (1) include the following repeating units.

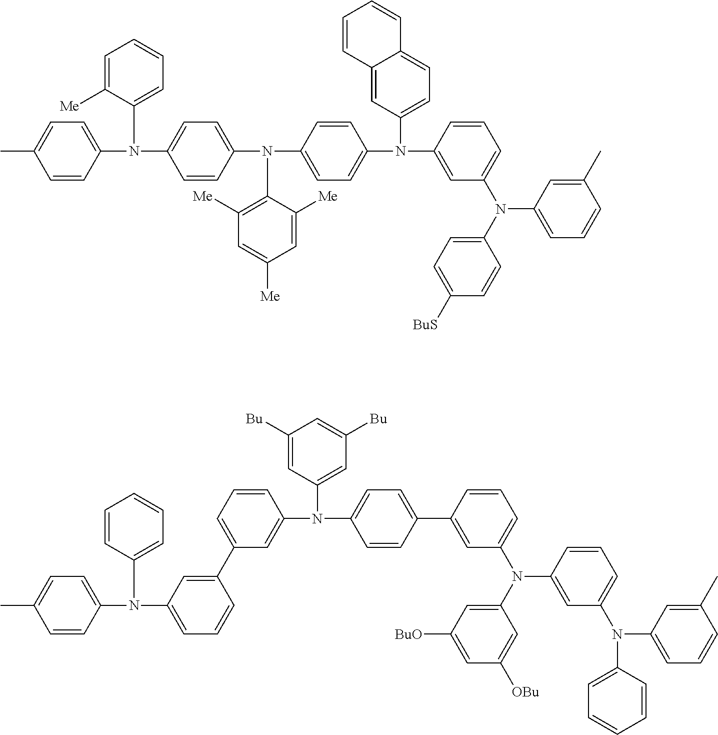

Specific examples (f=1) of the repeating unit represented by the above-described formula (1-a) include the following repeating units.

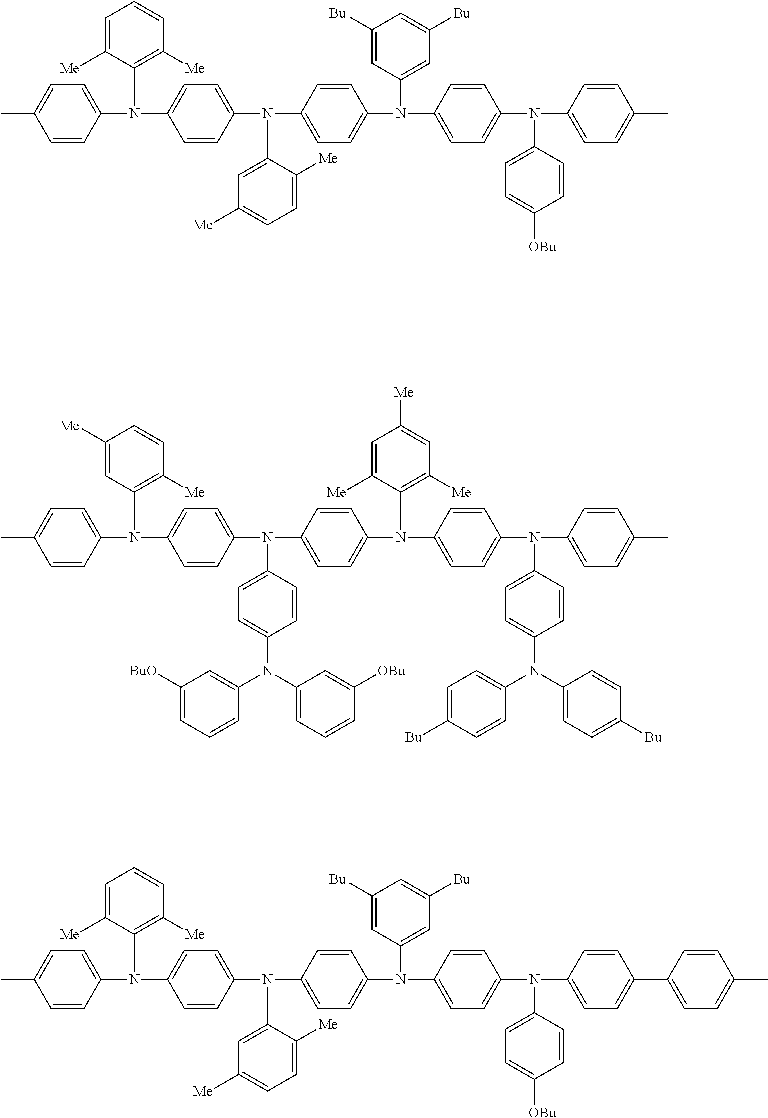

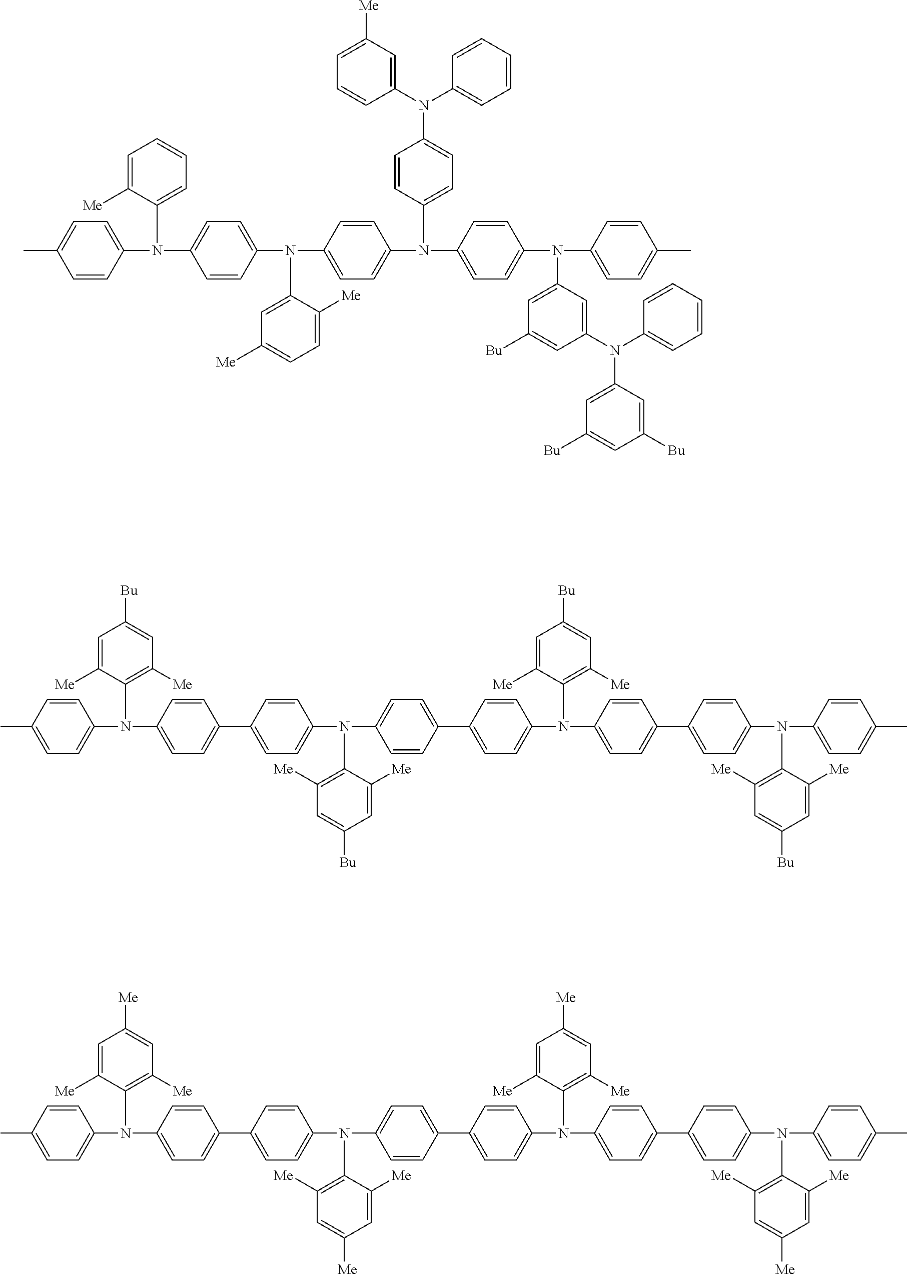

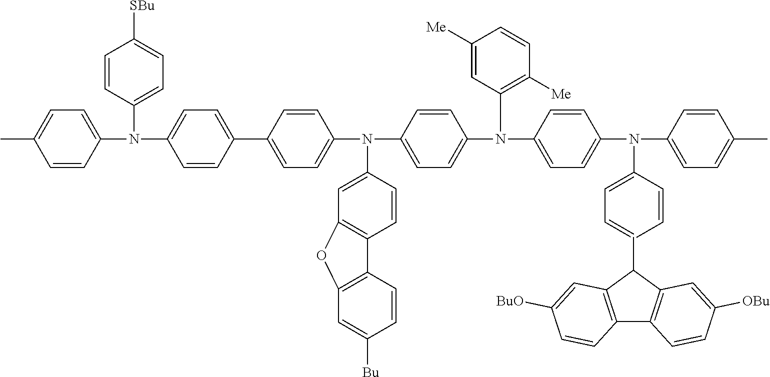

Specific examples (f=2) of the repeating unit represented by the above-described formula (1) include the following repeating units.

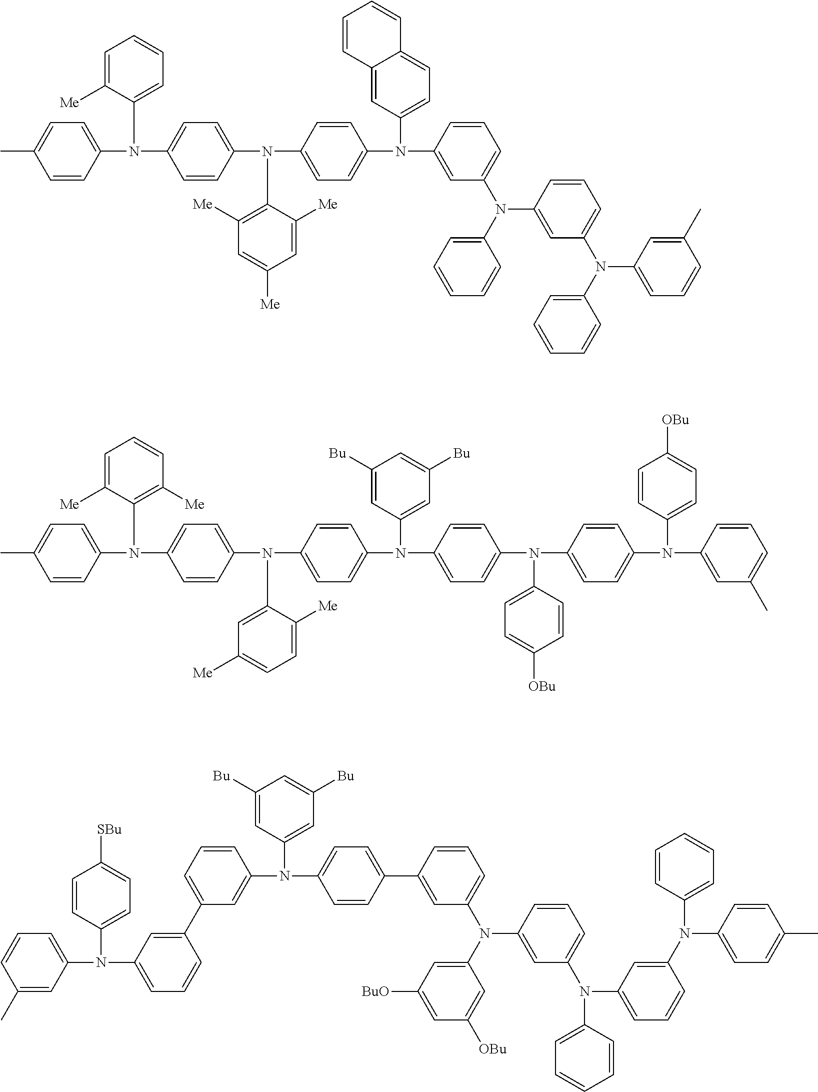

Specific examples (f=2) of the repeating unit represented by the above-described formula (1-a) include the following repeating units.

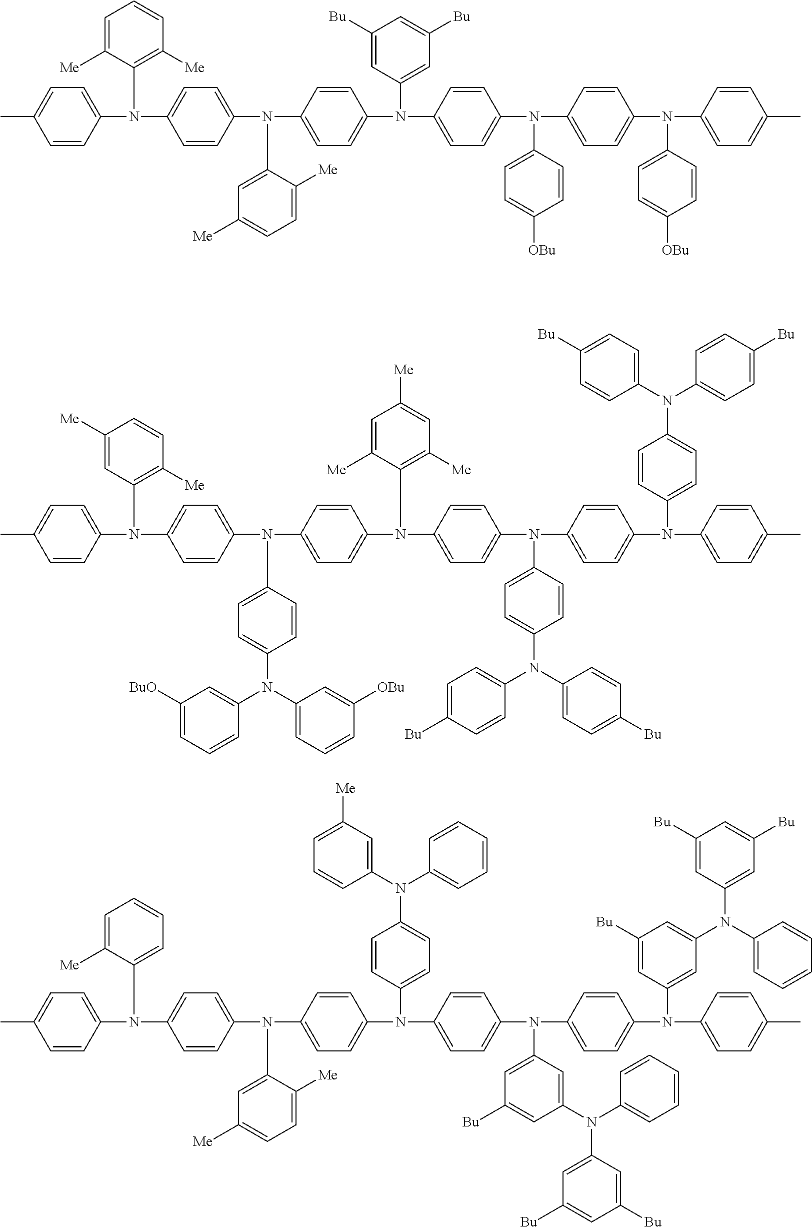

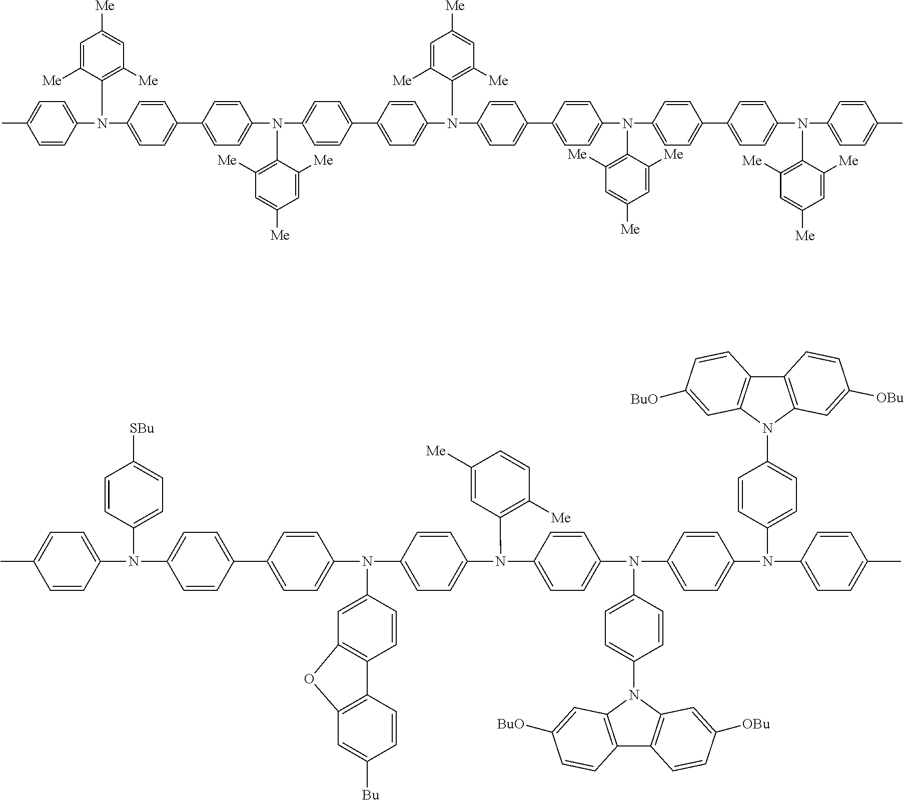

Specific examples (f=3) of the repeating unit represented by the above-described formula (1) include the following repeating units.

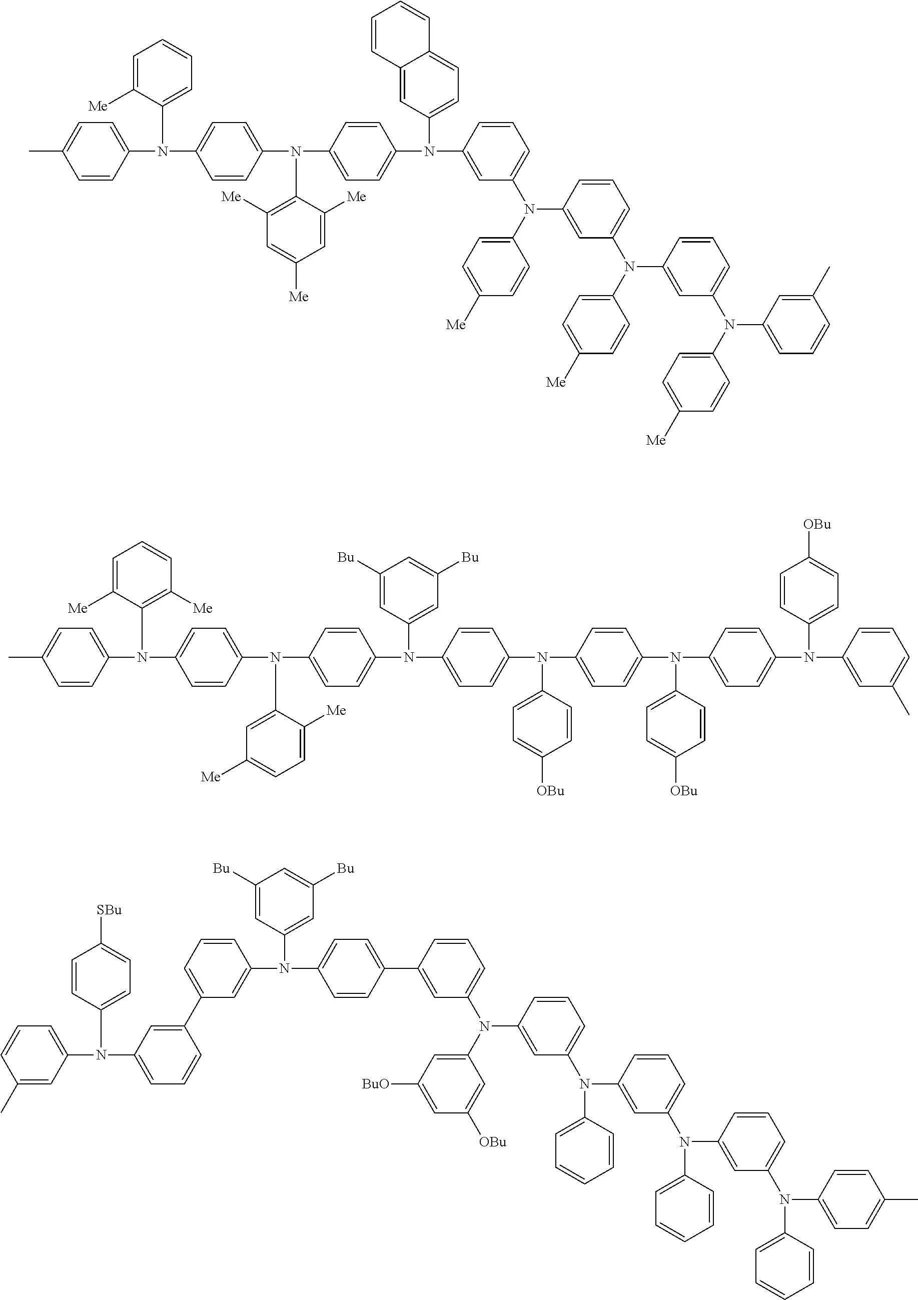

Specific examples (f=3) of the repeating unit represented by the above-described formula (1-a) include the following repeating units.

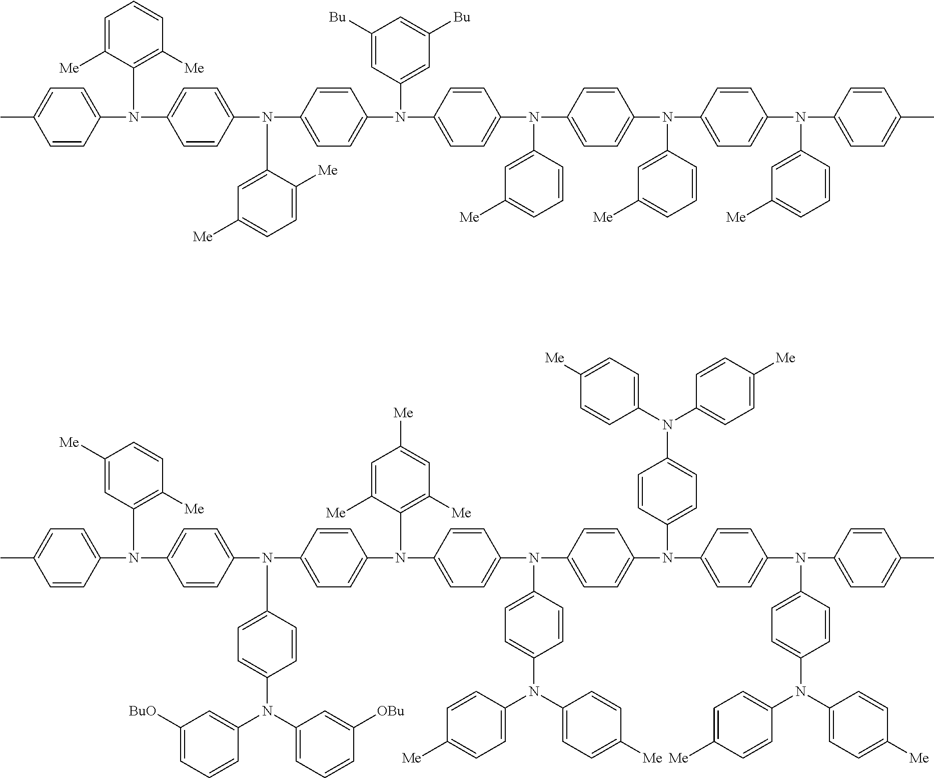

It is preferable that the polymer compound of the present invention contains further a repeating unit represented by the formula (3).

Ar¹³ (3)

[wherein,

Ar¹³ represents an arylene group, a di-valent heterocyclic group or a di-valent group having a metal complex structure, and these groups may have a substituent.].

In the above-described formula (3), the arylene group represented by Ar¹³ is an atomic group remaining after removing two hydrogen atoms from an aromatic hydrocarbon (preferably, an atomic group remaining after removing two hydrogen atoms linking directly to carbon atoms constituting the ring), and the arylene group may have a substituent.

The aromatic hydrocarbon includes those having a condensed ring, and those obtained by linking two or more rings selected from independent benzene rings and condensed rings directly or via a vinylene group or the like.

In the arylene group represented by Ar¹³, a portion excluding a substituent has a number of carbon atoms of usually 6 to 60 (this number of carbon atoms does not include the number of carbon atoms of a substituent.), preferably 6 to 20.

The arylene group represented by Ar¹³ includes, for example, phenylene groups (the following formulae 1 to 3), naphthalenediyl groups (the following formulae 4 to 13), anthracene-diyl groups (the following formulae 14 to 19), biphenyldiyl groups (the following formulae 20 to 25), terphenyldiyl groups (the following formulae 26 to 28), groups derived from condensed ring compounds (the following formulae 29 to 35), fluorene-diyl groups (the following formulae 36 to 38) and benzofluorene-diyl groups (the following formulae 39 to 46).

The groups represented by the following formulae 1 to 46 may have a substituent, and the substituent includes a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group and a cyano group. These groups have the same meaning as the groups represented by the above-described R¹ to R⁸, and dot not include cross-linkable groups.

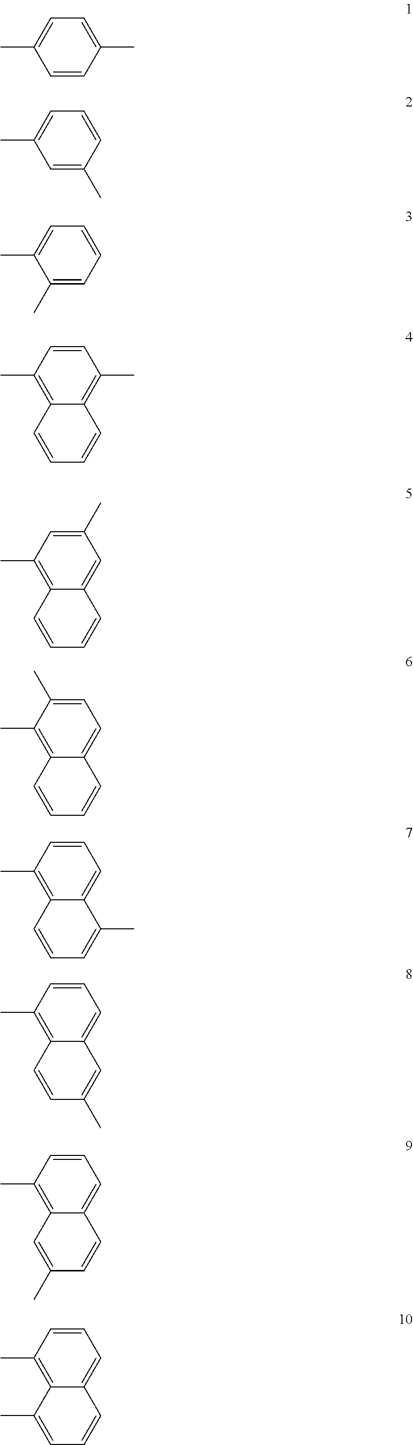

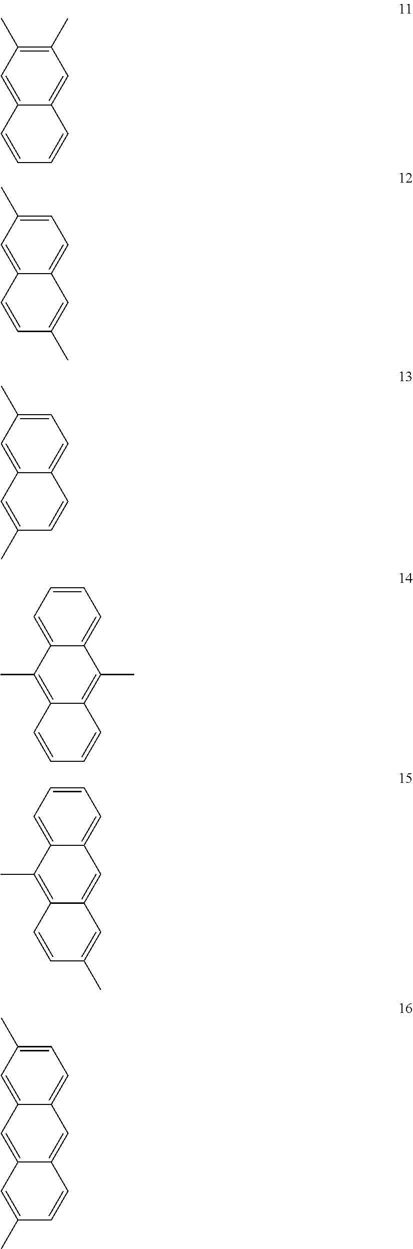

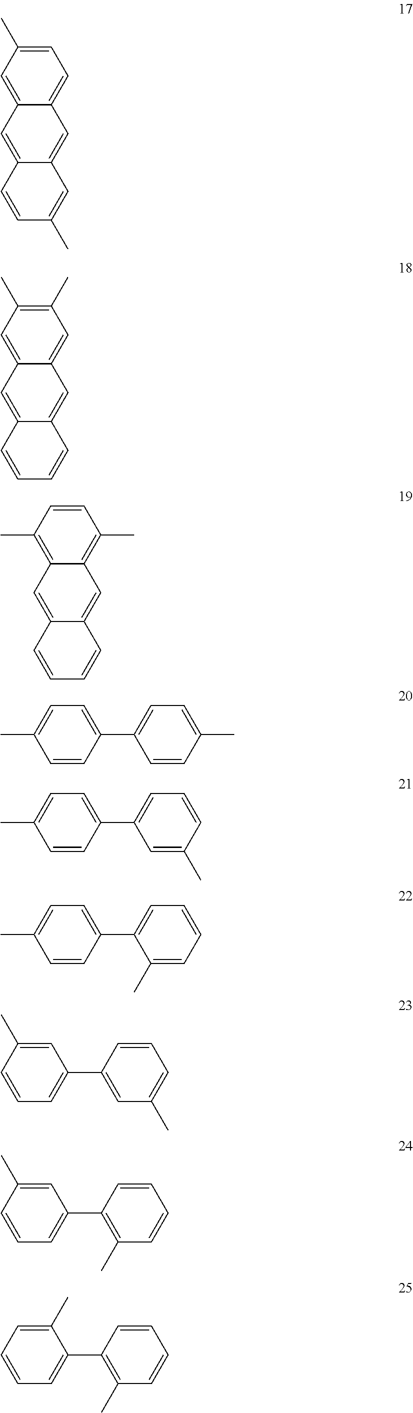

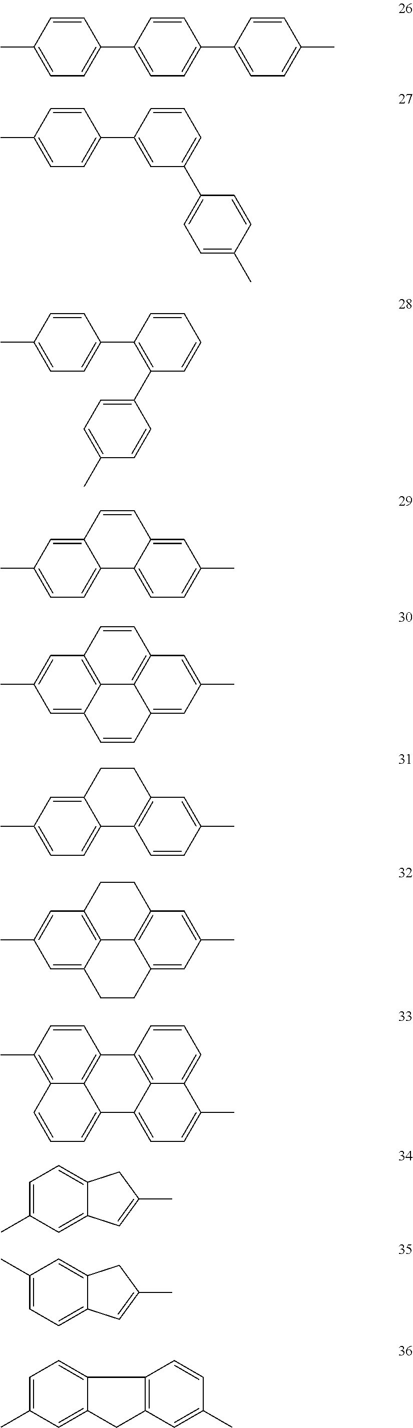

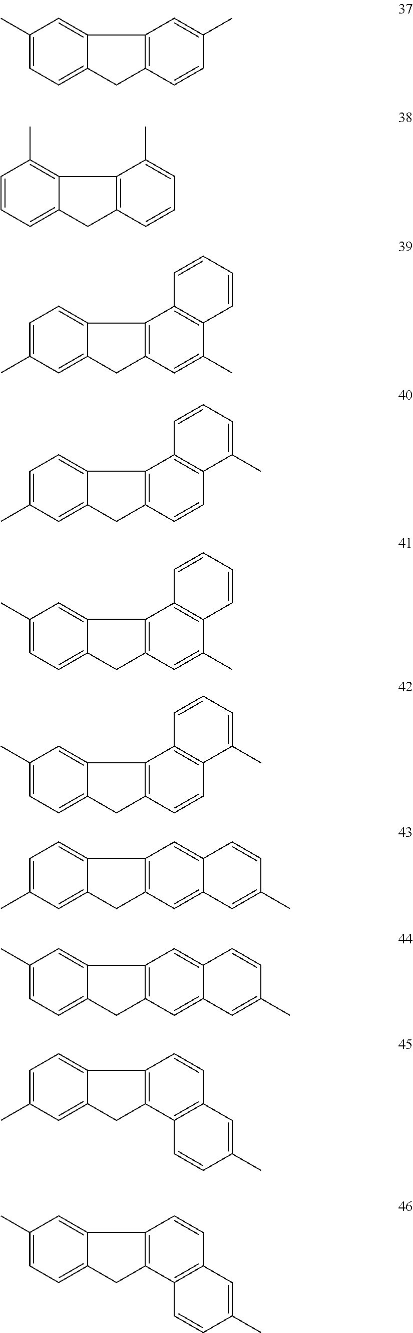

The repeating unit represented by the above-described formula (3) is preferably a repeating unit represented by the following formula (3′), and it is more preferable that at least one of R¹⁰ and R¹¹ is an alkyl group, an aryl group or an arylalkyl group, it is further preferable that R¹⁰ is an alkyl group and R¹¹ is an aryl group or an arylalkyl group, from the standpoint of luminance life of light emitting device in which the polymer compound of the present invention is used.

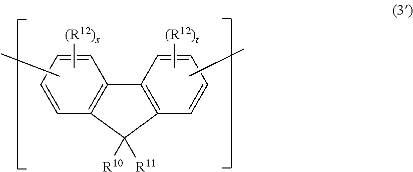

[wherein,

R¹⁰ and R¹¹ represent each independently a hydrogen atom, an alkyl group, an aryl group, an arylalkyl group or a mono-valent heterocyclic group, and these groups may have a substituent, and R¹⁰ and R¹¹ may be mutually linked to form a ring structure.

R¹² represents a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups have the same meaning as the groups represented by the above-described R¹ to R⁸, and these groups may have a substituent. When there are a plurality of R¹², these may be the same or different.

s and t represent each independently an integer of 0 to 3.].

The repeating unit represented by the above-described formula (3′) is preferably a repeating unit represented by the formula (3′-a) from the standpoint of luminance life of light emitting device in which the polymer compound of the present invention is used. It is preferable that s and t are 0 from the standpoint of easiness of synthesis of the polymer compound of the present invention, and it is preferable that at least one of R¹⁰ and R¹¹ is an alkyl group, an aryl group or an arylalkyl group, it is more preferable that R¹⁰ is an alkyl group and R¹¹ is an aryl group or an arylalkyl group, from the standpoint of luminance life of light emitting device in which the polymer compound of the present invention is used.

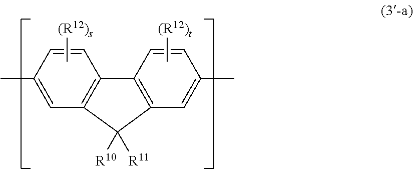

[wherein,

R¹⁰ and R¹¹ have the same meaning as described above. R¹² has the same meaning as described above. When there are a plurality of R¹², these may be the same or different.

s and t represent each independently an integer of 0 to 3.].

The repeating unit represented by the above-described formula (3′-a) includes, for example, repeating units represented by the following formulae (3′-a)-1 to (3′-a)-14, and repeating units represented by the formulae (3′-a)-8 to (3′-a)-9 or (3′-a)-11 to (3′-a)-14 are preferable, a repeating unit represented by the formula (3′-a)-13 or (3′-a)-14 is more preferable, from the standpoint of luminance life of light emitting device in which the polymer compound of the present invention is used.

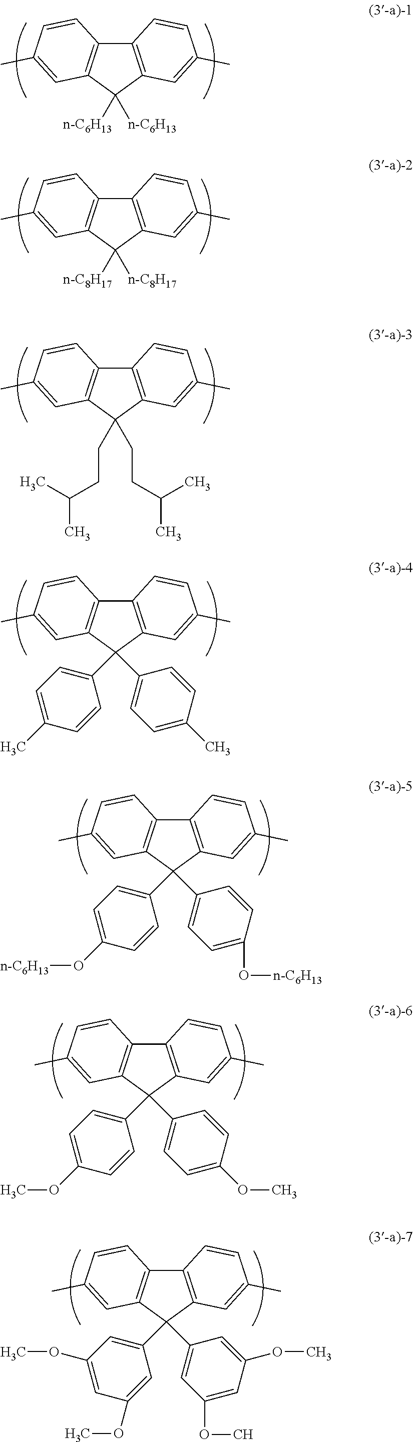

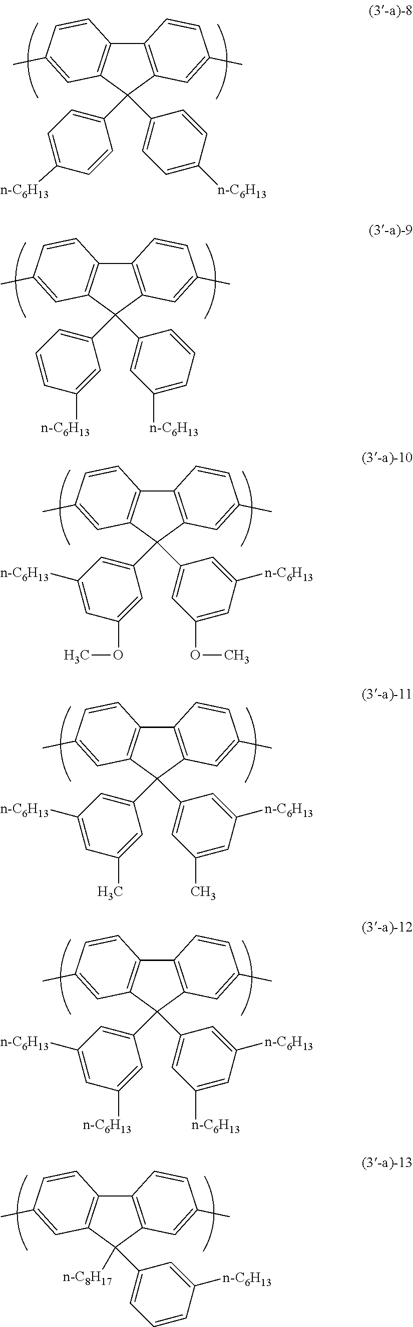

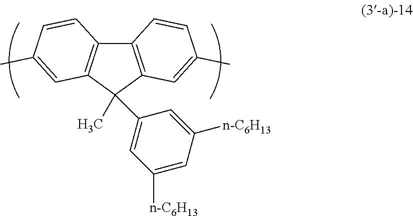

The repeating unit represented by the above-described formula (3) is preferably a repeating unit represented by the following formula (4), from the standpoint of the charge transportability of the polymer compound of the present invention.

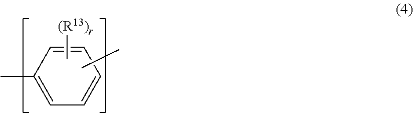

[wherein,

R¹³ represents a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group. These groups have the same meaning as the groups represented by the above-described R¹ to R⁸, and these groups may have a substituent. When there are a plurality of R¹³, these may be the same or different.

r represents an integer of 0 to 4.].

The above-described R¹³ is preferably an alkyl group or an alkoxy group, further preferably an alkyl group, from the standpoint of the solubility of the polymer compound of the present invention. The above-described r is preferably 0 to 2, particularly preferably 0. This is because the charge transportability of the polymer compound of the present invention is more excellent.

The repeating unit represented by the above-described formula (4) is preferably a repeating unit represented by the following formula (4-a) or the following formula (4-b), more preferably a repeating unit represented by the formula (4-a), from the standpoint of easiness of synthesis of the polymer compound of the present invention.

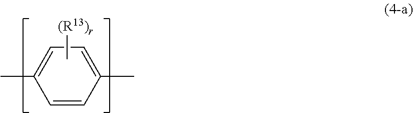

[wherein,

R¹³ has the same meaning as described above, and when there are a plurality of R¹³, these may be the same or different.

r has the same meaning as described above.].

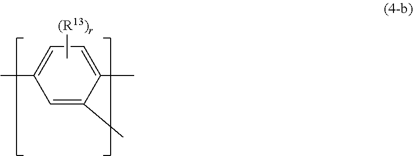

[wherein,

R¹³ has the same meaning as described above, and when there are a plurality of R¹³, these may be the same or different.

r has the same meaning as described above.].

In the above-described formula (3), the di-valent heterocyclic group represented by Ar¹³ is an atomic group remaining after removing two hydrogen atoms from a heterocyclic compound (preferably, an atomic group remaining after removing two hydrogen atoms linking directly to carbon atoms constituting the ring), and this group may have a substituent.

Here, the heterocyclic compound includes organic compounds having a cyclic structure in which elements constituting the ring include not only a carbon atom but also a hetero atom such as an oxygen atom, a sulfur atom, a nitrogen atom, a phosphorus atom, a boron atom, an arsenic acid or the like contained in the ring, and includes those having a condensed ring, and those obtained by directly linking two or more groups selected from independent single rings and condensed rings.

The di-valent heterocyclic group is preferably a di-valent aromatic heterocyclic group. The di-valent aromatic heterocyclic group is an atomic group remaining after removing two hydrogen atoms from an aromatic heterocyclic compound (preferably, an atomic group remaining after removing two hydrogen atoms linking directly to carbon atoms constituting the ring). The aromatic heterocyclic compound includes, for example, compounds in which a hetero atom-containing hetero ring itself shows aromaticity such as oxadiazole, thiadiazole, thiazole, oxazole, thiophene, pyrrole, phosphole, furan, pyridine, pyrazine, pyrimidine, triazine, pyridazine, quinoline, isoquinoline, carbazole, dibenzophosphole, dibenzofuran, dibenzothiophene and the like, and compounds in which a hetero atom-containing hetero ring itself shows no aromaticity but an aromatic ring is condensed to the hetero ring such as phenoxazine, phenothiazine, dibenzoborole, dibenzosilole, benzopyran and the like.

The substituent which the di-valent heterocyclic group may have includes a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group and a cyano group, preferably an alkyl group, an alkoxy group, an aryl group, an aryloxy group, an arylalkyl group, an arylalkoxy group, a halogen atom and a cyano group, from the standpoint of the solubility of the resultant polymer compound. These groups have the same meaning as the groups represented by the above-described R¹ to R⁸.

In the di-valent heterocyclic group represented by Ar¹³, a portion excluding a substituent has a number of carbon atoms of usually 3 to 60, and the total number of carbon atoms including a substituent is usually 3 to 100.

The di-valent heterocyclic group represented by Ar¹³ includes, for example, pyridine-diyl groups (the following formulae 101 to 104), diazaphenylene groups (the following formulae 105 to 108), triazine-diyl groups (the following formulae 109), quinoline-diyl groups (the following formulae 110 to 114), quinoxaline-diyl groups (the following formulae 115 to 119), acridinediyl groups (the following formulae 120 to 123), bipyridyl-diyl groups (the following formulae 124 to 126), phenanthrolinediyl groups (the following formulae 127 to 128), groups having a structure containing an oxygen atom, a sulfur atom, a nitrogen atom, a silicon atom and the like as a hetero atom (the following formulae 129 to 136), 5-membered ring heterocyclic groups containing an oxygen atom, a sulfur atom, a nitrogen atom, a silicon atom and the like as a hetero atom (the following formulae 137 to 140), 5-membered ring condensed heterocyclic groups containing an oxygen atom, a sulfur atom, a nitrogen atom, a silicon atom and the like as a hetero atom (the following formulae 141 to 158), 5-membered ring heterocyclic groups containing an oxygen atom, a sulfur atom, a nitrogen atom, a silicon atom and the like as a hetero atom, linked at an α-position of the hetero atom to form a dimer or a trimer (the following formulae 159 to 160), 5-membered ring heterocyclic groups containing an oxygen atom, a sulfur atom, a nitrogen atom, a silicon atom or the like as a hetero atom, linked at an a-position of the hetero atom to a phenyl group (the following formulae 161 to 166), 5-membered ring condensed heterocyclic groups containing an oxygen atom, a sulfur atom, a nitrogen atom and the like as a hetero atom, having a phenyl group, a furyl group or a thienyl group substituted thereon (the following formulae 167 to 172) and 6-membered ring heterocyclic groups containing an oxygen atom, a nitrogen atom and the like as a hetero atom (the following formulae 173 to 176). These groups may have a substituent.

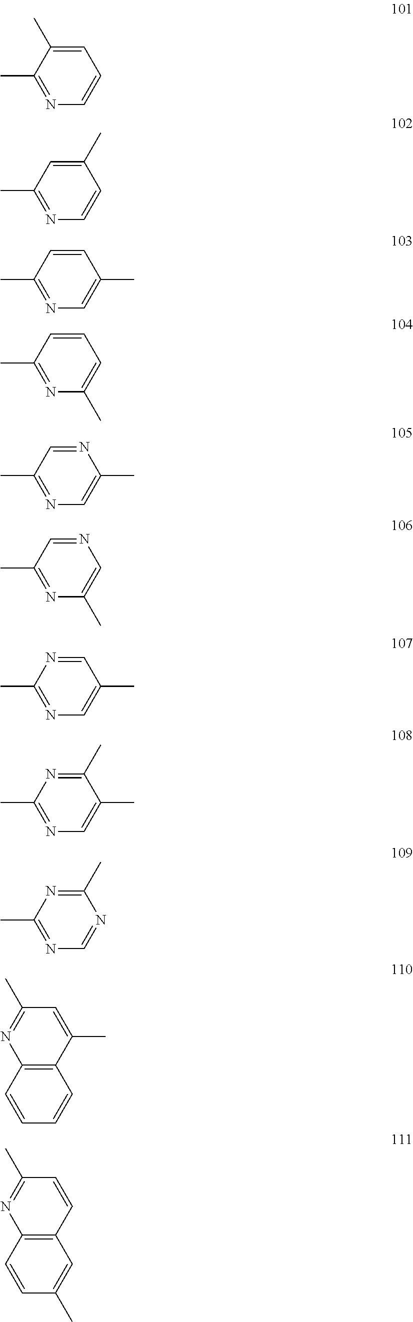

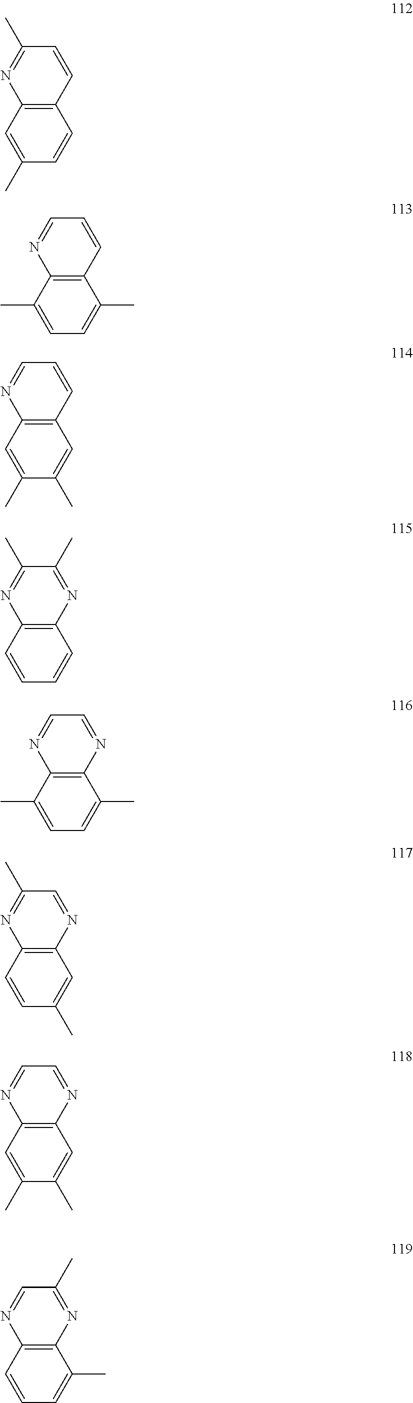

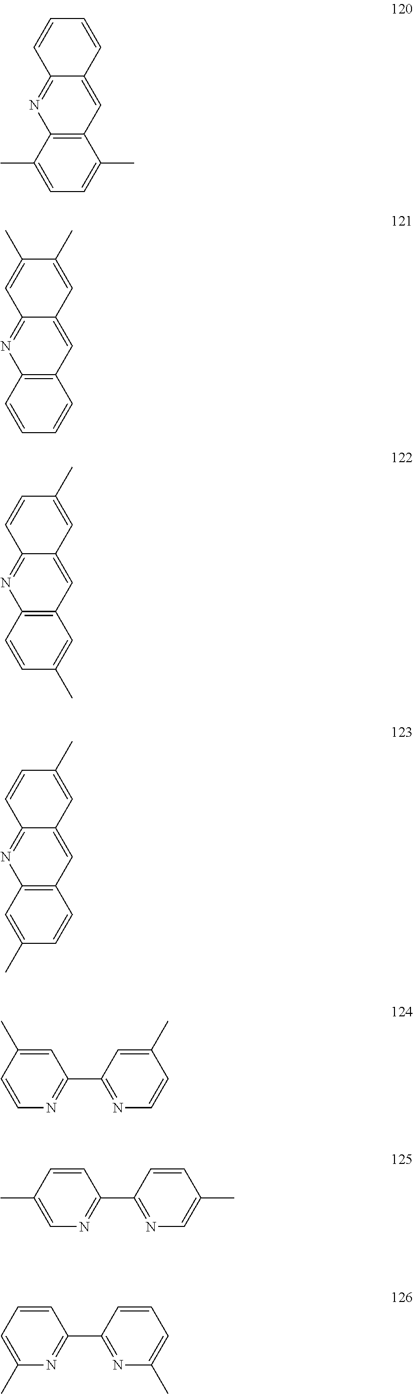

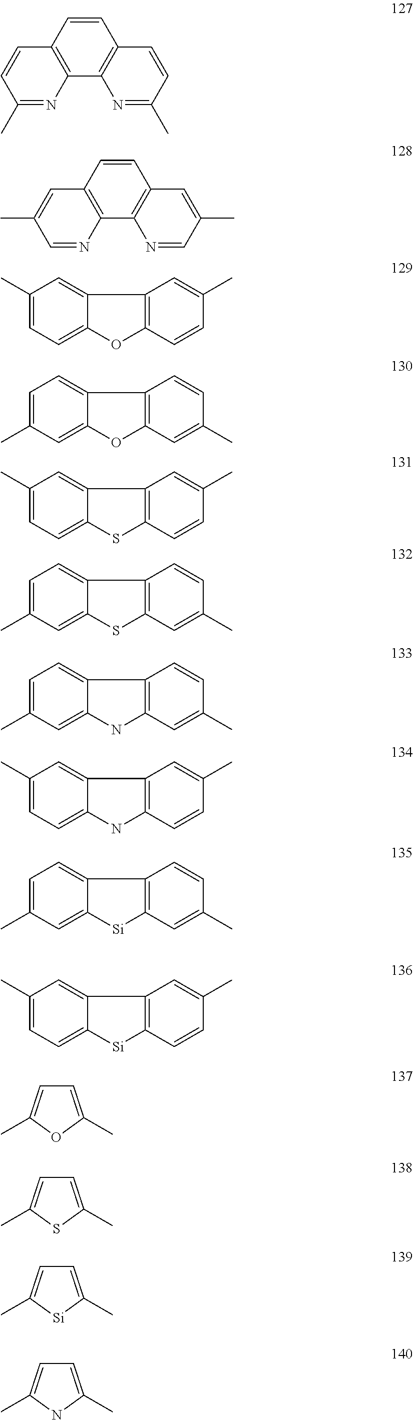

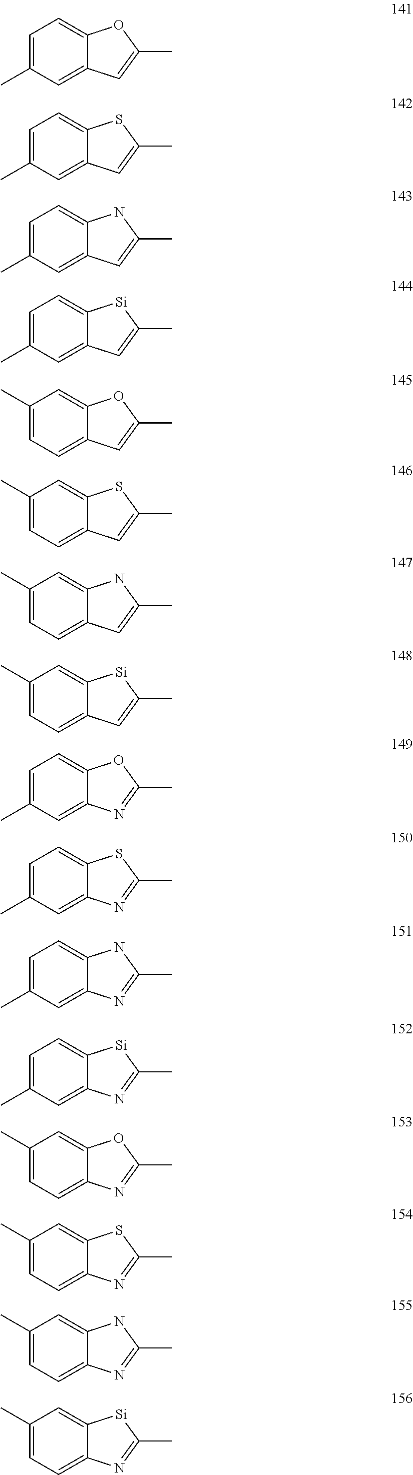

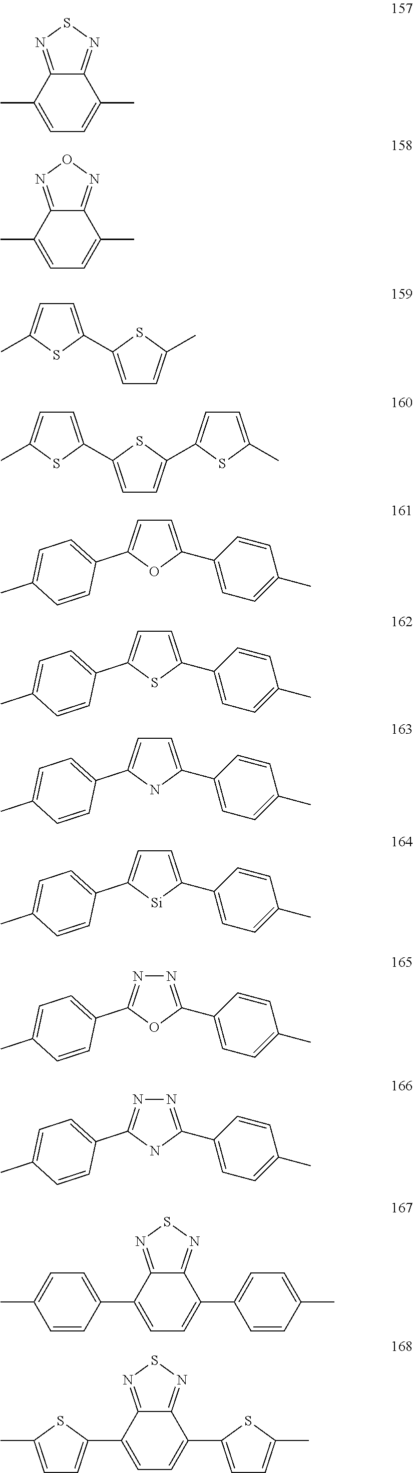

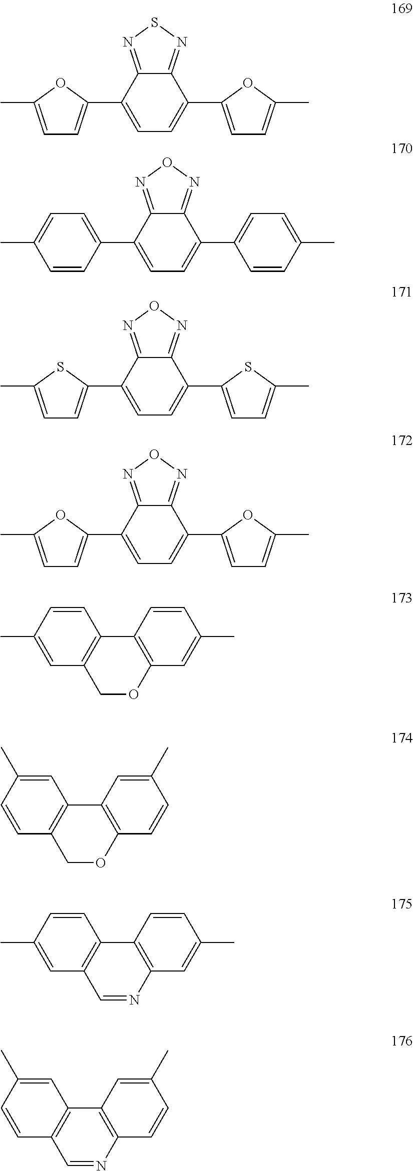

The di-valent heterocyclic group represented by the above-described Ar¹³ is preferably a di-valent heterocyclic group represented by the following formula (5), from the standpoint of the charge transportability of the polymer compound of the present invention, and this group may have a substituent.

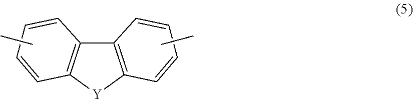

[wherein,

Y represents an oxygen atom, a sulfur atom, —N(R^{a})—, —O—C(R^{b}) (R^{c})— or —Si(R^{d}) (R^{e})—. R^{a}, R^{b}, R^{c}, R^{d} and R^{e} represent each independently a hydrogen atom, an alkyl group, an alkoxy group, an aryl group or an arylalkyl group, and these groups may have a substituent.].

In the above-described formula (5), Y is preferably an oxygen atom, a sulfur atom or —N(R^{a})—, more preferably an oxygen atom or —N(R^{a})—, from the standpoint of easiness of synthesis of the polymer compound of the present invention.

When the di-valent heterocyclic group represented by the above-described formula (5) has a substituent, the substituent includes a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and preferable from the standpoint of the solubility of the polymer compound of the present invention is an alkyl group, an alkoxy group, an aryl group, an aryloxy group, an arylalkyl group, an arylalkoxy group, a halogen atom or a cyano group. These groups have the same meaning as the groups represented by the above-described R¹ to R⁸.

The di-valent heterocyclic group represented by the above-described formula (5) is preferably a di-valent group represented by the following formula (5)-1 or the following formula (5)-2, from the standpoint of the charge transportability of the polymer compound of the present invention. These groups may have a substituent.

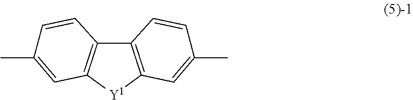

[wherein,

Y¹ represents an oxygen atom, a sulfur atom, —N(R^{a})—, —O—C(R^{b}) (R^{C})— or —Si(R^{d}) (R^{e})—.].

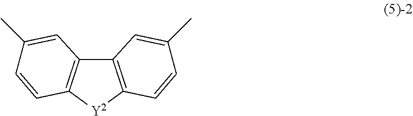

[wherein,

Y² represents an oxygen atom, a sulfur atom, —N(R^{a})—, —O—C(R^{b}) (R^{C})— or —Si(R^{d}) (R^{e})—.].

In the above-described formula (5)-1 and the above-described formula (5)-2, Y¹ and Y² are preferably an oxygen atom, a sulfur atom or —N(R^{a})—, more preferably an oxygen atom or —N(R^{a})—, particularly preferably an oxygen atom, from the standpoint of easiness of synthesis of the polymer compound of the present invention.

When the repeating unit represented by the above-described formula (5)-1 or the above-described formula (5)-2 has a substituent, the substituent includes an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a halogen atom, an acyl group, an acyloxy group, an imine residue, an amide group, an acid imide group, a mono-valent heterocyclic group, a carboxyl group, a substituted carboxyl group, a cyano group and a nitro group, and preferable from the standpoint of the solubility of the resultant polymer compound are an alkyl group, an alkoxy group, an aryl group, an aryloxy group, an arylalkyl group, an arylalkoxy group, a halogen atom and a cyano group. These groups have the same meaning as the groups represented by the above-described R¹ to R⁸, and further may have a substituent.

The repeating unit represented by the above-described formula (5)-1 or the above-described formula (5)-2 includes, for example, repeating units represented by the formulae (5-101) to (5-108). R^{a} and R represent each independently a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group. These groups may have a substituent. These groups have the same meaning as the groups represented by the above-described R¹ to R⁸.

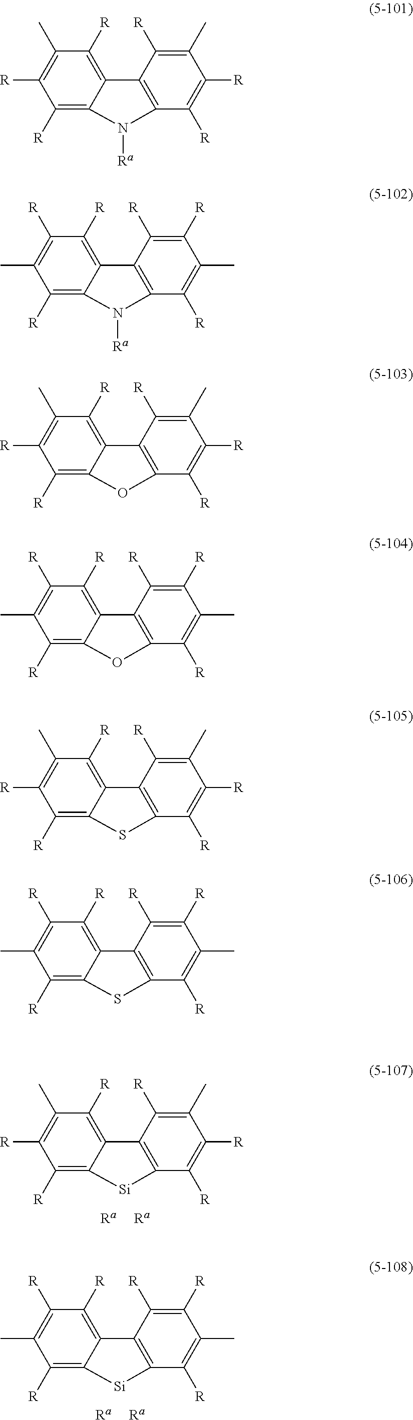

The di-valent heterocyclic group represented by the above-described Ar¹³ is preferably a di-valent heterocyclic group represented by the formula (6) from the standpoint of the charge transportability of the polymer compound of the present invention, and this group may have a substituent.

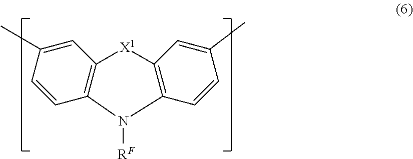

[wherein,

R^{F} represents a hydrogen atom, an alkyl group, an aryl group or a mono-valent heterocyclic group, and these groups may have a substituent.

X¹ represents an oxygen atom, a sulfur atom or a group represented by —C(R¹⁴)₂—. R¹⁴ represents an alkyl group or an aryl group, and these groups may have a substituent, and a plurality of R¹⁴ may be mutually the same or different.].

As the alkyl group represented by the above-described R^{F}, for example, C₁ to C₂₀ alkyl groups can be selected. As the aryl group represented by the above-described R^{F}, for example, a phenyl group, a 1-naphthyl group, a 2-naphthyl group, a 1-anthracenyl group, a 2-anthracenyl group, a 9-anthracenyl group or a 2-fluorenyl group can be selected. As the mono-valent heterocyclic group represented by the above-described R^{F}, for example, a pyridyl group, a pyrimidyl group, a triazyl group or a quinolyl group can be selected. These groups may have a substituent.

When the group represented by the above-described R^{F} has a substituent, the substituent includes an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group and a cyano group, preferably an alkyl group, an alkoxy group, an aryl group, an aryloxy group, an arylalkyl group, an arylalkoxy group, a substituted amino group, an acyl group or a cyano group, further preferably an alkyl group, an alkoxy group or an aryl group. These groups have the same meaning as the groups represented by the above-described R¹ to R⁸.

The above-described X¹ is preferably an oxygen atom, because of more excellent luminance life of light emitting device in which the polymer compound of the present invention is used.

As the alkyl group represented by the above-described R¹⁴, for example, C₁ to C₂₀ alkyl groups can be selected. As the aryl group represented by the above-described R¹⁴, for example, a phenyl group, a 1-naphthyl group, a 2-naphthyl group, a 1-anthracenyl group, a 2-anthracenyl group, a 9-anthracenyl group or a 2-fluorenyl group can be selected. These groups may have a substituent.

When the group represented by the above-described R¹⁴ has a substituent, the substituent includes an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group and a cyano group, preferably an alkyl group, an alkoxy group, an aryl group, an aryloxy group, an arylalkyl group, an arylalkoxy group, a substituted amino group, an acyl group or a cyano group, further preferably an alkyl group, an alkoxy group or an aryl group. These groups have the same meaning as the groups represented by the above-described R¹ to R⁸.

The di-valent heterocyclic group represented by the above-described formula (6) includes, for example, groups represented by the following formulae (6-1), (6-2) and (6-3).

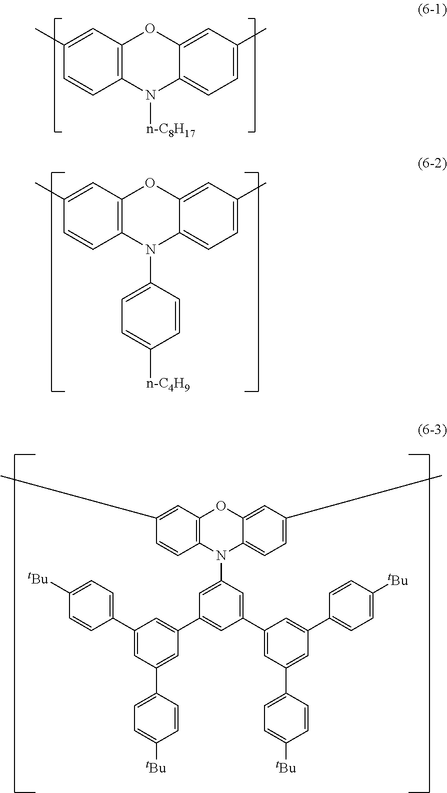

In the above-described formula (3), the di-valent group having a metal complex structure represented by Ar¹³ is an atomic group remaining after removing two hydrogen atoms from an organic ligand of a metal complex having an organic ligand.

The organic ligand has a number of carbon atoms of usually 4 to 60. The organic ligand includes, for example, 8-quinolinol and derivatives thereof, benzoquinolinol and derivatives thereof, 2-phenyl-pyridine and derivatives thereof, 2-phenyl-benzothiazole and derivatives thereof, 2-phenyl-benzoxazole and derivatives thereof and porphyrin and derivatives thereof. The central metal of the metal complex includes, for example, aluminum, zinc, beryllium, iridium, platinum, gold, europium and terbium.

The metal complex having an organic ligand includes, for example, metal complexes and triplet light emitting complexes known as low molecular weight fluorescent or phosphorescent materials.

The di-valent group having a metal complex structure includes, for example, repeating units represented by the following formulae 201 to 207.

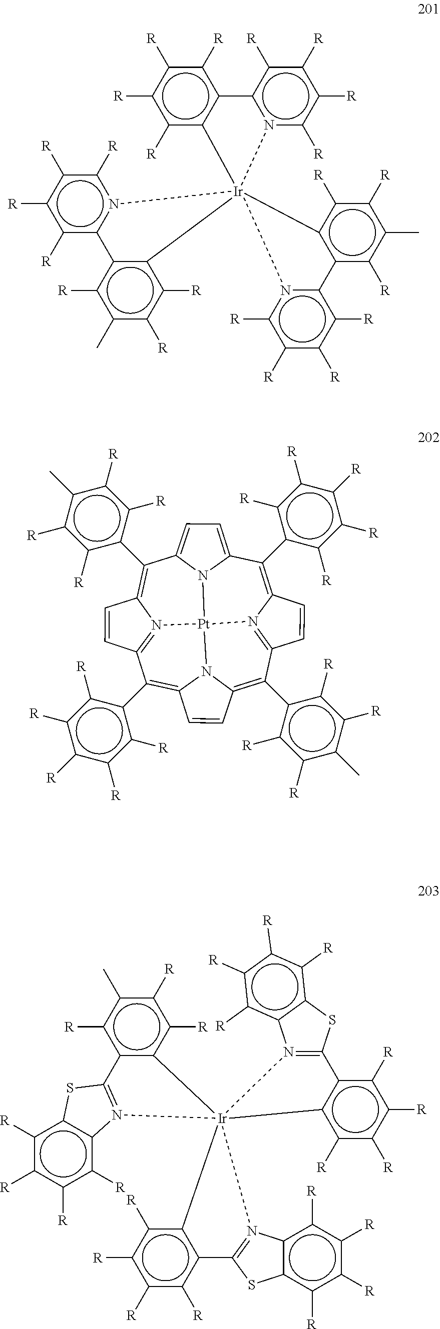

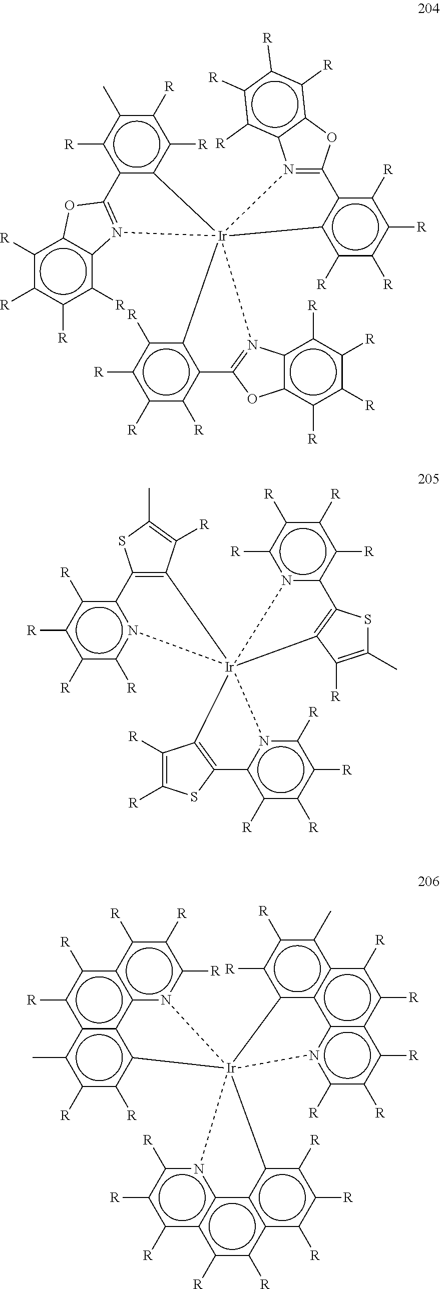

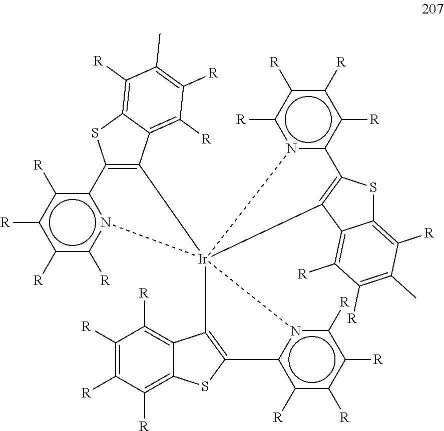

In the above-described formulae 201 to 207, R represents a hydrogen atom, a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group. In these formulae, a plurality of R may be the same or different. These groups have the same meaning as the groups represented by the above-described R¹ to R⁸.

The polymer compound of the present invention may further contain a repeating unit represented by the following formula (7).

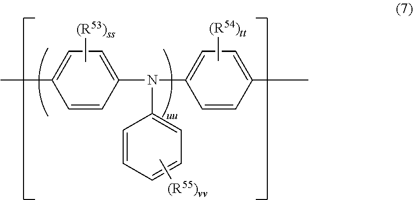

[wherein,

ss and tt are each independently an integer of 0 to 4, uu is 1 or 2 and vv is an integer of 0 to 5.

R⁵³, R⁵⁴ and R⁵⁵ represent each independently an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group or a cyano group. When there are a plurality of R⁵³, R⁵⁴ and R⁵⁵, these may be the same or different, respectively. These groups have the same meaning as the groups represented by the above-described R¹ to R⁸.].

The repeating unit represented by the formula (7) includes, for example, repeating units represented by the following formulae (7-1) and (7-2).

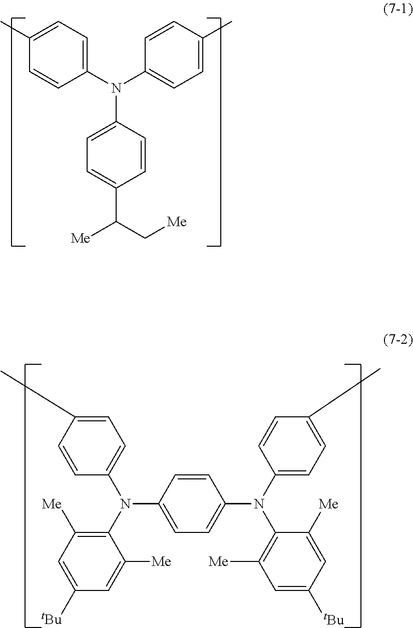

It is preferable that the polymer compound of the present invention further contains at least one of a repeating unit represented by the formula (2A) and a repeating unit represented by the formula (3A), in addition to the repeating unit represented by the above-described formula (1).

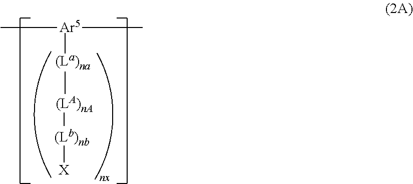

[wherein,

na represents an integer of 0 to 3, nb represents an integer of 0 to 12, nA is 0 or 1 and nx represents an integer of 1 to 4.

Ar⁵ represents a (2+nx)-valent aromatic hydrocarbon group or a (2+nx)-valent heterocyclic group, and these groups may have a substituent.

L^{a} and L^{b} represent each independently an alkylene group or a phenylene group, and these groups may have a substituent. When there are a plurality of L^{a}, these may be the same or different. When there are a plurality of L^{b}, these may be the same or different.

L^{A} represents an oxygen atom or a sulfur atom. When there are a plurality of L^{A}, these may be the same or different.

X represents a mono-valent cross-linkable group. When there are a plurality of X, these may be the same or different.].

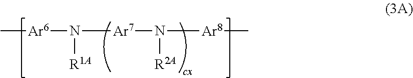

[wherein,

c represents 0 or 1,

Ar⁶ and Ar⁸ represent each independently an arylene group or a di-valent heterocyclic group, and these groups may have a substituent,

Ar⁷ represents an arylene group, a di-valent heterocyclic group or a di-valent group obtained by linking two or more identical or different groups selected from arylene groups and di-valent heterocyclic groups, and these groups may have a substituent.

R^{1A} represents a mono-valent cross-linkable group,

R^{2A} represents a mono-valent cross-linkable group, an alkyl group, an aryl group or a mono-valent heterocyclic group, and these groups may have a substituent (not including a cross-linkable group).].

In the formula (2A), na represents an integer of 0 to 3, and is preferably 0 to 2, more preferably 0 or 1, further preferably 0, since synthesis of a monomer as a raw material of the polymer compound of the present embodiment is easy.

In the formula (2A), nb represents an integer of 0 to 12, and is preferably 0 to 10, more preferably 0 to 8, since synthesis of a monomer as a raw material of the polymer compound of the present embodiment is easy.

In the formula (2A), nA represents 0 or 1, and is preferably 0, since a light emitting device produced by using the polymer compound of the present embodiment is excellent in luminance life.

In the formula (2A), nx represents an integer of 1 to 4, and is preferably an integer of 1 to 3, more preferably 2, since a light emitting device produced by using the polymer compound of the present embodiment is more excellent in hole transportability and durability.

In the formula (2A), the unsubstituted or substituted (2+nx)-valent aromatic hydrocarbon group represented by Ar^{y} has a number of carbon atoms of usually 6 to 60, preferably 6 to 48, more preferably 6 to 20, further preferably 6 to 14. The (2+nx)-valent aromatic hydrocarbon group is preferably a 2-, 3-, 4- or 5-valent aromatic hydrocarbon group, more preferably a 3- or 4-valent aromatic hydrocarbon group. Here, the “(2+nx)-valent aromatic hydrocarbon group” denotes an atomic group remaining after removing (2+nx) hydrogen atoms linking directly to carbon atoms constituting the ring from an aromatic hydrocarbon group, and includes groups having a benzene ring and groups having a condensed ring. The above-described number of carbon atoms does not include the number of carbon atoms of a substituent.

The above-described aromatic hydrocarbon compound includes, for example, benzene, naphthalene, anthracene, tetracene, pyrene, perylene, fluorene, benzofluorene, phenanthrene, dihydrophenanthrene, chrysene and coronene; and benzene, naphthalene, anthracene, pyrene, fluorene, benzofluorene, phenanthrene and dihydrophenanthrene are preferable, benzene, naphthalene and fluorene are more preferable, since the polymer compound of the present embodiment is more excellent in stability and a light emitting device produced by using the polymer compound is more excellent in hole transportability.

In the formula (2A), the unsubstituted or substituted (2+nx)-valent heterocyclic group represented by Ar⁵ has a number of carbon atoms of usually 3 to 60, preferably 3 to 20. The (2+nx)-valent heterocyclic group is preferably a 2-, 3-, 4- or 5-valent heterocyclic group, more preferably a 2-, 3- or 4-valent heterocyclic group. Here, the “(2+nx)-valent heterocyclic group” denotes an atomic group remaining after removing (2+nx) hydrogen atoms linking directly to carbon atoms constituting the ring from a heterocyclic compound, and includes monocylic groups and groups having a condensed ring. The above-described number of carbon atoms does not include the number of carbon atoms of a substituent.

The above-described heterocyclic compound includes, for example, pyridine, pyrimidine, triazine, quinoline, isoquinoline, quinoxaline, dibenzofuran, dibenzothiophene, carbazole, phenoxazine, phenothiazine, benzothiadiazole and dibenzosilole.

When the group represented by Ar⁵ has a substituent in the formula (2A), the substituent is preferably an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group or a cyano group, more preferably an alkyl group, an alkoxy group, an aryl group, an aryloxy group, an arylalkyl group, an arylalkoxy group, a substituted amino group, an acyl group or a cyano group, further preferably an alkyl group, an alkoxy group or an aryl group.

The definitions and specific examples of the alkyl group, the alkoxy group, the aryl group, the aryloxy group, the arylalkyl group, the arylalkoxy group, the arylalkenyl group, the arylalkynyl group, the substituted amino group, the halogen atoms, the acyl group, the acyloxy group and the mono-valent heterocyclic group are the same as the definitions and specific examples of the alkyl group, the alkoxy group, the aryl group, the aryloxy group, the arylalkyl group, the arylalkoxy group, the arylalkenyl group, the arylalkynyl group, the substituted amino group, the halogen atoms, the acyl group, the acyloxy group and the mono-valent heterocyclic group represented by R¹ to R⁸ in the above-described formula (1).

In the formula (2A), Ar⁵ is preferably an unsubstituted or substituted aromatic hydrocarbon group, since a light emitting device produced by using the polymer compound of the present embodiment is excellent in hole transportability and durability.

In the formula (2A), the alkylene group represented by L^{a} and L^{b} may be any of linear, branched or cyclic, and may have a substituent. It is preferably a linear alkylene group, since synthesis of a monomer as a raw material of the polymer compound of the present embodiment is easy. The linear alkylene group and the branched alkylene group have a number of carbon atoms of usually 1 to 20, preferably 1 to 10, more preferably 1 to 6. The cyclic alkylene group has a number of carbon atoms of usually 3 to 20, preferably 3 to 10, more preferably 3 to 6.

The alkylene group includes, for example, a methylene group, a 1,2-ethylene group, a 1,3-propylene group, a 1,3-butylene group, a 1,3-pentylene group, a 1,4-pentylene group, a 1,5-pentylene group, a 1,4-hexylene group, a 1,6-hexylene group, a 1,7-heptylene group, a 1,6-octylene group and a 1,8-octylene group.

In the formula (2A), the phenylene group represented by L^{a} and L^{b} may have a substituent. The phenylene group includes, for example, an o-phenylene group, a m-phenylene group and a p-phenylene group. The substituent which the phenylene group may have includes an alkyl group, an alkoxy group, a halogen atom and a cyano group.

The definitions and specific examples of the alkyl group, the alkoxy group and the halogen atom are the same as the definitions and specific examples of the alkyl group, the alkoxy group and the halogen atom represented by R¹ to R⁸ in the above-described formula (1).

In the formula (2A), L^{a} represents preferably a phenylene group, since synthesis of a monomer as a raw material of the polymer compound of the present embodiment is easy.

In the formula (2A), L^{b} represents preferably an alkylene group, since synthesis of a monomer as a raw material of the polymer compound of the present embodiment is easy.

In the formula (2A), L^{A} represents an oxygen atom or a sulfur atom, and preferable is an oxygen atom, since synthesis of a monomer as a raw material of the polymer compound of the present embodiment is easy.

In the formula (2A), X represents a mono-valent cross-linkable group.

X includes, for example, an unsubstituted or substituted aziridinyl group, an unsubstituted or substituted azetidinyl group, an azide group, an unsubstituted or substituted epoxy group, an unsubstituted or substituted oxetanyl group, an unsubstituted or substituted alkenyl group, an unsubstituted or substituted alkynyl group and a group having a cyclobutene structure, and preferable is an unsubstituted or substituted aziridinyl group, an azide group, an unsubstituted or substituted epoxy group, an unsubstituted or substituted oxetanyl group, an unsubstituted or substituted alkenyl group, an unsubstituted or substituted alkynyl groups, an unsubstituted or substituted aryl group having a cyclobutene structure or an unsubstituted or substituted mono-valent heterocyclic group having a cyclobutene structure, more preferable is an unsubstituted or substituted alkenyl group, an unsubstituted or substituted aryl group having a cyclobutene structure or an unsubstituted or substituted mono-valent heterocyclic group having a cyclobutene structure, further preferable is an unsubstituted or substituted alkenyl group or an unsubstituted or substituted aryl group having a cyclobutene structure, since synthesis of a monomer as a raw material of the polymer compound of the present embodiment is easy.

In the formula (2A), X includes, for example, groups represented by the following formulae (X-1), (X-2), (X-01) to (X-19), and preferable are groups represented by the formulae (X-1), (X-2), (X-01), (X-03), (X-04), (X-06) to (X-18), more preferable are groups represented by the formulae (X-1), (X-2), (X-09) to (X-18), further preferable are groups represented by the formulae (X-1) and (X-2), since synthesis of a monomer as a raw material of the polymer compound of the present embodiment is easy.

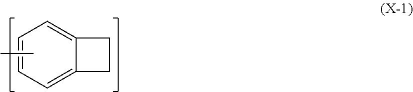

In the formula (X-1), benzocyclobutene may have a substituent. The substituent in the formula (X-1) is a hydrogen atom, an alkyl group, an alkoxy group, an aryl group, an aryloxy group, an amino group, a substituted amino group, a halogen atom, an acyl group, an acyloxy group, a mono-valent heterocyclic group, a carboxyl group, a substituted carboxyl group, a cyano group or a nitro group.

The definitions and specific examples of the alkyl group, the alkoxy group, the aryl group, the aryloxy group, the substituted amino group, the halogen atom, the acyl group, the acyloxy group, the mono-valent heterocyclic group and the substituted carboxyl group are the same as the definitions and specific examples of the alkyl group, the alkoxy group, the aryl group, the aryloxy group, the amino group, the substituted amino group, the halogen atom, the acyl group, the acyloxy group, the mono-valent heterocyclic group and the substituted carboxyl group represented by R¹ to R⁸ in the above-described formula (1).

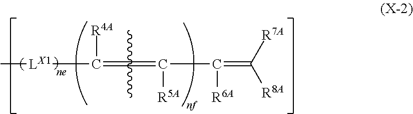

In the formula (X-2), ne and of represent each independently 0 or 1.

L^{X1} represents an oxygen atom, a sulfur atom, a carbonyl group or a group represented by —O—CO—.

R^{4A}, R^{5A}, R^{6A}, R^{7A} and R^{8A} represent each independently a hydrogen atom, an alkyl group, an alkoxy group, an aryl group, an aryloxy group, a mono-valent heterocyclic group, an amino group, a substituted amino group, an acyl group, an acyloxy group, a halogen atoms, a cyano group or a nitro group.

The definitions and specific examples of the alkyl group, the alkoxy group, the aryl group, the aryloxy group, the mono-valent heterocyclic group, the substituted amino group, the acyl group, the acyloxy group and the halogen atom are the same as the definitions and specific examples of the alkyl group, the alkoxy group, the aryl group, the aryloxy group, the mono-valent heterocyclic group, the substituted amino group, the acyl group, the acyloxy group and the halogen atom represented by R¹ to R⁸ in the above-described formula (1).

In the formula (X-2), a wavy line means that the compound having a double bond containing the wavy line may be any of E-form, Z-form or a mixture of E-form and Z-form.

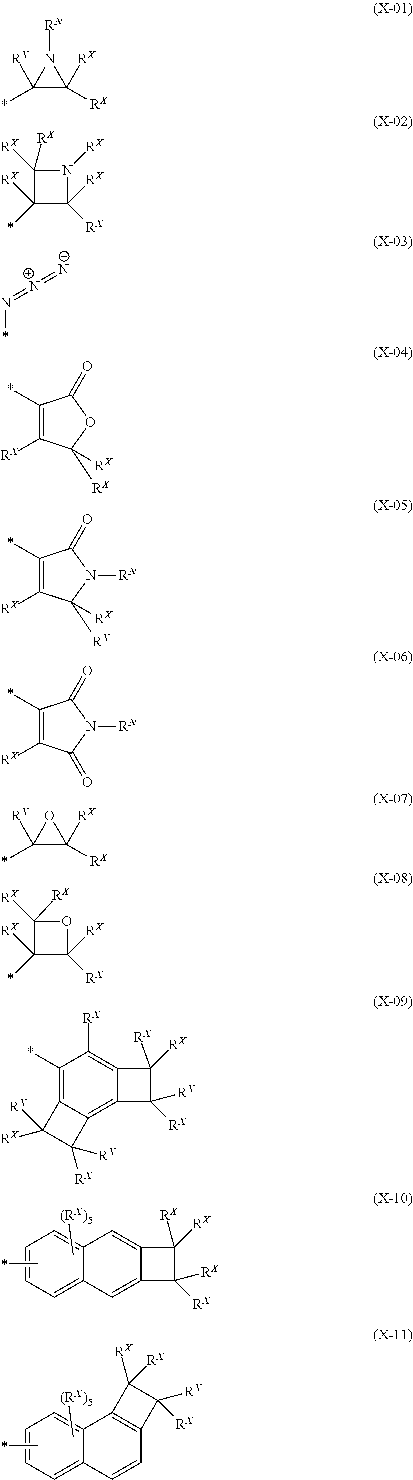

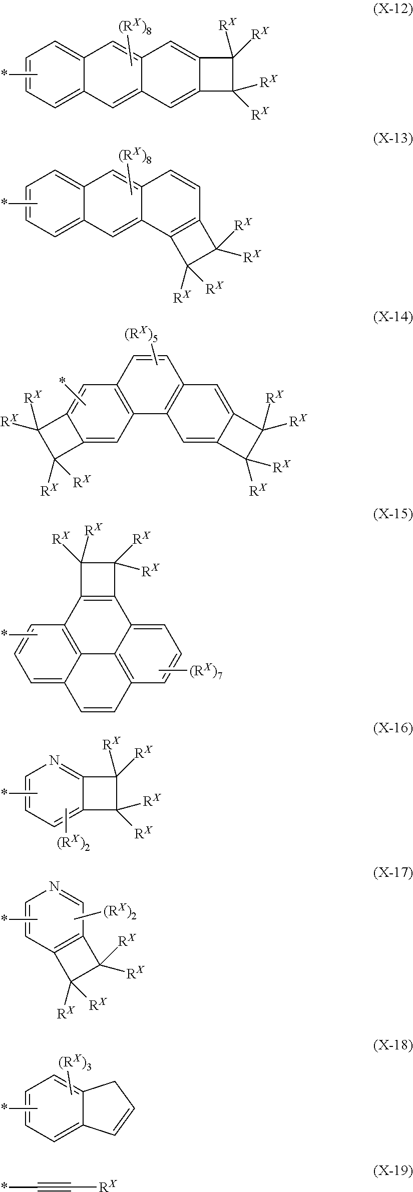

In the formulae (X-01) to (X-19),

R^{X} represents a hydrogen atom, an alkyl group, an alkoxy group, an aryl group, an aryloxy group, an amino group, a substituted amino group, a halogen atom, an acyl group, an acyloxy group, a mono-valent heterocyclic group, a carboxyl group, a substituted carboxyl group, a cyano group or a nitro group. A plurality of R^{x} may be the same or different.

The definitions and specific examples of the alkyl group, the alkoxy group, the aryl group, the aryloxy group, the substituted amino group, the halogen atom, the acyl group, the acyloxy group, the mono-valent heterocyclic group and the substituted carboxyl group are the same as the definitions and specific examples of the alkyl group, the alkoxy group, the aryl group, the aryloxy group, the substituted amino group, the halogen atom, the acyl group, the acyloxy group, the mono-valent heterocyclic group and the substituted carboxyl group represented by R¹ to R⁸ in the above-described formula (1).

R^{X} is preferably a hydrogen atom, an alkyl group, an alkoxy group, an aryl group, an aryloxy group or a mono-valent heterocyclic group, more preferably a hydrogen atom, an unsubstituted or substituted alkyl group, an unsubstituted or substituted alkoxy group or an unsubstituted or substituted aryl group, since synthesis of a monomer as a raw material of the polymer compound of the present embodiment is easy.

R^{N} represents a hydrogen atom, an alkyl group, an acyl group, an aryl group or a mono-valent heterocyclic group.

The definitions and specific examples of the alkyl group, the acyl group, the aryl group and the mono-valent heterocyclic group are the same as the definitions and specific examples of the alkyl group, the acyl group, the aryl group and the mono-valent heterocyclic group represented by R¹ to R⁸ in the above-described formula (1).

R^{N} is preferably an alkyl group, an acyl group or a mono-valent heterocyclic group, each substituted by an aryl group, since synthesis of a monomer as a raw material of the polymer compound of the present embodiment is easy.

In the formulae (X-01) to (X-19), “*” represents a connecting bond.

The group represented by the formula (X-1) includes groups represented by the following formula (X-1-1) or (X-1-2), and preferable are groups represented by the formula (X-1-1), since synthesis of a monomer as a raw material of the polymer compound of the present embodiment is easy.

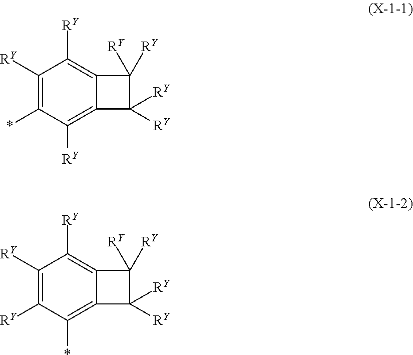

In the formulae (X-1-1) and (X-1-2),

R^{Y} represents a hydrogen atom, an alkyl group, an alkoxy group, an aryl group, an aryloxy group, a substituted amino group, a halogen atom, an acyl group, an acyloxy group, a mono-valent heterocyclic group, a carboxyl group, a substituted carboxyl group, a cyano group or a nitro group. A plurality of R^{Y} may be the same or different.

The definitions and specific examples of the alkyl group, the alkoxy group, the aryl group, the aryloxy group, the substituted amino group, the halogen atom, the acyl group, the acyloxy group, the mono-valent heterocyclic group and the substituted carboxyl group are the same as the definitions and specific examples of the alkyl group, the alkoxy group, the aryl group, the aryloxy group, the substituted amino group, the halogen atom, the acyl group, the acyloxy group, the mono-valent heterocyclic group and the substituted carboxyl group represented by R¹ to R⁸ in the above-described formula (1).

R^{Y} is preferably a hydrogen atom, an alkyl group, an alkoxy group, an aryl group, an aryloxy group or a mono-valent heterocyclic group, more preferably a hydrogen atom, an alkyl group, an alkoxy group or an aryl group, further preferably a hydrogen atom or an alkyl group, since synthesis of a monomer as a raw material of the polymer compound of the present embodiment is easy. In the formulae (X-1-1) and (X-1-2), “*” represents a connecting bond.

In the formula (X-2), ne represents 0 or 1, and preferable is 0 since a light emitting device produced by using the polymer compound of the present embodiment is more excellent in hole transportability and durability.

In the formula (X-2), of represents 0 or 1, and preferable is 0 since synthesis of a monomer as a raw material of the polymer compound of the present embodiment is easy.

In the above-described formula (X-2), L^{X1} represents an oxygen atom, a sulfur atom, a carbonyl group or a group represented by —O—CO—, and preferable is a carbonyl group or a group represented by —O—CO—, since synthesis of a monomer as a raw material of the polymer compound of the present embodiment is easy.

In the formula (X-2), R^{4A}, R^{5A}, R^{6A}, R^{7A} and R^{8A} represent preferably a hydrogen atom, an alkyl group, an alkoxy group, an aryl group, an aryloxy group, a mono-valent heterocyclic group, a halogen atom or a cyano group, more preferably a hydrogen atom, an alkyl group or a fluorine atom, further preferably a hydrogen atom, since a light emitting device produced by using the polymer compound of the present embodiment is more excellent in hole transportability and durability.

The definitions and specific examples of the alkyl group, the alkoxy group, the aryl group, the aryloxy group, the mono-valent heterocyclic group and the halogen atom are the same as the definitions and specific examples of the alkyl group, the alkoxy group, the aryl group, the aryloxy group, the mono-valent heterocyclic group and the halogen atom represented by R¹ to R⁸ in the above-described formula (1).

The repeating unit represented by the formula (2A) is preferably a repeating unit represented by the following formula (4A), since a light emitting device produced by using the polymer compound of the present embodiment is more excellent in hole transportability and durability.

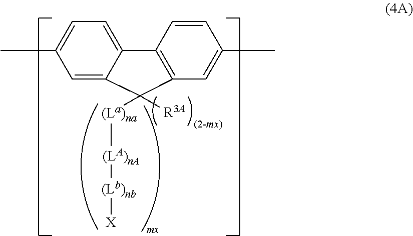

L^{a}, L^{b}, L^{A}, na, nb, nA and X represent each the same meaning as described above.

mx represents 1 or 2. mx is preferably 2 since a light emitting device produced by using the polymer compound of the present embodiment is more excellent in hole transportability and durability.

R^{3A} represents a hydrogen atom, an alkyl group, an alkoxy group, an aryl group, an aryloxy group or a mono-valent heterocyclic group.

The definitions and specific examples of the alkyl group, the alkoxy group, the aryl group, the aryloxy group and the mono-valent heterocyclic group are the same as the definitions and specific examples of the alkyl group, the alkoxy group, the aryl group, the aryloxy group and the mono-valent heterocyclic group represented by R¹ to R⁸ in the above-described formula (1).

In the formula (4A), R^{3A} is preferably an alkyl group or an aryl group, more preferably an aryl group having a substituent, further preferably an aryl group substituted by an alkyl group, since a light emitting device obtained by using the polymer compound of the present embodiment is more excellent in hole transportability and durability.

The definitions and specific examples of the alkyl group and the aryl group are the same as the definitions and specific examples of the alkyl group and the aryl group represented by R¹ to R⁸ in the above-described formula (1).

In the formula (4A), the fluorene ring may have a substituent, the substituent is preferably an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group or a cyano group, more preferably an alkyl group, an alkoxy group, an aryl group, an aryloxy group, an arylalkyl group, an arylalkoxy group, a substituted amino group, an acyl group or a cyano group, further preferably an alkyl group, an alkoxy group or an aryl group.

As the repeating unit represented by the formula (2A), repeating units represented by the following formulae (2-101) to (2-144) are preferable, repeating units represented by the formulae (2-101) to (2-103), (2-109), (2-111), (2-112), (2-114) to (2-117), (2-123) and (2-130) to (2-141) are more preferable, repeating units represented by the formulae (2-101) to (2-103), (2-109), (2-111) (2-112), (2-115), (2-117), (2-130), (2-132), (2-134), (2-135) and (2-138) to (2-141) are further preferable, repeating units represented by the formulae (2-101), (2-103), (2-109), (2-111), (2-115), (2-117), (2-130), (2-132), (2-134), (2-138) and (2-140) are particularly preferable.

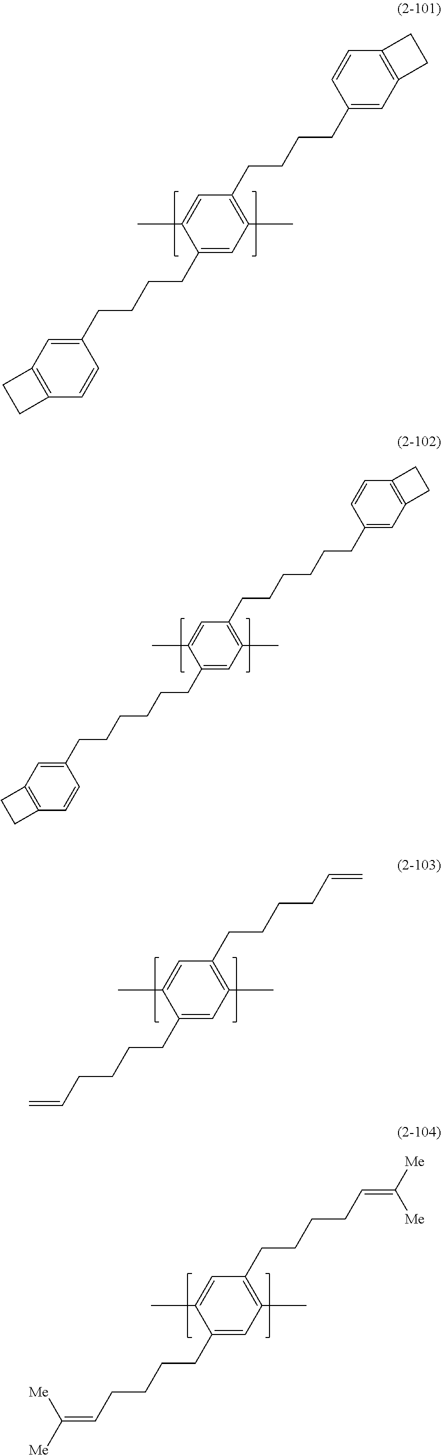

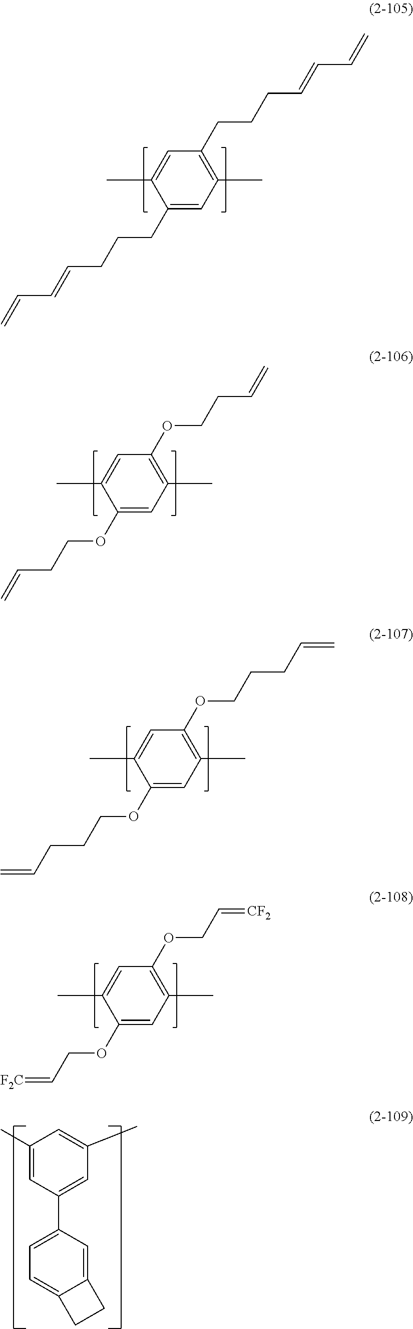

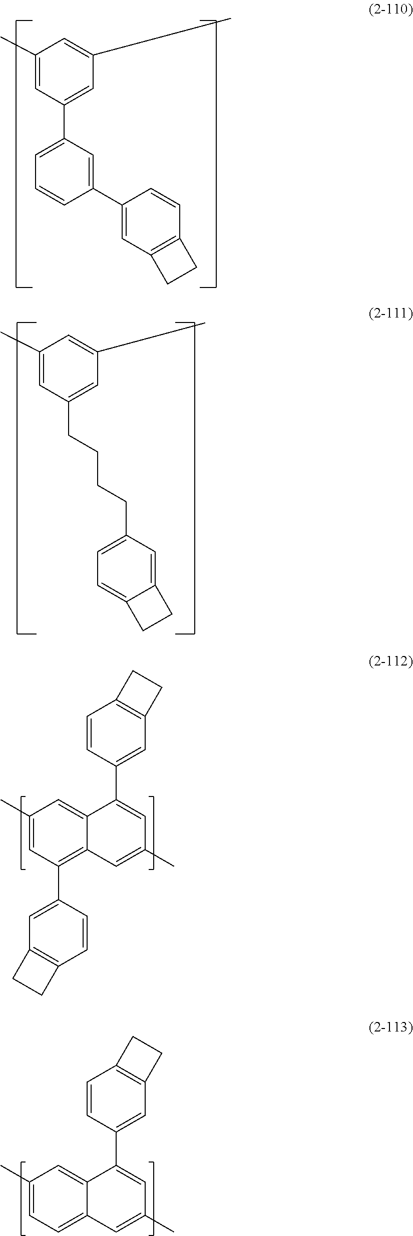

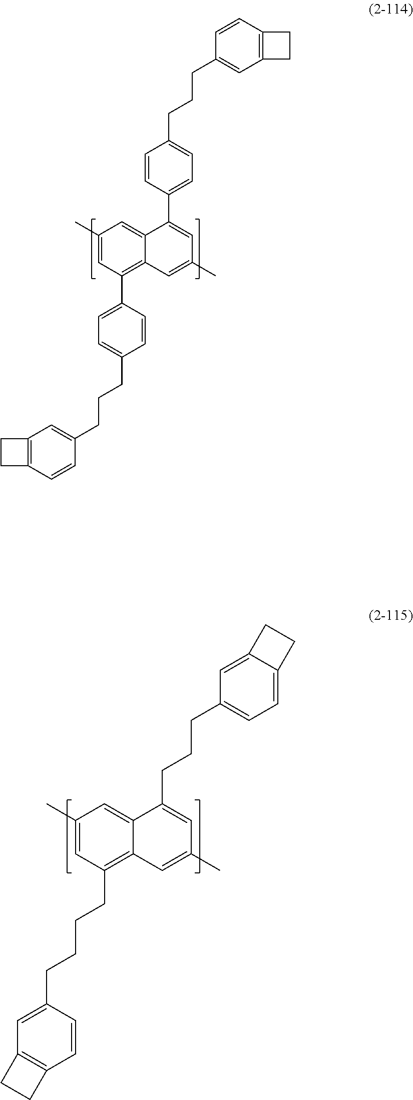

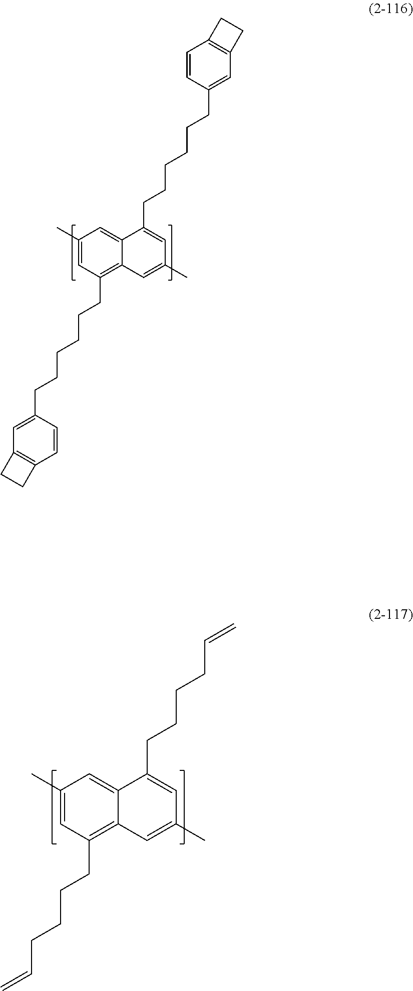

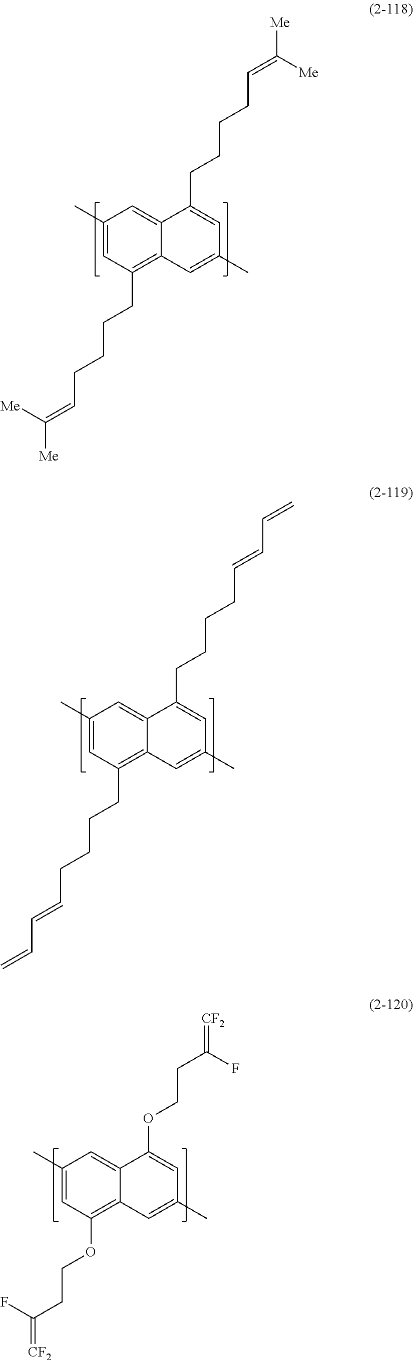

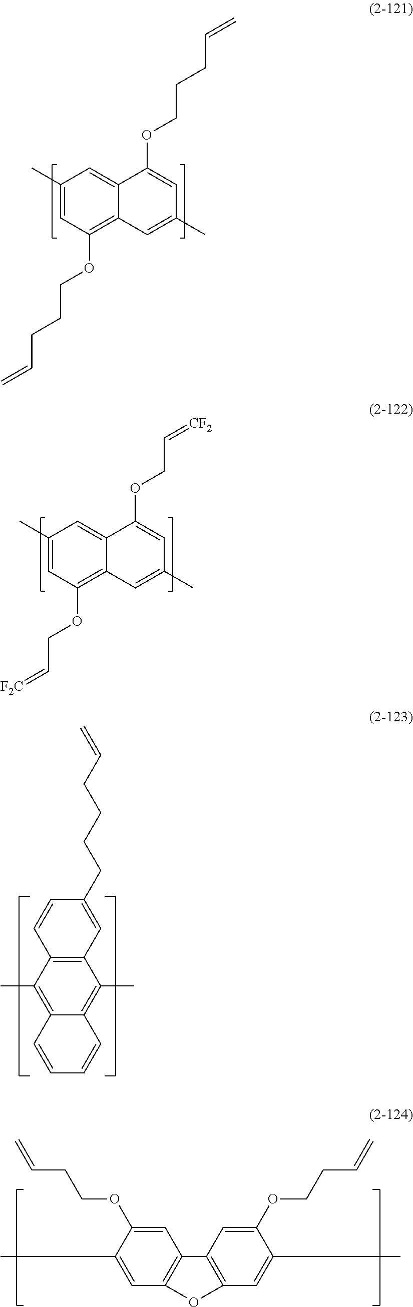

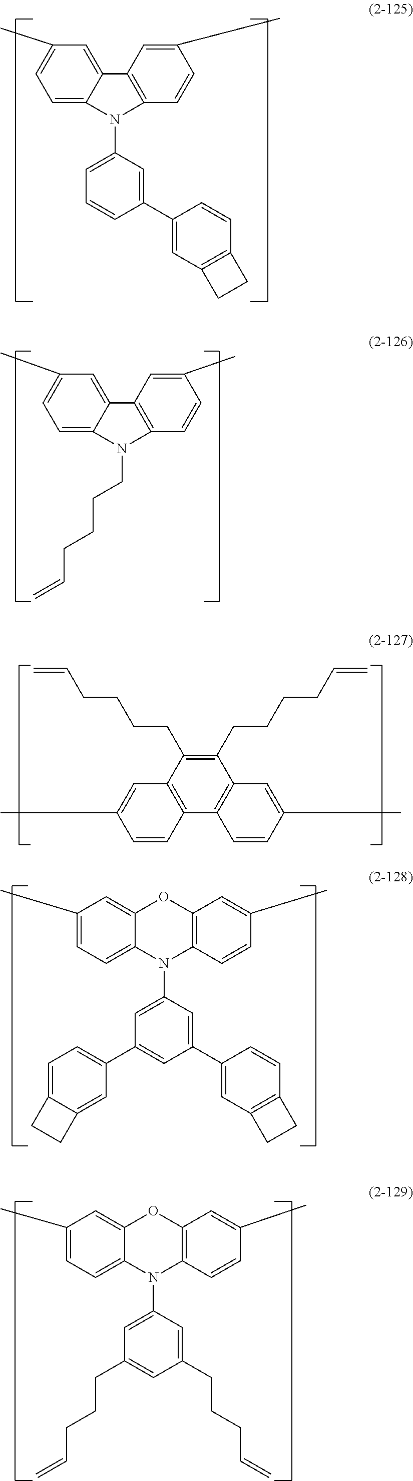

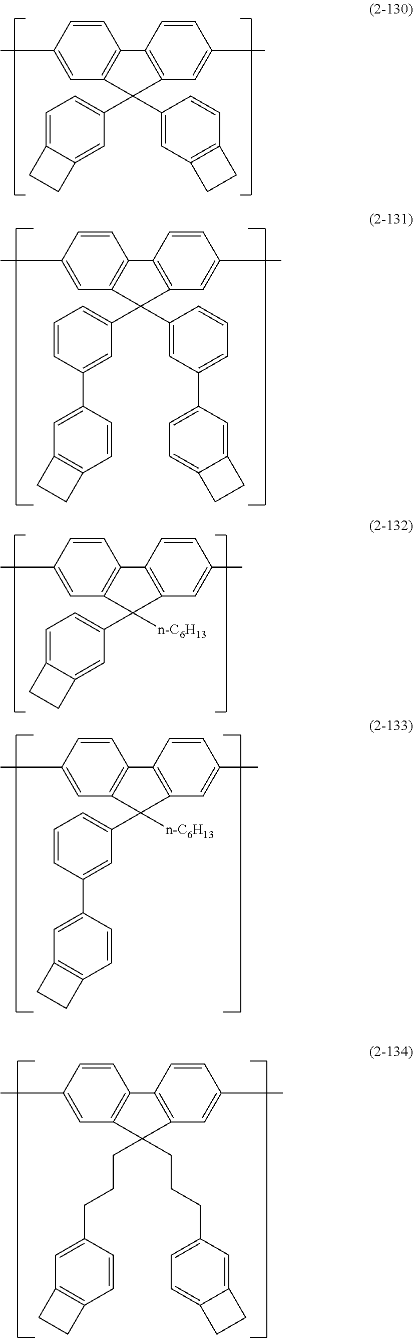

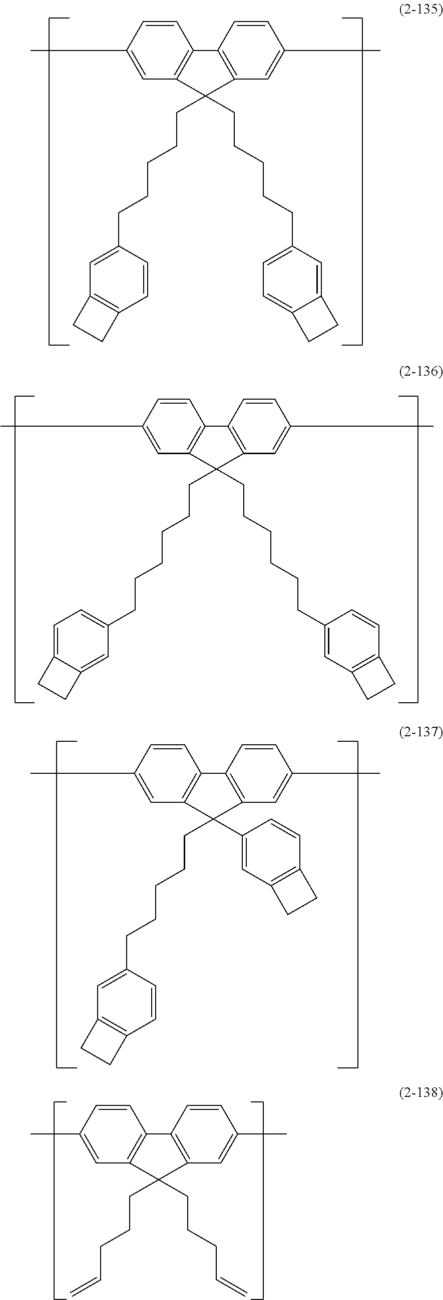

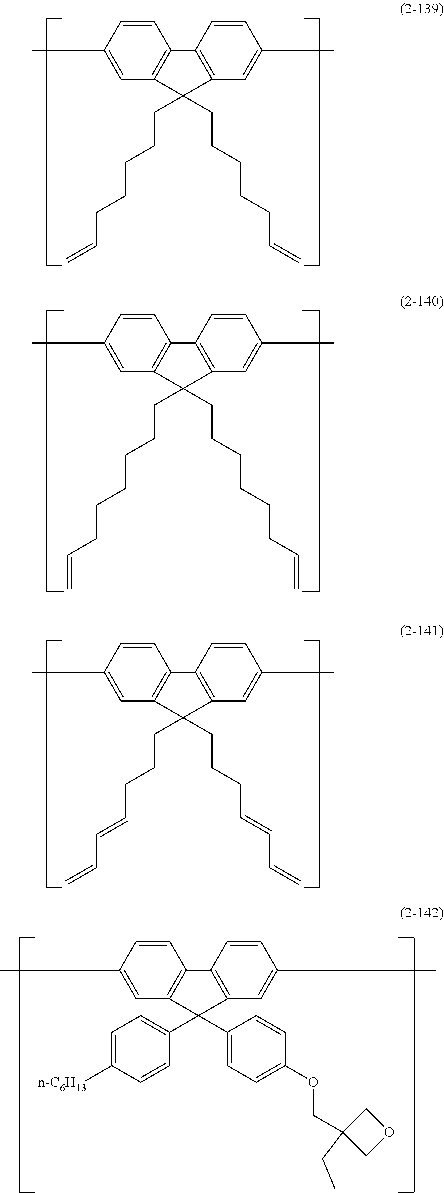

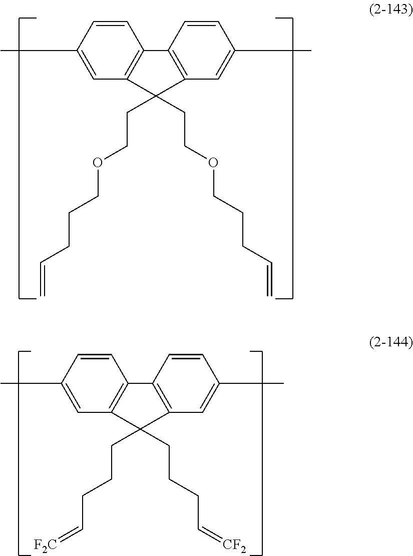

The content of the repeating unit represented by the formula (2A) is preferably 0.5 to 40% by mol, more preferably 3 to 30% by mol, further preferably 3 to 20% by mol with respect to the sum of all repeating units, since a light emitting device produced by using the polymer compound of the present embodiment is excellent in hole transportability and durability.

In the formula (3A), Ar⁶ and Ar⁸ represent each independently an arylene group or a di-valent heterocyclic group, and these groups may have a substituent, and Ar⁷ represents an arylene group, a di-valent heterocyclic group or a di-valent group obtained by linking two or more identical or different groups selected from arylene groups and di-valent heterocyclic groups, and these groups may have a substituent.

R^{1A} represents a mono-valent cross-linkable group, and R^{2A} represents a mono-valent cross-linkable group, an alkyl group, an aryl group or a mono-valent heterocyclic group.

In the formula (3A), cx is preferably 0, since synthesis of a monomer as a raw material of the polymer compound of the present embodiment is easy and a light emitting device produced by using the polymer compound of the present embodiment is more excellent in hole transportability and durability.

In the formula (3A), the group represented by Ar⁶, Ar⁷ and Ar⁸ is preferably an unsubstituted or substituted arylene group, since a light emitting device produced by using the polymer compound of the present embodiment is more excellent in hole transportability and durability.

As the arylene group represented by Ar⁶, Ar⁷ and Ar⁸ in the formula (3A), for example, a 1,2-phenylene group, a 1,3-phenylene group, a 1,4-phenylene group, a 1,4-naphthalenediyl group, a 2,6-naphthalenediyl group, a 2,7-naphthalenediyl group, a 2,6-anthracene-diyl group, a 9,10-anthracene-diyl group, a 2,7-phenanthrenediyl group, a 5,12-naphthacene-diyl group, a 2,7-fluorene-diyl group, a 3,6-fluorene-diyl group, a 1,6-pyrenediyl group, a 2,7-pyrenediyl group and a 3,8-perylenediyl group can be selected, and a 1,4-phenylene group, a 2,7-fluorene-diyl group, a 2,6-anthracene-diyl group, a 9,10-anthracene-diyl group, a 2,7-phenanthrenediyl group and a 1,6-pyrenediyl group are preferable, a 1,4-phenylene group is further preferable. These groups may have a substituent. The substituent is preferably an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group or a cyano group, more preferably an alkyl group, an alkoxy group, an aryl group, an aryloxy group, an arylalkyl group, an arylalkoxy group, a substituted amino group, an acyl group or a cyano group, further preferably an alkyl group, an alkoxy group or an aryl group.

As di-valent heterocyclic group represented by Ar⁶, Ar⁷ and Ar⁸ in the formula (3A), for example, a 2,5-pyrrolediyl group, a dibenzofurandiyl group, a dibenzothiophenediyl group and a 2,1,3-benzothiadiazole-4,7-diyl group can be selected, and these groups may have the above-described substituent.

In the formula (3A), the di-valent group obtained by linking two or more identical or different groups selected from arylene groups and di-valent heterocyclic groups represented by Ar⁷ is, for example, preferably a group represented by the following formula (1a-1), (1a-2), (1a-3), (1a-4), (1a-5), (1a-6) or (1a-7), more preferably a group represented by the following formula (1a-1). These groups may have the above-described substituent.

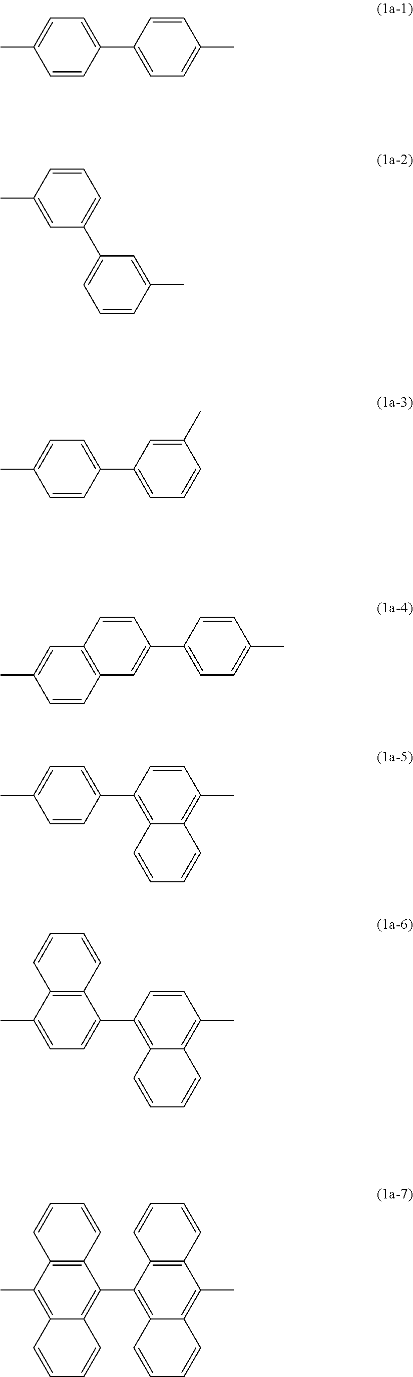

When the group represented by Ar⁶, Ar⁷ and Ar⁸ has a substituent in the formula (3), the substituent includes an alkyl group, an alkoxy group, an aryl group, an aryloxy group, an arylalkyl group, an arylalkoxy group, an arylalkenyl group, an arylalkynyl group, an amino group, a substituted amino group, a halogen atom, an acyl group, an acyloxy group, a mono-valent heterocyclic group, a carboxyl group, a nitro group and a cyano group, preferably an alkyl group, an alkoxy group, an aryl group, an aryloxy group, an arylalkyl group, an arylalkoxy group, a substituted amino group, an acyl group and a cyano group, more preferably an alkyl group, an alkoxy group and an aryl group.

The definitions and specific examples of the alkyl group, the alkoxy group, the aryl group, the aryloxy group, the arylalkyl group, the arylalkoxy group, the arylalkenyl group, the arylalkynyl group, the substituted amino group, the halogen atom, the acyl group, the acyloxy group and the mono-valent heterocyclic group are the same as the definitions and specific examples of the alkyl group, the alkoxy group, the aryl group, the aryloxy group, the arylalkyl group, the arylalkoxy group, the arylalkenyl group, the arylalkynyl group, the substituted amino group, the halogen atom, the acyl group, the acyloxy group and the mono-valent heterocyclic group represented by R¹ to R⁸ in the above-described formula (1).

In the formula (3A), the mono-valent cross-linkable group represented by R^{1A} or R^{2A} includes, for example, groups represented by the above-described formulae (X-1), (X-2), (X-01) to (X-18), and preferable are groups represented by the formulae (X-1), (X-2), (X-01), (X-03), (X-04) and (X-06) to (X-18), more preferably are groups represented by the formulae (X-1), (X-2) and (X-07) to (X-18), further preferable are groups represented by the formula (X-1), since a light emitting device produced by using the polymer compound of the present embodiment is more excellent in hole transportability and durability.

The definitions and specific examples of the alkyl group, the aryl group and the mono-valent heterocyclic group represented by R^{2A} in the formula (3A) are the same as the definitions and specific examples of the alkyl group, the aryl group and the mono-valent heterocyclic group represented by R¹ to R⁸ in the above-described formula (1).

In the formula (3A), R^{2A} preferably represents the same mono-valent cross-linkable group as R^{1A}, since synthesis of a monomer as a raw material of the polymer compound of the present embodiment is easy.

Specific examples of the repeating unit represented by the formula (3A) include, for example, repeating units represented by the formulae (3-01) to (3-05), and preferable is a repeating unit represented by the formula (3-01), (3-02), (3-04) or (3-05), more preferable is a repeating unit represented by the formula (3-01) or (3-02), further preferable is a repeating unit represented by the formula (3-01).

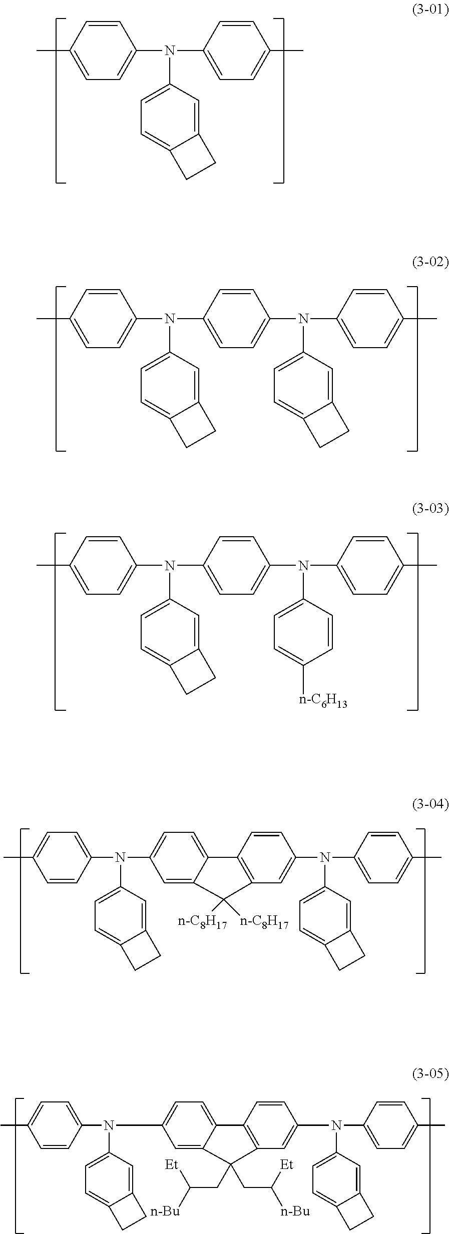

The content of the repeating unit represented by the formula (3A) is preferably 0.5 to 40% by mol, more preferably 3 to 30% by mol, further preferably 3 to 20% by mol, with respect to the sum of all repeating units, since a light emitting device produced by using the polymer compound of the present embodiment is more excellent in hole transportability and durability.

### —Proportion of Repeating Unit in Polymer Compound—

Examples of the polymer compound of the present invention include the following compounds EP-1 to EP-6.

TABLE 1

| | Proportion of number of moles of repeating unit | | | | |
|---|---|---|---|---|---|
| | | | | Formula (3) | |
| | | | | (excluding | Formula (5), |
| | | | | formula (3′) | formula (6) |
| | Formula | Formula | Formula | and formula | and formula |
| | (1) | (3′) | (4) | (4)) | (7) |
| compound | u | v | w | x | y |
| EP-1 | 0.001 to | 0.001 to | 0 | 0 | 0 |
| | 0.999 | 0.999 | | | |
| EP-2 | 0.001 to | 0.001 to | 0.001 to | 0 | 0 |
| | 0.998 | 0.998 | 0.998 | | |
| EP-3 | 0.001 to | 0.001 to | 0.001 to | 0.001 to | 0 |
| | 0.997 | 0.997 | 0.997 | 0.300 | |
| EP-4 | 0.001 to | 0.001 to | 0 | 0 | 0.001 to |
| | 0.998 | 0.998 | | | 0.300 |
| EP-5 | 0.001 to | 0.001 to | 0.001 to | 0 | 0.001 to |
| | 0.997 | 0.997 | 0.997 | | 0.300 |
| EP-6 | 0.001 to | 0.001 to | 0.001 to | 0.001 to | 0.001 to |
| | 0.996 | 0.996 | 0.996 | 0.300 | 0.300 |

[in the table,

u, v, w, x and y are a number representing the molar ratio of a repeating unit.

u+v+w+x+y=1.0, and 1≧u+v≧0.1.].

In the polymer compound of the present invention, the proportion of the total number of moles of repeating units represented by the above-described formula (1) and the above-described formula (3′) with respect to (the total number of moles) of all repeating units in the polymer compound is usually 0.1 to 1.0, and it is preferably 0.5 to 1.0, more preferably 0.7 to 1.0 since a light emitting device obtained by using the polymer compound of the present embodiment is more excellent in luminance life.

### —Example of Polymer Compound—

Examples of the polymer compound of the present invention include polymer compounds represented by the following formulae. In the formulae, u, v, w, x and y are a number representing the molar ratio. In the following formulae, in an example appending v1 and v2, v1 and v2 are each independently numbers satisfying v=v1+v2, and in an example appending v1, v2 and v3, v1, v2 and v3 are each independently numbers satisfying v=v1+v2+v3.

u+v+w+x+y=1.0, and 1≧u+v≧0.1.

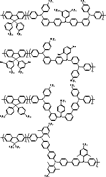

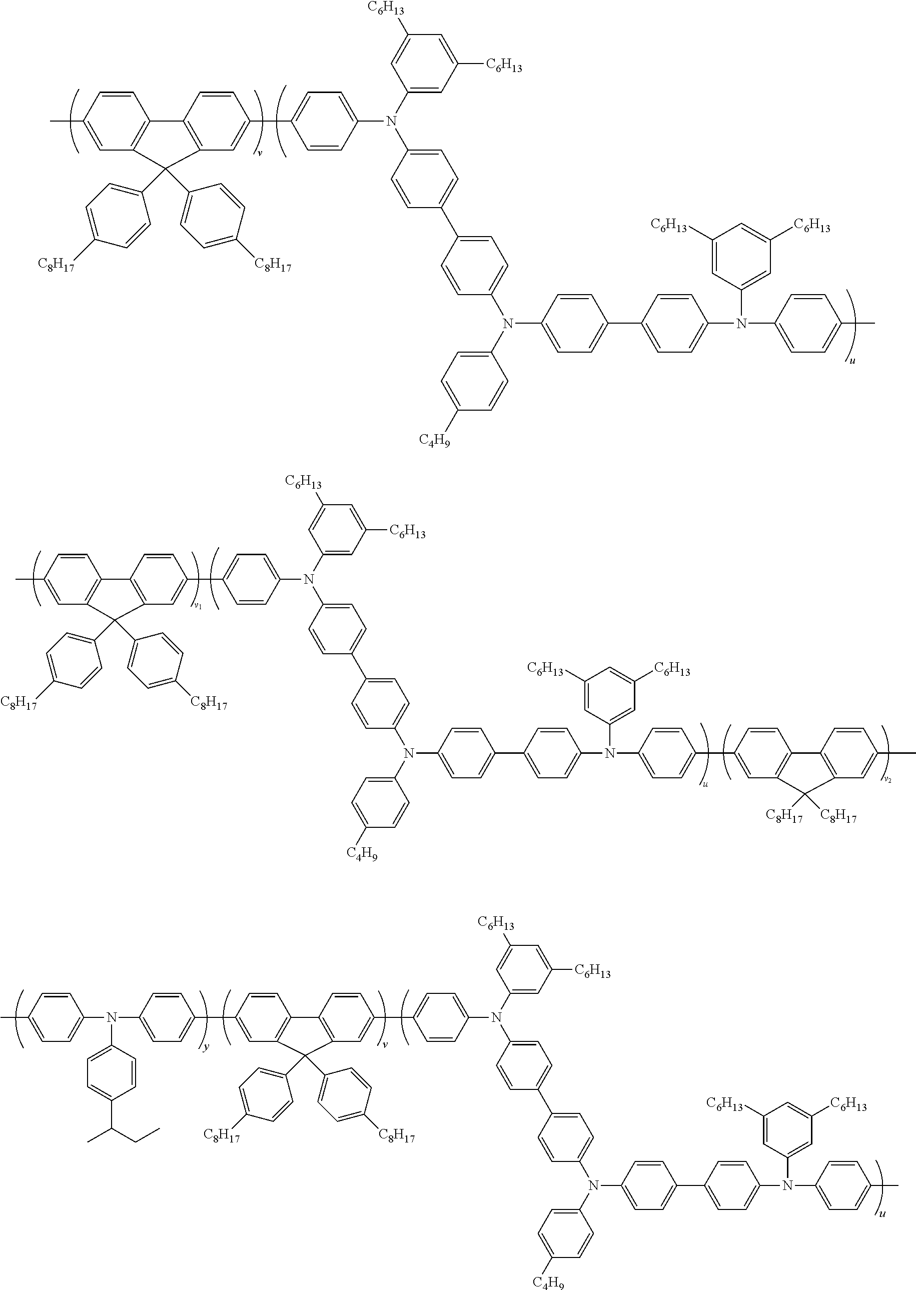

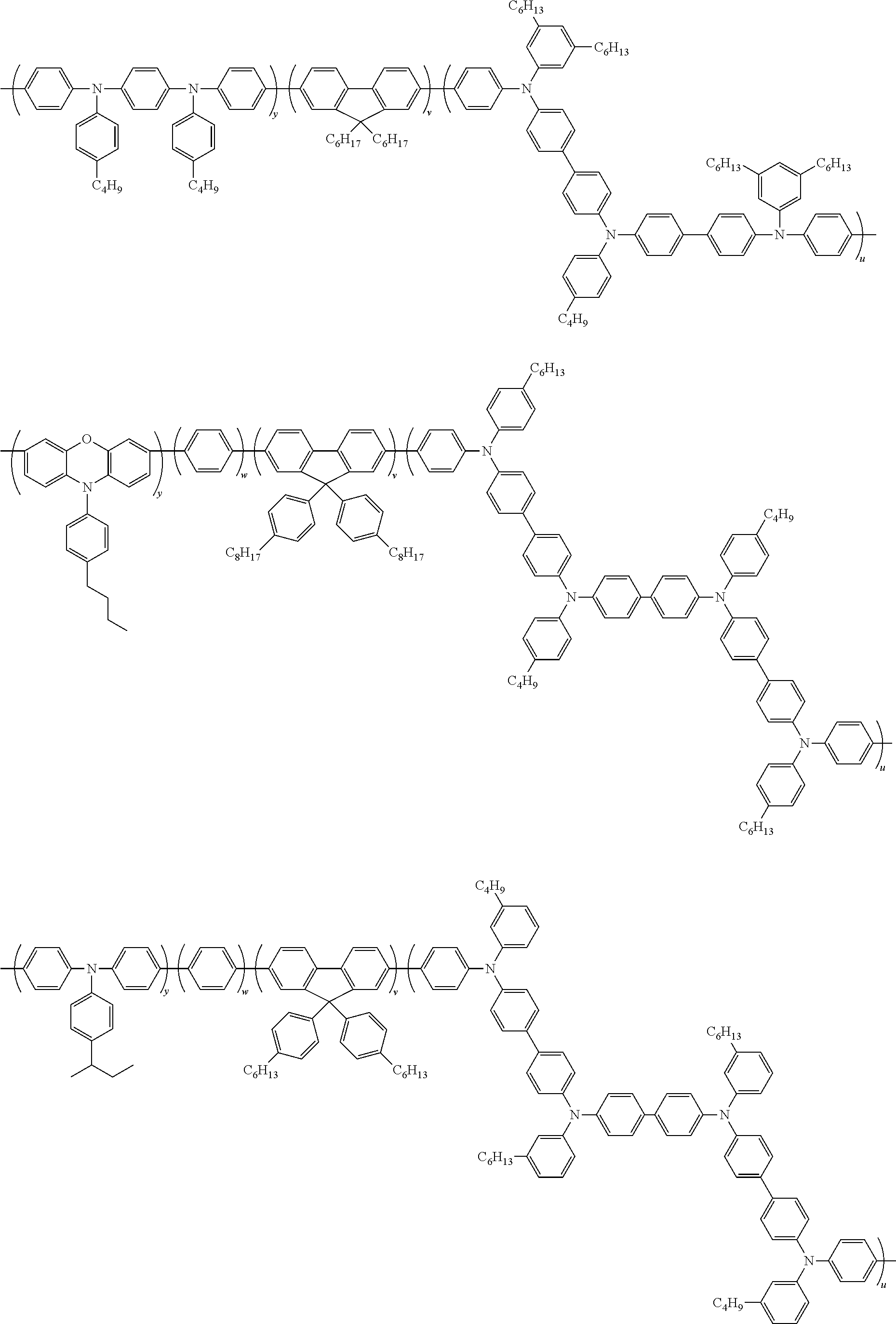

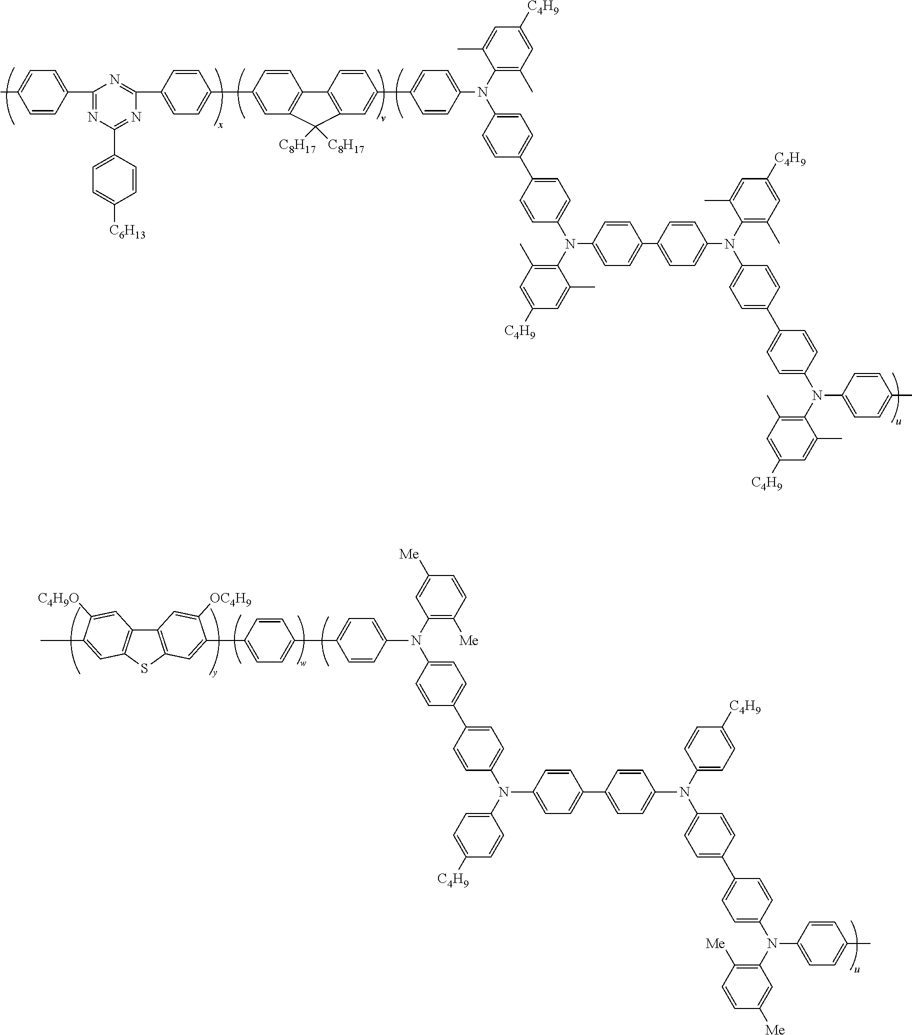

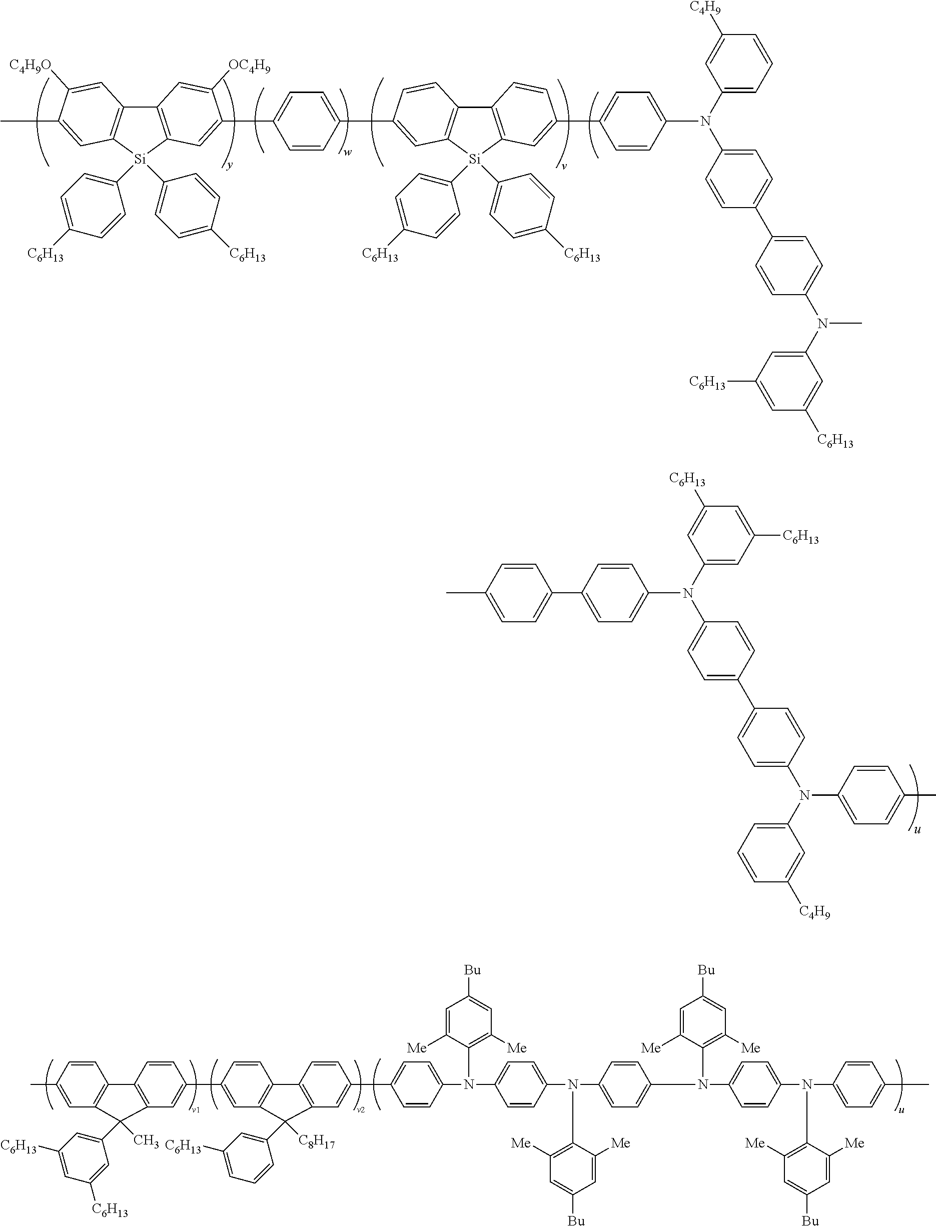

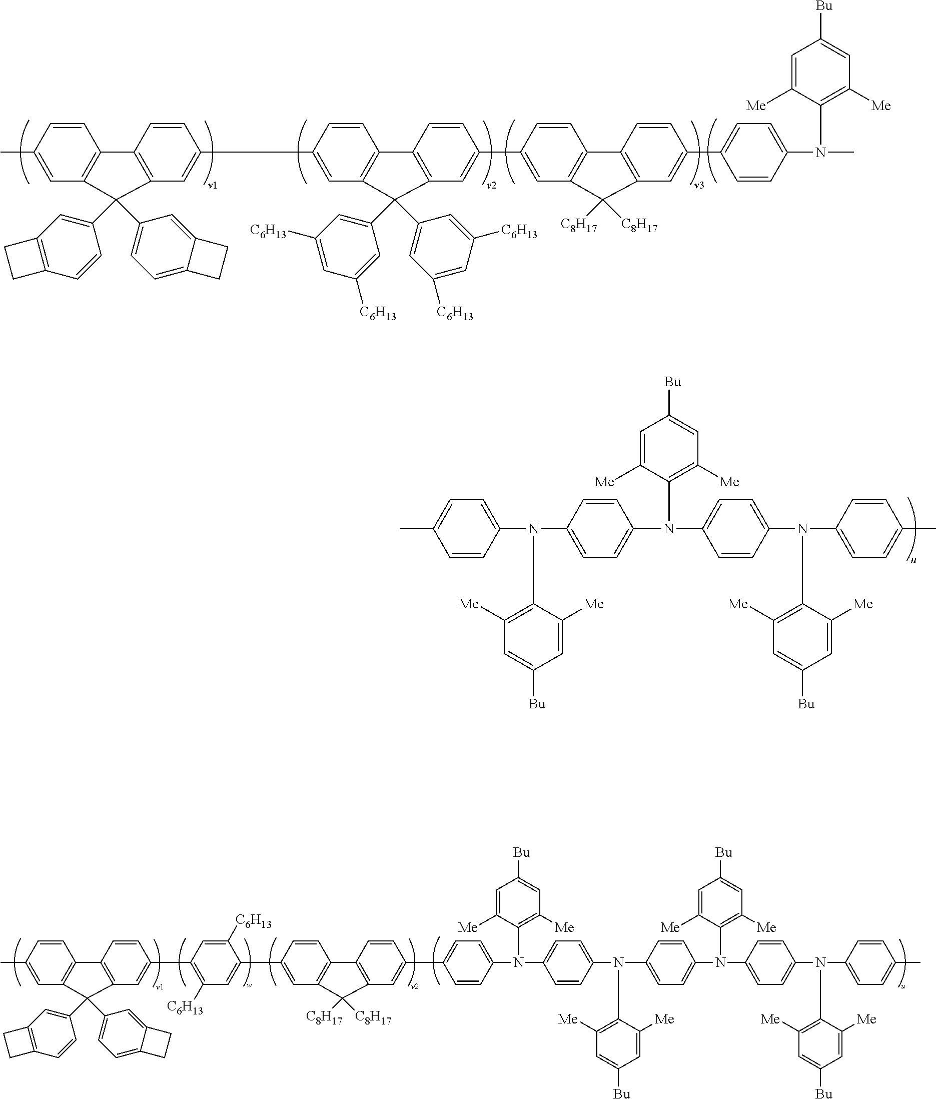

The polymer compound of the present invention has a polystyrene-equivalent number-average molecular weight of preferably 1×10³ to 1×10⁸, more preferably 1×10³ to 1×10⁷, particularly preferably 1×10⁴ to 1×10⁷, since luminance life is more excellent when used in a light emitting device.

The polymer compound of the present invention may be any of an alternative copolymer, a random copolymer, a block copolymer and a graft copolymer. As the polymer compound of the present invention, random copolymers in which identical repeating units constituting the polymer compound are not substantially adjacent, block copolymers and graft copolymers are more preferable than complete random copolymers, since luminance life is more excellent when used in a light emitting device. The polymer compound of the present invention includes also those having branching in the main chain and thus having 3 or more end parts, and dendrimers.

An end group of the polymer compound of the present invention may be protected by a stable group since if a polymerization active group remains intact, there is a possibility of decrease in light emitting property and life of the resultant light emitting device when used for fabrication of a light emitting device. As the end group, a group containing a conjugation bond continuous with a conjugation structure of the main chain is preferable, and for example, a group bonding to an aryl group or mono-valent heterocyclic group via a carbon-carbon bond is mentioned, and substituents described in Japanese Patent Application Laid-Open (JP-A) No. 9-45478 and the like may also be permissible

### <Production Method of Polymer Compound>

Next, the method of producing the polymer compound of the present invention will be illustrated.

The polymer compound of the present invention may be produced by any method, and for example, can be produced by condensation-polymerizing a compound represented by the formula: X¹¹-A¹¹-X¹² and a compound represented by the formula: X¹³-A¹²-X¹⁴. In the above-described formulae, A¹¹ represents a repeating unit of the above-described formula (1) and A¹² represents a repeating unit of the above-described formula (3′) or the above-described formula (4). In the above-described formulae, X¹¹, X¹², X¹³ and X¹⁴ represent each independently a polymerization reactive group.

The polymer compound of the present invention can, further, be produced by condensation-polymerizing a compound represented by the formula: X¹⁵⁻A¹³-X¹⁶. In the above-described formulae, A¹³ represents a repeating unit of the above-described formula (3) (excluding repeating units represented by the above-described formula (3′) and the above-described formula (4)), the above-described formula (5), the above-described formula (6), the above-described formula (7), the above-described formula (2A) or the above-described formula (3A). In the above-described formulae, X¹⁵ and X¹⁶ represent each independently a polymerization reactive group.

The above-described formula: X¹¹-A¹¹-X¹² in which X¹¹ and X¹² are a hydrogen atom can be subjected to a reaction such as a bromination reaction and the like, to convert a hydrogen atom into a bromine atom. The above-described formula: X¹³-A¹²-X¹⁴ and the above-described formula: X¹⁵-A¹³-X¹⁶ in which X¹³, X¹⁴, X¹⁵ and X¹⁶ are a halogen atom can be subjected to a known method, to convert the group into a polymerization reactive group other than halogen atoms.

The above-described polymerization reactive group includes, for example, a halogen atom, an alkyl sulfonate group, an aryl sulfonate group, an arylalkyl sulfonate group, a borate residue, a sulfoniummethyl group, a phosphoniummethyl group, a phosphonatemethyl group, a mono-halogenated methyl group, a boric acid residue (—B(OH)₂), a formyl group, a cyano group and a vinyl group.

The halogen atom as the above-described polymerization reactive group includes, for example, a fluorine atom, a chlorine atom, a bromine atom and an iodine atom.

The alkyl sulfonate group as the above-described polymerization reactive group includes, for example, a methane sulfonate group, an ethane sulfonate group and a trifluoromethane sulfonate group.

The aryl sulfonate group as the above-described polymerization reactive group includes, for example, a benzene sulfonate group and a p-toluene sulfonate group.

The arylalkyl sulfonate group as the above-described polymerization reactive group includes, for example, a benzyl sulfonate group.

The borate residue as the above-described polymerization reactive group includes, for example, groups represented by the following formulae.

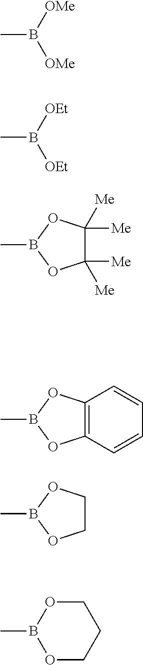

The sulfoniummethyl group as the above-described polymerization reactive group includes, for example, groups represented by the following formulae.

CH₂S⁺Me₂X′⁻, CH₂S⁺Ph₂X′⁻

[wherein, X′ represents a halogen atom and Ph represents a phenyl group.].

The phosphoniummethyl group as the above-described polymerization reactive group includes, for example, groups represented by the following formula.

CH₂P⁺Ph₃X′⁻

[wherein, X′ represents a halogen atom and Ph represents a phenyl group.].

The phosphonatemethyl group as the above-described polymerization reactive group includes, for example, groups represented by the following formula.

—CH₂PO(OR′)₂

[wherein, R′ represents an alkyl group, an aryl group or an arylalkyl group.].

The mono-halogenated methyl group represented by the above-described polymerization reactive group includes, for example, a methyl fluoride group, a methyl chloride group, a methyl bromide group and a methyl iodide group.

The above-described polymerization reactive group is preferably a halogen atom, an alkyl sulfonate group, an aryl sulfonate group or an arylalkyl sulfonate group in the case of use of a 0-valent nickel complex such as in the Yamamoto coupling reaction and the like, and preferably an alkyl sulfonate group, a halogen atom, a borate residue or a boric acid residue in the case of use of a nickel catalyst or a palladium catalyst such as in the Suzuki coupling reaction and the like.

Production of the polymer compound of the present invention can be carried out, by dissolving a compound having a plurality of polymerization reactive groups, as a monomer, in an organic solvent if necessary, and using an alkali and a suitable catalyst, at temperatures of not lower than the melting point and not higher than the boiling point of the organic solvent, and can be carried out by a method described, for example, in “Organic Reactions, vol. 14, pp. 270-490, John Wiley & Sons, Inc., 1965”, “Organic Syntheses, Collective Volume VI, pp. 407-411, John Wiley & Sons, Inc., 1988”, “Chem. Rev., vol. 95, p. 2457 (1995), “J. Organomet. Chem., vol. 576, p. 147 (1999)”, “Macromol. Chem. Macromol. Symp., vol. 12, p. 229 (1987)”.

In the method of producing the polymer compound of the present invention, a known condensation reaction can be used, depending on the kind of the above-described polymerization reactive group, and for example, a method of polymerization by the Suzuki coupling reaction of the corresponding monomer, a method of polymerization by the Grignard method, a method of polymerization with a 0-valent nickel complex, a method of polymerization with an oxidizer such as FeCl₃ and the like, a method of electrochemical oxidation polymerization and a method by decomposition of an intermediate polymer having a suitable leaving group are listed.

Of them, a method of polymerization by the Suzuki coupling reaction, a method of polymerization by the Grignard method or a method of polymerization with a 0-valent nickel complex is preferable, a method of polymerization by the Suzuki coupling reaction is more preferable, from the standpoint of structure control of the polymer compound of the present invention (referred to also as “sequence control”). It is because a copolymer in which identical repeating units constituting the polymer compound of the present invention are mutually not substantially adjacent can be obtained.

Among methods of producing the polymer compound of the present invention, preferable are production methods in which the polymerization reactive group is selected from the group consisting of halogen atoms, alkyl sulfonate groups, aryl sulfonate groups and arylalkyl sulfonate groups and condensation polymerization is conducted in the presence of a 0-valent nickel complex.

The compound as a raw material of the polymer compound of the present invention includes, for example, a dihalogenated compound, a bis(alkyl sulfonate) compound, a bis(aryl sulfonate) compound, a bis(arylalkyl sulfonate) compound, a halogen-alkyl sulfonate compound, a halogen-aryl sulfonate compound, a halogen-arylalkyl sulfonate compound, an alkyl sulfonate-aryl sulfonate compound, an alkyl sulfonate-arylalkyl sulfonate compound and an aryl sulfonate-arylalkyl sulfonate compound. In the case of production of a polymer compound in which sequence is controlled, it is preferable to use a halogen-alkyl sulfonate compound, a halogen-aryl sulfonate compound, a halogen-arylalkyl sulfonate compound, an alkyl sulfonate-aryl sulfonate compound, an alkyl sulfonate-arylalkyl sulfonate compound or an aryl sulfonate-arylalkyl sulfonate compound as the above-described compound.

As the method of producing the polymer compound of the present invention, preferable are production methods in which the polymerization reactive group is selected from the group consisting of halogen atoms, alkyl sulfonate groups, aryl sulfonate groups, arylalkyl sulfonate groups, boric acid residues and borate residues, the ratio of the sum (J) of number of moles of a halogen atom, an alkyl sulfonate group, an aryl sulfonate group and an arylalkyl sulfonate group to the sum (K) of number of moles of a boric acid residue and a borate residue, in all raw material compounds, is substantially 1.0 (usually, K/J is 0.7 to 1.2), and condensation polymerization is conducted using a 0-valent nickel catalyst or a palladium catalyst, from the standpoint of easiness of synthesis of the polymer compound.

Combinations of the above-described raw material compounds (for example, a compound represented by the above-described formula: X¹¹-A¹¹-X¹² with a compound represented by the above-described formula: X¹³-A¹²-X¹⁴) include combinations of a dihalogenated compound, a bis(alkyl sulfonate) compound, a bis(aryl sulfonate) compound or a bis(arylalkyl sulfonate) compound with a diboric acid compound or a diborate compound.

In the case of production of a polymer compound in which sequence is controlled, it is preferable to use a halogen-boric acid compound, a halogen-borate compound, an alkyl sulfonate-boric acid compound, an alkyl sulfonate-borate compound, an aryl sulfonate-boric acid compound, an aryl sulfonate-borate compound, an arylalkyl sulfonate-boric acid compound, an arylalkyl sulfonate-boric acid compound, an arylalkyl sulfonate-borate compound and the like as the above-described raw material compound. It is because, by this, a polymer compound in which repeating units represented by the above-described formula (1) are not substantially adjacent can be produced.

For suppressing a side reaction, the organic solvent used for the above-described condensation polymerization is preferably subjected to a sufficient deoxidation treatment and a dehydration treatment previously. However, this is not the case when a reaction in a two-phase system with water is conducted such as in the Suzuki coupling reaction.

The organic solvent used for the above-described condensation polymerization includes, for example, saturated hydrocarbons such as pentane, hexane, heptane, octane, cyclohexane and the like; unsaturated hydrocarbons such as benzene, toluene, ethylbenzene, xylene and the like; halogenated saturated hydrocarbons such as carbon tetrachloride, chloroform, dichloromethane, chlorobutane, bromobutane, chloropentane, bromopentane, chlorohexane, bromohexane, chlorocyclohexane, bromocyclohexane and the like; halogenated unsaturated hydrocarbons such as chlorobenzene, dichlorobenzene, trichlorobenzene and the like; alcohols such as methanol, ethanol, propanol, isopropanol, butanol, tert-butyl alcohol and the like; carboxylic acids such as formic acid, acetic acid, propionic acid and the like; ethers such as dimethyl ether, diethyl ether, methyl tert-butyl ether, tetrahydrofuran, tetrahydropyran, dioxane and the like; amines such as trimethylamine, triethylamine, N,N,N′,N′-tetramethylethylenediamine, pyridine and the like; and amides such as N,N-dimethylformamide, N,N-dimethylacetamide, N,N-diethylacetamide, N-methylmorpholine oxide and the like, and of them, ethers are preferable, tetrahydrofuran and diethyl ether are preferable. These organic solvents may each be used singly or two or more of them may be used in combination.

In the above-described condensation polymerization, an alkali or a suitable catalyst may be added for promoting the reaction. As the alkali or the suitable catalyst, those which are sufficiently dissolved in the solvent used for the reaction are preferable. For mixing an alkali or a catalyst, it may be advantageous that a solution of an alkali or a catalyst is added slowly while stirring the reaction liquid under an atmosphere of an inert gas such as an argon gas, a nitrogen gas and the like, or reversely, the reaction liquid is slowly added to a solution of an alkali or a catalyst.

When the polymer compound of the present invention is used for fabrication of a light emitting device and the like, its purity exerts an influence on the performances of the light emitting device such as a light emitting property and the like, therefore, it is preferable that a monomer as a raw material before polymerization is purified by a method such as distillation, sublimation purification, re-crystallization and the like before performing polymerization. Further, it is preferable that, after polymerization, a purification treatment such as re-precipitation purification, chromatographic fractionation, and the like is carried out.

### <Application>

The polymer compound of the present invention is useful not only as a light emitting material, but also as a film, an organic semiconductor material, an organic transistor material, an optical material, an organic photoelectric conversion device material or an electrically conductive material by doping.

### <Composition>

The composition of the present invention is a composition comprising the polymer compound of the present invention and at least one material selected from the group consisting of hole transporting materials, electron transporting materials and light emitting materials.

The above-described hole transporting material includes, for example, polyvinylcarbazole and derivatives thereof, polysilane and derivatives thereof, polysiloxane derivatives having an aromatic amine in the side chain or main chain, pyrazoline derivatives, arylamine derivatives, stilbene derivatives, triphenyldiamine derivatives, polyaniline and derivatives thereof, polythiophene and derivatives thereof, polypyrrole and derivatives thereof, poly(p-phenylenevinylene) and derivatives thereof and poly(2,5-thienylenevinylene) and derivatives thereof.

The above-described electron transporting material includes, for example, oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof and polyfluorene and derivatives thereof.

The above-described light emitting material includes, for example, naphthalene derivatives, anthracene and derivatives thereof, perylene and derivatives thereof, polymethine dyes, xanthene dyes, coumarin dyes, cyanine dyes, metal complexes having 8-hydroxyquinoline as a ligand, metal complexes having a 8-hydroxyquinoline derivative as a ligand, other fluorescent metal complexes, aromatic amines, tetraphenylcyclopentadiene, tetraphenylcyclopentadiene derivatives, tetraphenylcyclobutadiene, tetraphenylcyclobutadiene derivatives, and, fluorescent materials composed of a low molecular weight compound such as a stilbene compound, a silicon-containing aromatic compound, an oxazole compound, a furoxan compound, a thiazole compound, a tetraarylmethane compound, a thiadiazole compound, a pyrazole compound, a metacyclophane compound, an cetylene compound and the like, and also light emitting materials described in JP-A No. 57-51781, JP-A No. 59-194393 and the like.

The composition of the present invention may contain a solvent. That is, the composition comprising a solvent of the present invention includes a composition comprising the polymer compound of the present invention and a solvent, and a composition further comprising at least one material selected from the group consisting of hole transporting materials, electron transporting materials and light emitting materials.

The composition comprising a solvent of the present invention is useful for fabrication of a light emitting device and an organic transistor. In the present specification, “composition comprising a solvent” denotes a composition which is liquid in device fabrication, typically, one which is liquid at normal pressure (namely, 1 atm) and 25° C. Further, the composition comprising a solvent is, in general, referred to as ink, ink composition, liquid composition, solution or the like in some cases.

The composition of the present invention may also contain a stabilizer, an additive for controlling viscosity and/or surface tension, an antioxidant and the like, in addition to the above-described components. These optional components may each be used singly or two or more of them may be used in combination.

The above-described stabilizer includes a phenol antioxidant, a phosphorus-based antioxidant and the like.

As the above-described additive for controlling viscosity and/or surface tension, a high molecular weight compound for increasing viscosity (thickener), a poor solvent, a low molecular weight compound for lowering viscosity, a surfactant for lowering surface tension, and the like may be used in combination according to demands.

As the above-described high molecular weight compound, those not disturbing light emission and charge transportation may be permissible, and when the composition contains a solvent, those soluble in the solvent are usually used. As the high molecular weight compound, for example, polystyrene of high molecular weight and polymethyl methacrylate of high molecular weight can be used. The above-described high molecular weight compound has a polystyrene-equivalent weight-average molecular weight of preferably 500000 or more, more preferably 1000000 or more. Also a poor solvent can be used as a thickening agent.

As the above-described antioxidant, those not disturbing light emission and charge transportation may be permissible, and when the composition contains a solvent, those soluble in the solvent are usually used. As the antioxidant, for example, a phenol antioxidant and a phosphorus-based antioxidant can be used. By use of the antioxidant, preservation stability of the above-described polymer compound and solvent can be improved.

When the composition of the present invention contains a hole transporting material, the proportion of the hole transporting material in the composition is usually 1 to 400 wt %, preferably 5 to 150 wt %, when proportion of the polymer compound of the present invention is 100 wt %. When the composition of the present invention contains an electron transporting material, the proportion of the electron transporting material in the composition is usually 1 to 400 wt %, preferably 5 to 150 wt %, when the proportion of the polymer compound of the present invention is 100 wt %. When the composition of the present invention contains a light emitting material, the proportion of the light emitting material in the composition is usually 1 to 400 wt %, preferably 5 to 150 wt %, when the proportion of the polymer compound of the present invention is 100 wt %.

In the case of firm formation using the above-described composition comprising a solvent in fabricating a light emitting device, it may be advantageous to only remove a solvent by drying after application of the liquid composition, and also in the case of mixing of a hole transporting material, a charge transporting material and a light emitting material, the same means can be applied, that is, this method is very useful in producing a light emitting device. In drying, drying may be effected under heating at about 50 to 150° C., alternatively, drying may be carried out under reduced pressure of about 10⁻³ Pa.

In film formation using the above-described composition comprising a solvent, coating methods such as a spin coat method, a casting method, a micro gravure coat method, a gravure coat method, a bar coat method, a roll coat method, a wire bar coat method, a dip coat method, a slit coat method, a cap coat method, a capillary coat method, a spray coat method, a screen printing method, a flexo printing method, an offset printing method, an inkjet printing method, a nozzle coat method and the like can be used.

The proportion of a solvent in the above-described composition comprising a solvent is usually 1 to 100000 wt %, preferably 150 to 100000 wt %, more preferably 1000 to 100000 wt %, when the proportion of the polymer compound of the present invention is 100 wt %. Though the viscosity of the composition comprising a solvent varies depending on a printing method, it is preferably 0.5 to 500 mPa·s at 25° C., and when the composition passes through a discharge apparatus such as in an inkjet print method and the like, the viscosity at 25° C. is preferably 0.5 to 20 mPa·s, for preventing clogging and curved flying in discharging.

As the solvent to be contained in the above-described composition comprising a solvent, those capable of dissolving or dispersing components other than the solvent in the composition are preferable. The solvent includes, for example, chlorine-based solvents such as chloroform, methylene chloride, 1,2-dichloroethane, 1,1,2-trichloroethane, chlorobenzene, o-dichlorobenzene and the like; ether solvents such as tetrahydrofuran, dioxane and the like; aromatic hydrocarbon solvents such as toluene, xylene, trimethylbenzene, mesitylene and the like; aliphatic hydrocarbon solvents such as cyclohexane, methylcyclohexane, n-pentane, n-hexane, n-heptane, n-octane, n-nonane, n-decane and the like; ketone solvents such as acetone, methyl ethyl ketone, cyclohexanone and the like; ester solvents such as ethyl acetate, butyl acetate, methyl benzoate, ethyl cellosolve acetate and the like; polyhydric alcohols such as ethylene glycol, ethylene glycol monobutyl ether, ethylene glycol monoethyl ether, ethylene glycol monomethyl ether, dimethoxyethane, propylene glycol, diethoxymethane, triethylene glycol monoethyl ether, glycerin, 1,2-hexane diol and the like and derivatives thereof; alcohol solvents such as methanol, ethanol, propanol, isopropanol, cyclohexanol and the like; sulfoxide solvents such as dimethyl sulfoxide and the like; and amide solvents such as N-methyl-2-pyrrolidone, N,N-dimethylformamide and the like. These solvents may each be used singly or two or more of them may be used in combination. Among the above-described solvents, one or more organic solvents having a structure comprising at least one benzene ring and having a melting point of 0° C. or lower and a boiling point of 100° C. or higher are preferably contained from the standpoint of viscosity, film formability and the like. Regarding the kind of the solvent, at least one of aromatic hydrocarbon solvents, aliphatic hydrocarbon solvents, ester solvents and ketone solvents is preferably contained, and toluene, xylene, ethylbenzene, diethylbenzene, trimethylbenzene, mesitylene, n-propylbenzene, isopropylbenzene, n-butylbenzene, isobutylbenzene, s-butylbenzene, anisole, ethoxybenzene, 1-methylnaphthalene, cyclohexane, cyclohexanone, cyclohexylbenzene, bicyclohexyl, cyclohexenylcyclohexanone, n-heptylcyclohexane, n-hexylcyclohexane, methyl benzoate, 2-propylcyclohexanone, 2-heptanone, 3-heptanone, 4-heptanone, 2-octanone, 2-nonanone, 2-decanone and dicyclohexyl ketone are preferable, and at least one of xylene, anisole, mesitylene, cyclohexylbenzene and bicyclohexylmethyl benzoate is more preferably contained, from the standpoint of solubility of components other than a solvent in the composition comprising a solvent into an organic solvent, uniformity in film formation, a viscosity property and the like.

The number of the solvent to be contained in the above-described composition comprising a solvent is preferably 2 or more, more preferably 2 to 3, particularly preferably 2 from the standpoint of film formability and from the standpoint of a device property and the like.

When two solvents are contained in the above-described composition comprising a solvent, one of them may be solid state at 25° C. From the standpoint of film formability, it is preferable that one solvent has a boiling point of 180° C. or higher and another solvent has a boiling point of lower than 180° C., and it is more preferable that one solvent has a boiling point of 200° C. or higher and another solvent has a boiling point of lower than 180° C. From the standpoint of viscosity, it is preferable that 0.2 wt % or more of components excepting solvents from the composition are dissolved at 60° C. in solvents, and it is preferable that 0.2 wt % or more of components excepting solvents from the composition are dissolved at 25° C. in one of two solvents.

When three solvents are contained in the above-described composition comprising a solvent, one or two of them may be solid at 25° C. From the standpoint of film formability, it is preferable that at least one of three solvents has a boiling point of 180° C. or higher and at least one solvent has a boiling point of lower than 180° C., and it is more preferable that at least one of three solvents has a boiling point of 200° C. or higher and 300° C. or lower and at least one solvent has a boiling point of 180° C. or lower. From the standpoint of viscosity, it is preferable that 0.2 wt % or more of components excepting solvents from the composition are dissolved at 60° C. in two of three solvents, and it is preferable that 0.2 wt % or more of components excepting solvents from the liquid composition are dissolved at 25° C. in one of three solvents.

When two or more solvents are contained in the above-described composition comprising a solvent, the content of a solvent having highest boiling point is preferably 40 to 90 wt %, more preferably 50 to 90 wt %, further preferably 65 to 85 wt % with respect to the weight of all solvents contained in the composition, from the standpoint of viscosity and film formability.

### <Film>

The film of the present invention will be illustrated. The film of the present invention contains the polymer compound of the present invention or the composition of the present invention. When the polymer compound of the present invention contains at least one of a repeating unit represented by the above-described formula (2A) and a repeating unit represented by the above-described formula (3A), the film of the present invention is a film obtained by cross-linking the polymer compound of the present invention or a composition comprising the polymer compound of the present invention. This cross-linking step is carried out, for example, by heating.

The film includes, for example, a luminescent film, an electrically conductive film and an organic semiconductor film.

The above-described luminescent film has a quantum yield of light emission of preferably 50% or more, more preferably 60% or more, further preferably 70% or more, from the standpoint of the luminance, the driving voltage and the like of a light emitting device.

The above-described electrically conductive film preferably has a surface resistance of 1 KΩ/□ or less. By doping a film with a Lewis acid, an ionic compound or the like, electric conductivity can be enhanced. The surface resistance of the film is more preferably 100Ω/□ or less, further preferably 10Ω/□ or less.

In the above-described organic semiconductor film, one larger parameter of electron mobility or hole mobility is preferably 10⁻⁵ cm²/V/s or more, more preferably 10⁻³ m²/V/s or more, further preferably 10⁻¹ m²/V/s or more. Using the organic semiconductor film, an organic transistor can be fabricated. Specifically, by forming the organic semiconductor film on a Si substrate carrying a gate electrode and an insulation film made of SiO₂ or the like formed thereon, and forming a source electrode and a drain electrode with Au and the like, an organic transistor can be obtained.

### <Organic Transistor>

The organic transistor of the present embodiment is an organic transistor comprising the polymer compound or the composition of the present invention. A polymer electric field effect transistor as an embodiment of the organic transistor will be illustrated below.

The polymer compound and the composition of the present invention can be suitably used as a material of a polymer electric field effect transistor, particularly, as an active layer. Regarding the structure of a polymer electric field effect transistor, it may be usually advantageous that a source electrode and a drain electrode are disposed in contact with an active layer made of a polymer, further, a gate electrode is disposed sandwiching an insulation layer in contact with the active layer.

The polymer electric field effect transistor is usually formed on a supporting substrate. As the supporting substrate, for example, a glass substrate, a flexible film substrate and a plastic substrate can be used.

The polymer electric field effect transistor can be produced by known methods, for example, a method described in JP-A No. 5-110069.

In forming an active layer, it is advantageous and preferable for production to use an organic solvent-soluble polymer compound (that is, to use the composition comprising a solvent of the present invention). For film formation from a solution prepared by dissolving an organic solvent-soluble polymer compound in a solvent, coating methods such as a spin coat method, a casting method, a micro gravure coat method, a gravure coat method, a bar coat method, a roll coat method, a wire bar coat method, a dip coat method, a slit coat method, a cap coat method, a capillary coat method, a spray coat method, a screen printing method, a flexo printing method, an offset printing method, an inkjet printing method, a nozzle coat method and the like can be used.

The polymer electric field effect transistor is preferably sealed after fabrication. By this, the polymer electric field effect transistor is blocked from atmospheric air, thus, lowering of properties of the polymer electric field effect transistor can be suppressed.

As the sealing method, a method of covering with an ultraviolet (UV) curable resin, a thermosetting resin, or an inorganic SiONx film and the like, a method of pasting a glass plate or a film with an UV curable resin, a thermosetting resin or the like, and other methods are mentioned. For effectively performing blocking from atmospheric air, it is preferable that processes after fabrication of a polymer electric field effect transistor until sealing are carried out without exposing to atmospheric air, and for example, sealing is performed in a dried nitrogen gas atmosphere or in vacuum.

### <Organic Photoelectric Conversion Device>

The organic photoelectric conversion device of the present embodiment (for example, solar battery) is an organic photoelectric conversion device comprising the polymer compound of the present invention or the composition of the present invention.

The polymer compound and the composition of the present invention can be suitably used as a material of an organic photoelectric conversion device, particularly, as an organic semiconductor layer of a schottky barrier type device utilizing an interface between an organic semiconductor and a metal, or as an organic semiconductor layer of a pn hetero junction type device utilizing an interface between an organic semiconductor and an inorganic semiconductor or an organic semiconductor.

Further, the polymer compound and the composition of the present invention can be suitably used as an electron donating polymer or an electron accepting polymer in a bulk hetero junction type device in which the donor-acceptor contact area is increased, or as an electron donating conjugated polymer (dispersion supporting body) of an organic photoelectric conversion device using a high molecular weight-low molecular weight complex system, for example, a bulk hetero junction type organic photoelectric conversion device comprising a fullerene derivative dispersed as an electron acceptor.

With respect to the structure of the above-described organic photoelectric conversion device, it is advantageous, in the case of for example a pn hetero junction type device, that a p type semiconductor layer is formed on an ohmic electrode, for example, on ITO, further, an n type semiconductor layer is laminated, and an ohmic electrode is disposed thereon.

The above-described organic photoelectric conversion device is usually formed on a supporting substrate. As the supporting substrate, for example, a glass substrate, a flexible film substrate and a plastic substrate can be used.

The organic photoelectric conversion device can be produced by known methods, for example, a method described in “Synth. Met., 102, 982 (1999)”, and a method described in “Science, 270, 1789 (1995)”.

### <Light Emitting Device>

Next, the light emitting device of the present invention will be described.

The light emitting device of the present invention is a light emitting device having the film of the present invention. The light emitting device of the present invention includes, for example, a light emitting device in which this film is a hole transporting layer, a light emitting device in which this film is a light emitting layer, and the like. Preferable embodiments of the light emitting device of the present invention will be described below.

The first light emitting device of the present invention is a light emitting device having electrodes consisting of an anode and a cathode, and a light emitting layer disposed between the electrodes and comprising the polymer compound of the present invention or the composition of the present invention, and/or, a charge transporting layer disposed between the electrodes and comprising the polymer compound of the present invention or the composition of the present invention.

The second light emitting device of the present invention is a light emitting device having electrodes consisting of an anode and a cathode, and a light emitting layer disposed between the electrodes and obtained by crosslinking the polymer compound or the composition of the present invention (usually, the polymer compound or the composition of the present invention is cured by crosslinking), and/or, a charge transporting layer disposed between the electrodes and obtained by crosslinking the polymer compound or the composition of the present invention (usually, the polymer compound or the composition of the present invention is cured by crosslinking).

The light emitting device of the present invention includes (1) a light emitting device having an electron transporting layer disposed between a cathode and a light emitting layer, (2) a light emitting device having a hole transporting layer disposed between an anode and a light emitting layer, and (3) a light emitting device having an electron transporting layer disposed between a cathode and a light emitting layer and having a hole transporting layer disposed between an anode and a light emitting layer.

The structure of the light emitting device of the present invention includes, for example, the following structures a) to d).

a) anode/light emitting layer/cathode
b) anode/hole transporting layer/light emitting layer/cathode
c) anode/light emitting layer/electron transporting layer/cathode
d) anode/hole transporting layer/light emitting layer/electron transporting layer/cathode
(wherein, / denotes adjacent lamination of layers. The same shall apply hereinafter.)

The above-described light emitting layer is a layer having a function of emitting light, the above-described hole transporting layer is a layer having a function of transporting holes, and the above-described electron transporting layer is a layer having a function of transporting electrons.

The electron transporting layer and the hole transporting layer are collectively called a charge transporting layer. Two or more layers of the light emitting layer, two or more layers of the hole transporting layer and two or more layers of the electron transporting layer may independently be used. The hole transporting layer adjacent to the light emitting layer is called an inter-layer layer in some cases.

The method of forming a light emitting layer includes a method of film formation from a solution. For film formation from a solution, coating methods such as a spin coat method, a casting method, a micro gravure coat method, a gravure coat method, a bar coat method, a roll coat method, a wire bar coat method, a dip coat method, a slit coat method, a cap coat method, a capillary coat method, a spray coat method, a screen printing method, a flexo printing method, an offset printing method, an inkjet printing method, a nozzle coat method and the like can be used. The method of film formation from a solution is useful also for film formation of a hole transporting layer and an electron transporting layer.

In the case of firm formation from a solution using the polymer compound or the composition of the present invention (namely, the composition comprising a solvent of the present invention) in fabricating a light emitting device, it may be advantageous to only remove a solvent by drying after application of this solution, and also in the case of mixing of a charge transporting material and a light emitting material, the same means can be applied, that is, this method is advantageous for production.

The thickness of a light emitting layer may be advantageously regulated so as to give appropriate light emission efficiency and driving voltage, and is usually 1 nm to 1 μm, preferably 2 nm to 500 nm, further preferably 5 nm to 200 nm.

When the light emitting device of the present invention has a hole transporting layer, the hole transporting material to be used is the same as the hole transporting material explained in the section of the above-described composition comprising a solvent, and preferable are high molecular weight hole transporting materials such as polyvinylcarbazole and derivatives thereof, polysilane and derivatives thereof, polysiloxane derivatives having an aromatic amine compound group in the side chain or main chain, polyaniline and derivatives thereof, polythiophene and derivatives thereof, poly(p-phenylenevinylene) and derivatives thereof, poly(2,5-thienylenevinylene) and derivatives thereof and the like, more preferable are polyvinylcarbazole and derivatives thereof, polysilane and derivatives thereof and polysiloxane derivatives having an aromatic amine in the side chain or main chain. When a low molecular weight hole transporting material is used, it is preferably dispersed in a polymer binder.

The method of forming a hole transporting layer includes a method of film formation from a mixed solution with a polymer binder, in the case of a low molecular weight hole transporting material. In the case of a high molecular weight hole transporting material, a method of film formation from a solution is used.

As the polymer binder to be mixed, those not extremely disturbing hole transportation are preferable, and those showing no strong absorption against visible light are suitably used. The polymer binder includes, for example, polycarbonate, polyacrylate, polymethyl acrylate, polymethyl methacrylate, polystyrene, polyvinyl chloride and polysiloxane.

The thickness of a hole transporting layer may be advantageously regulated so as to give appropriate light emission efficiency and driving voltage, and is usually 1 nm to 1 μm, preferably 2 nm to 500 nm, further preferably 5 nm to 200 nm.

When the light emitting device of the present invention has an electron transporting layer, the electron transporting material to be used is the same as the electron transporting material explained in the section of the above-described composition comprising a solvent, and preferable are oxadiazole derivatives, benzoquinone and derivatives thereof, anthraquinone and derivatives thereof, metal complexes of 8-hydroxyquinoline and derivatives thereof, polyquinoline and derivatives thereof, polyquinoxaline and derivatives thereof and polyfluorene and derivatives thereof, more preferable are 2-(4-biphenylyl)-5-(4-t-butylphenyl)-1,3,4-oxadiazole, benzoquinone, anthraquinone, tris(8-quinolinol)aluminum and polyquinoline.

The method of forming an electron transporting layer includes a vacuum vapor deposition method from a powder and a method of film formation from a solution or melted state in the case of a low molecular weight electron transporting material, and a method of film formation from a solution or melted state in the case of a high molecular weight electron transporting material. In film formation from a solution or melted state, a polymer binder may be used together.

As the polymer binder to be mixed, those not extremely disturbing electron transportation are preferable, and those showing no strong absorption against visible light are suitably used. The polymer binder includes, for example, poly(N-vinylcarbazole), polyaniline and derivatives thereof, polythiophene and derivatives thereof, poly(p-phenylenevinylene) and derivatives thereof, poly(2,5-thienylenevinylene) and derivatives thereof, polycarbonate, polyacrylate, polymethyl acrylate, polymethyl methacrylate, polystyrene, polyvinyl chloride and polysiloxane.

The thickness of an electron transporting layer may be advantageously regulated so as to give appropriate light emission efficiency and driving voltage, and is usually 1 nm to 1 μm, preferably 2 nm to 500 nm, further preferably 5 nm to 200 nm.

Among charge transporting layers disposed adjacent to an electrode, those having a function of improving charge injection efficiency from an electrode and having an effect of lowering the driving voltage of a light emitting device are, particularly, called a charge injection layer (hole injection layer, electron injection layer) in some cases.

Further, for improving close adherence with an electrode or improving charge injection from an electrode, a charge injection layer or an insulation layer may be disposed adjacent to the electrode, and for improving close adherence of an interface or preventing mixing and the like, a thin buffer layer may be inserted into an interface of a charge transporting layer and a light emitting layer.

The order and the number of layers to be laminated and the thickness of each layer may be advantageously determined in view of light emission efficiency and device life.

In the present invention, the light emitting device having a charge injection layer includes a light emitting device in which a charge injection layer (electron injection layer) is disposed adjacent to a cathode, and a light emitting device in which a charge injection layer (hole injection layer) is disposed adjacent to an anode.

The structure of the light emitting device of the present invention includes, for example, the following structures e) to p).

e) anode/charge injection layer/light emitting layer/cathode
f) anode/light emitting layer/charge injection layer/cathode
g) anode/charge injection layer/light emitting layer/charge injection layer/cathode
h) anode/charge injection layer/hole transporting layer/light emitting layer/cathode
i) anode/hole transporting layer/light emitting layer/charge injection layer/cathode
j) anode/charge injection layer/hole transporting layer/light emitting layer/charge injection layer/cathode
k) anode/charge injection layer/light emitting layer/charge transporting layer/cathode
l) anode/light emitting layer/electron transporting layer/charge injection layer/cathode
m) anode/charge injection layer/light emitting layer/electron transporting layer/charge injection layer/cathode
n) anode/charge injection layer/hole transporting layer/light emitting layer/charge transporting layer/cathode
o) anode/hole transporting layer/light emitting layer/electron transporting layer/charge injection layer/cathode
p) anode/charge injection layer/hole transporting layer/light emitting layer/electron transporting layer/charge injection layer/cathode

The charge injection layer includes, for example, a layer comprising an electrically conductive polymer, a layer disposed between an anode and a hole transporting layer and having ionization potential of a value between that of an anode material and that of a hole transporting material contained in the hole transporting layer, and a layer disposed between a cathode and an electron transporting layer and having electron affinity of a value between that of a cathode material and that of an electron transporting material contained in the electron transporting layer.

When the charge injection layer is a layer comprising an electrically conductive polymer, the electrically conductive polymer has an electric conductivity of preferably 10⁻⁵ to 10³ S/cm, and for decreasing leak current between light emission picture elements, more preferably 10⁻⁵ to 10² S/cm, further preferably 10⁻⁵ to 10¹ S/cm. Usually, for the electrically conductive polymer to have an electric conductivity in a range of 10⁻⁵ to 10³ S/cm, the electrically conductive polymer is doped with a suitable amount of ions.

The kind of ions to be doped is an anion in the case of a hole injection layer and is a cation in the case of an electron injection layer. The anion includes, for example, a polystyrene-sulfonate ion, an alkylbenzenesulfonate ion and a camphorsulfonate ion, and the cation includes, for example, a lithium ion, a sodium ion, a potassium ion and a tetrabutylammonium ion.

The thickness of the charge injection layer is usually 1 nm to 100 nm, preferably 2 nm to 50 nm.

The material used in the charge injection layer includes, for example, electrically conductive polymers such as polyaniline and derivatives thereof, polythiophene and derivatives thereof, polypyrrole and derivatives thereof, polyphenylenevinylene and derivatives thereof, polythienylenevinylene and derivatives thereof, polyquinoline and derivatives thereof, polyquinoxaline and derivatives thereof, polymers comprising an aromatic amine structure in the main chain or side chain, and the like; metal phthalocyanines (copper phthalocyanine and the like) and carbon.

The insulation layer has a function of making charge injection easy. This insulation layer has an average thickness of usually 0.1 to 20 nm, preferably 0.5 to 10 nm, more preferably 1 to 5 nm. The material of the insulation layer includes, for example, metal fluorides, metal oxides and organic insulation materials. The light emitting device bearing an insulation layer disposed therein includes a light emitting device having an insulation layer disposed adjacent to a cathode and a light emitting device having an insulation layer disposed adjacent to an anode.

The structure of the light emitting device of the present invention includes, for example, the following structures q) to ab).

q) anode/insulation layer/light emitting layer/cathode
r) anode/light emitting layer/insulation layer/cathode
s) anode/insulation layer/light emitting layer/insulation layer/cathode
t) anode/insulation layer/hole transporting layer/light emitting layer/cathode
u) anode/hole transporting layer/light emitting layer/insulation layer/cathode
v) anode/insulation layer/hole transporting layer/light emitting layer/insulation layer/cathode
w) anode/insulation layer/light emitting layer/electron transporting layer/cathode
x) anode/light emitting layer/electron transporting layer/insulation layer/cathode
y) anode/insulation layer/light emitting layer/electron transporting layer/insulation layer/cathode
z) anode/insulation layer/hole transporting layer/light emitting layer/electron transporting layer/cathode
aa) anode/hole transporting layer/light emitting layer/electron transporting layer/insulation layer/cathode
ab) anode/insulation layer/hole transporting layer/light emitting layer/electron transporting layer/insulation layer/cathode

The substrate on which the light emitting device of the present invention is formed may advantageously be one which does not change in forming an electrode and in forming a layer of an organic material, and includes, for example, glass, plastics, polymer films and silicon. In the case of an opaque substrate, it is preferable that the opposite electrode is transparent or semi-transparent.

In the light emitting device of the present invention, at least one of electrodes consisting of an anode and a cathode is usually transparent or semi-transparent, and it is preferable that the anode side is transparent or semi-transparent.

As the anode material, electrically conductive metal oxide films, semi-transparent metal films and the like are used, examples thereof include films (NESA and the like) fabricated by using an electrically conductive inorganic compound composed of indium oxide, zinc oxide, tin oxide, and composite thereof: indium.tin.oxide (ITO), indium.zinc.oxide and the like and films fabricated by using gold, platinum, silver or copper, and preferable are ITO, indium.zinc.oxide and tin oxide. The anode fabrication method includes, for example, a vacuum vapor deposition method, a sputtering method, an ion plating method and a plating method. As the anode, a transparent electrically conductive film made of an organic material such as polyaniline and derivatives thereof, polythiophene and derivatives thereof and the like may be used.

The thickness of the anode is usually 10 nm to 10 μm, preferably 20 nm to 1 μm, further preferably 40 nm to 500 nm, in view of light permeability and electric conductivity.

On the anode, a layer composed of a phthalocyanine derivative, an electrically conductive polymer, carbon and the like or a layer composed of a metal oxide, a metal fluoride, an organic insulation material and the like may be provided for making charge injection easy.

As the cathode material, materials having small work function are preferable, and use is made of metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, and alloys composed of two or more of them, or alloys composed of at least one of them and at least one of gold, silver, platinum, copper, manganese, titanium, cobalt, nickel, tungsten and tin, and graphite and graphite intercalation compounds and the like. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy and a calcium-aluminum alloy. The cathode may take a laminated structure composed of two or more layers.

The thickness of the cathode is usually 10 nm to 10 μm, preferably 20 nm to 1 μm, further preferably 50 nm to 500 nm, in view of electric conductivity and durability.

As the cathode fabrication method, for example, a vacuum vapor deposition method, a sputtering method and a laminate method of thermally compression-bonding a metal film are used. Between a cathode and an organic material layer, a layer composed of an electrically conductive polymer or a layer composed of a metal oxide, a metal fluoride, an organic insulation material and the like may be provided, and after cathode fabrication, a protective layer for protecting a light emitting device may be mounted. For use of a light emitting device stably for a long period of time, it is preferable to mount a protective layer and/or a protective cover, for protecting the light emitting device from external damage.

As the protective layer, a resin, a metal oxide, a metal fluoride, a metal boride and the like can be used. As the protective cover, a glass plate, a plastic plate having the surface on which a treatment for lowering coefficient of water permeability has been performed, and the like can be used, and a method in which the cover is pasted to a device substrate with a thermosetting resin or a photo-curable resin, thereby attaining seal, is suitably used. If a space is maintained using a spacer, it is easy to prevent damage of a device. If this space is filled with an inert gas such as a nitrogen gas, an argon gas and the like, oxidation of a cathode can be prevented, and further, by placing a desiccant such as barium oxide and the like in this space, it becomes easy to suppress moisture adsorbed in a production step from imparting damage to a device. It is preferable to adopt any one or more measures among them.

The light emitting device of the present invention can be used for displays such as a surface light source, a segment display, a dot matrix display, a liquid crystal display (backlight and the like), a flat panel display and the like.

For obtaining planar light emission using the light emitting device of the present invention, it may be advantageous to place a planar anode and a planar cathode so as to overlap. For obtaining light emission in the form of pattern, there are a method in which a mask having a window in the form of pattern is placed on the surface of the above-described planar light emitting device, a method in which an organic material layer at a non-light emitting part is formed with extremely large thickness to give substantially no light emission, and a method in which either an anode or a cathode, or both electrodes are formed in the form of pattern. By forming a pattern by any of these methods, and placing several electrodes so that on/off thereof is independently possible, a display device of segment type is obtained which can display digits, letters, simple marks and the like. Further, for providing a dot matrix display, it may be advantageous that both an anode and a cathode are formed in the form of stripe, and placed so as to cross. By using a method in which several polymer compounds showing different emission colors are painted separately or a method in which a color filter or a fluorescence conversion filter is used, partial color display and multi-color display are made possible. In the case of a dot matrix display, passive driving is possible, and active driving may also be carried out in combination with TFT and the like. These display devices can be used as a display of a computer, a television, a portable terminal, a cellular telephone, a car navigation, a view finder of video camera, and the like.

Further, the above-described planar light emitting device is of self emitting and thin type, and can be suitably used as a surface light source for back light of a liquid crystal display, or as a surface light source for illumination. The light source for illumination includes, for example, emission colors of white, red, green, blue and the like. If a flexible substrate is used, it can also be used as a curved light source or display.

### EXAMPLES

Examples are shown below for illustrating the present invention further in detail, but the present invention is not limited to them.

As number-average molecular weight and weight-average molecular weight, polystyrene-equivalent number-average molecular weight and weight-average molecular weight were measured by size exclusion chromatography (SEC) (manufactured by Shimadzu Corp., trade name: LC-10Avp). SEC using an organic solvent as a mobile phase is called gel permeation chromatography (GPC). The polymer to be measured was dissolved in tetrahydrofuran so as to give a concentration of about 0.5 wt %, and 30 μL of the solution was injected in GPC. As the mobile phase of GPC, tetrahydrofuran was used, and allowed to flow at a flow rate of 0.6 mL/min. As the column, two columns of TSKgel SuperHM-H (manufactured by Tosoh Corp.) and one column of TSKgel SuperH2000 (manufactured by Tosoh Corp.) were serially connected. As the detector, a differential refractive index detector (manufactured by Shimadzu Corp., trade name: RID-10A) was used. Measurement was carried out at 40° C.

Measurement of LC-MS was carried out by the following method. The measurement sample was dissolved in chloroform or tetrahydrofuran so as to give a concentration of about 2 mg/mL, and about 1 μL of the solution was injected in LC-MS (manufactured by Agilent Technologies, trade name: 1100LCMSD). As the mobile phase of LC-MS, acetonitrile and tetrahydrofuran were used while changing the ratio thereof and allowed to flow at a flow rate of 0.2 mL/min, unless otherwise stated. As the column, L-column 2 ODS (3 μm) (manufactured by Chemicals Evaluation and Research Institute, Japan, internal diameter: 2.1 mm, length: 100 mm, particle diameter: 3 μm) was used.

### Synthesis Example 1

### Synthesis of Compound 1-3

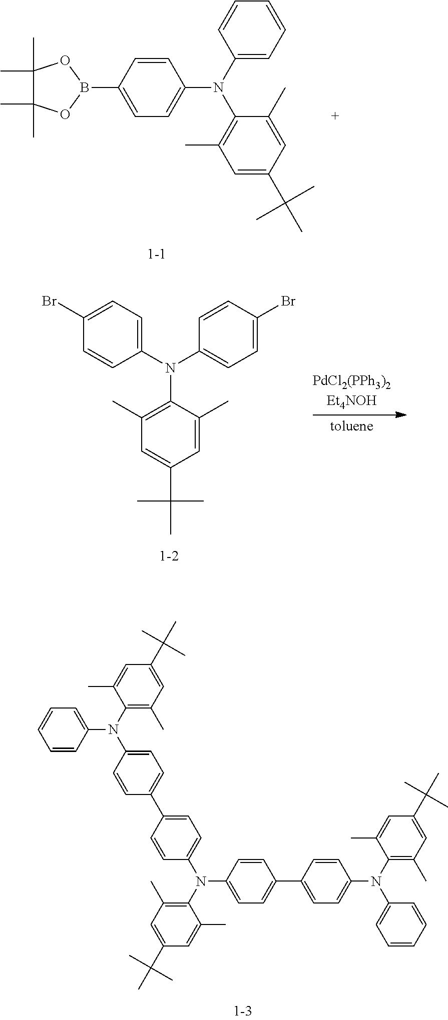 [SMILES: Cc1cc(C(C)(C)C)cc(C)c1N(c1ccccc1)c1ccc(B2OC(C)(C)C(C)(C)O2)cc1 ; Cc1cc(C(C)(C)C)cc(C)c1N(c1ccc(Br)cc1)c1ccc(Br)cc1 ; Cc1cc(C(C)(C)C)cc(C)c1N(c1ccccc1)c1ccc(-c2ccc(N(c3ccc(-c4ccc(N(c5ccccc5)c5c(C)cc(C(C)(C)C)cc5C)cc4)cc3)c3c(C)cc(C(C)(C)C)cc3C)cc2)cc1]

A compound 1-1 was synthesized according to a method described in JP-A No. 2007-321022, and a compound 1-2 was synthesized according to a method described in JP-A No. 2004-143419, respectively.

Next, into a 300 mL three-necked flask under an argon gas atmosphere, the compound 1-1 (10.3 g) and the compound 1-2 (5.00 g) were added, and dissolved in toluene (50.0 mL). Thereafter, to the solution were added bistriphenylphosphinepalladium dichloride (216 mg) and a 20 wt % tetraethylammonium hydroxide aqueous solution (22.7 g), and the mixture was refluxed with heating. After completion of the reaction, the mixture was left to cool, and filtrated through Celite. Further, toluene (200 mL) was added, and the solution was allowed to separate. The resultant organic layer was dried over sodium sulfate, and concentrated to remove the solvent. The resultant product was purified by column chromatography (filler: alumina, developing solvent: hexane:toluene=4:1 (volume ratio)). After distilling off the solvent, re-crystallization was performed from a mixed solvent composed of tetrahydrofuran and methanol, to obtain a compound 1-3 (9.00 g). It was identified as the target compound based on the following data.

¹H-NMR (300 MHz, THF-d₈): δ (ppm)=7.58 (m, 8H), 7.35 (m, 10H), 7.13 (m, 12H), 7.00 (m, 2H), 2.22 (s, 6H), 2.20 (s, 12H), 1.51 (s, 9H), 1.50 (s, 18H).

### Synthesis Example 2

### Synthesis of Compound 1-4

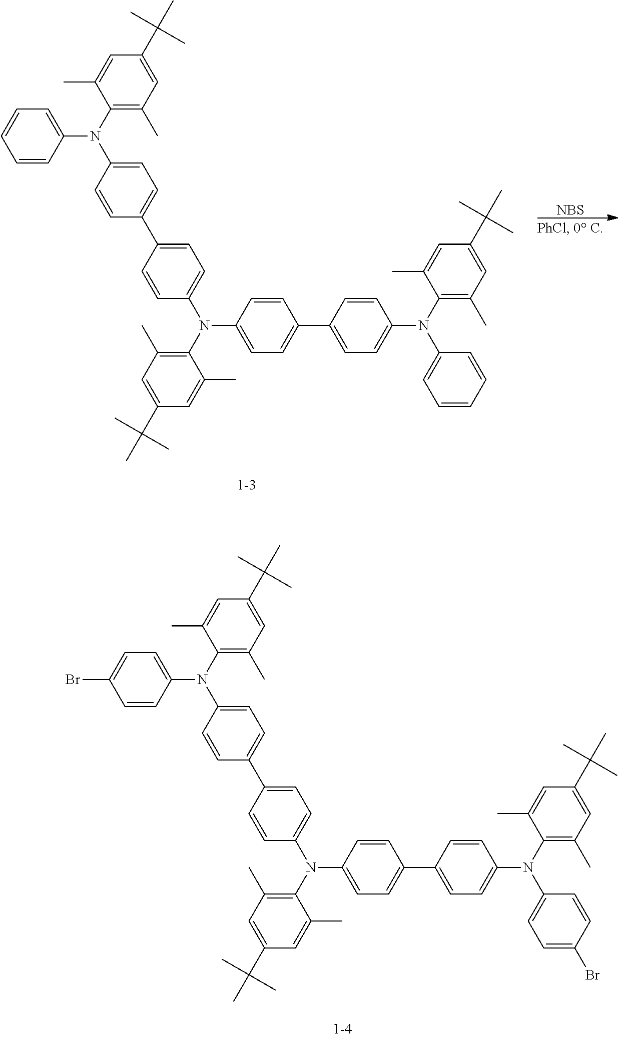

Into a 50 mL three-necked flask under an argon gas atmosphere, the compound 1-3 (8.00 g) was added, and dissolved in chlorobenzene (80.0 mL). Thereafter, the solution was cooled down to 0° C., N-bromosuccinimide (2.89 g) was added, and the mixture was stirred at 0° C. for 5 hours. After completion of the reaction, a saturated sodium thiosulfate aqueous solution (50.0 mL) was added, further, toluene (200 mL) was added, and the solution was allowed to separate. The resultant organic layer was dried over sodium sulfate, and concentrated to remove the solvent. The resultant product was re-crystallized from a mixed solvent composed of tetrahydrofuran and methanol, to obtain a compound 1-4 (4.10 g). It was identified as the target compound based on the following data.

¹H-NMR (300 MHz, THF-d₈): δ (ppm)=7.63-7.57 (m, 8H), 7.46-7.44 (m, 4H), 7.37 (s, 6H), 7.19-7.15 (m, 8H), 7.04-7.02 (m, 4H), 2.22-2.20 (m, 18H), 1.51-1.50 (m, 27H).

LC-MS (APCI, positive): [M+H]⁺ 1140.4

### Synthesis Example 3

### Synthesis of Compound 1-6

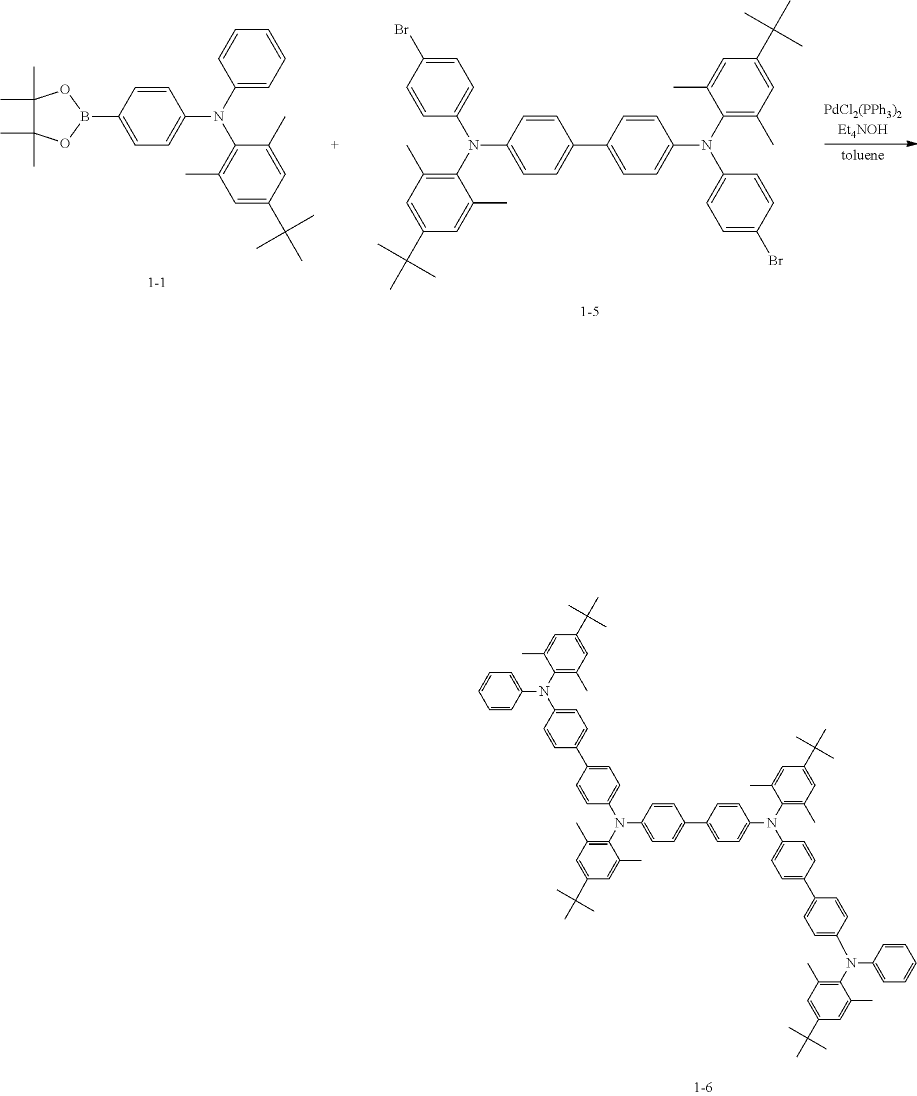 [SMILES: Cc1cc(C(C)(C)C)cc(C)c1N(c1ccccc1)c1ccc(B2OC(C)(C)C(C)(C)O2)cc1 ; Cc1cc(C(C)(C)C)cc(C)c1N(c1ccc(Br)cc1)c1ccc(-c2ccc(N(c3ccc(Br)cc3)c3c(C)cc(C(C)(C)C)cc3C)cc2)cc1 ; Cc1cc(C(C)(C)C)cc(C)c1N(c1ccccc1)c1ccc(-c2ccc(N(c3ccc(-c4ccc(N(c5ccc(-c6ccc(N(c7ccccc7)c7c(C)cc(C(C)(C)C)cc7C)cc6)cc5)c5c(C)cc(C(C)(C)C)cc5C)cc4)cc3)c3c(C)cc(C(C)(C)C)cc3C)cc2)cc1]

A compound 1-5 was synthesized according to a method described in JP-A No. 2004-143419.

Next, into a 300 mL three-necked flask under an argon gas atmosphere, the compound 1-1 (9.47 g) and the compound 1-5 (7.00 g) were added, and dissolved in toluene (70.0 mL). Thereafter, to the solution were added bistriphenylphosphinepalladium dichloride (60.0 mg) and a 20 wt % tetraethylammonium hydroxide aqueous solution (19.0 g), and the mixture was refluxed with heating. After completion of the reaction, the mixture was left to cool, and filtrated through Celite. Further, toluene (200 mL) was added, and the solution was allowed to separate. The resultant organic layer was dried over sodium sulfate, and concentrated to remove the solvent. The resultant product was purified by column chromatography (filler: alumina, developing solvent: hexane:toluene=4:1 (volume ratio)). After distilling off the solvent, re-crystallization was performed from a mixed solvent composed of tetrahydrofuran and methanol, to obtain a compound 1-6 (3.58 g). It was identified as the target compound based on the following data.

¹H-NMR (300 MHz, THF-d₈): δ (ppm)=7.43-7.39 (m, 12H), 7.20-7.13 (m, 12H), 7.02-6.94 (m, 16H), 2.06 (s, 12H), 2.03 (s, 12H), 1.35 (s, 12H), 1.34 (s, 12H).

### Synthesis Example 4

### Synthesis of Compound 1-7

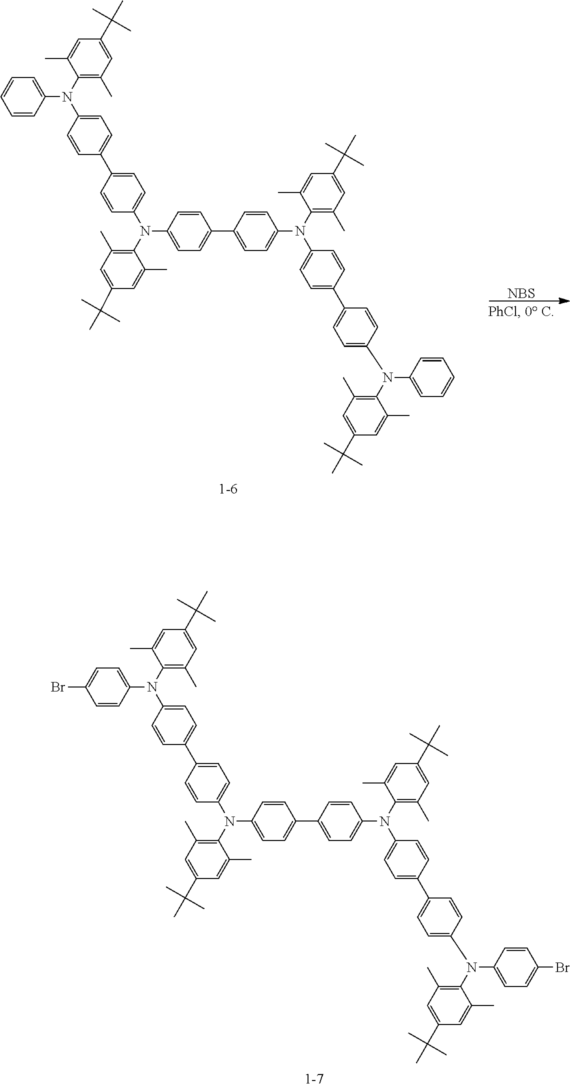 [SMILES: Cc1cc(C(C)(C)C)cc(C)c1N(c1ccccc1)c1ccc(-c2ccc(N(c3ccc(-c4ccc(N(c5ccc(-c6ccc(N(c7ccccc7)c7c(C)cc(C(C)(C)C)cc7C)cc6)cc5)c5c(C)cc(C(C)(C)C)cc5C)cc4)cc3)c3c(C)cc(C(C)(C)C)cc3C)cc2)cc1 ; "NBS" ; Cc1cc(C(C)(C)C)cc(C)c1N(c1ccc(Br)cc1)c1ccc(-c2ccc(N(c3ccc(-c4ccc(N(c5ccc(-c6ccc(N(c7ccc(Br)cc7)c7c(C)cc(C(C)(C)C)cc7C)cc6)cc5)c5c(C)cc(C(C)(C)C)cc5C)cc4)cc3)c3c(C)cc(C(C)(C)C)cc3C)cc2)cc1]

Into a 50 mL three-necked flask under an argon gas atmosphere, the compound 1-6 (3.30 g) was added, and dissolved in chlorobenzene (33.0 mL). Thereafter, the solution was cooled down to 0° C., N-bromosuccinimide (895 mg) was added, and the mixture was stirred at 0° C. for 5 hours. After completion of the reaction, a saturated sodium thiosulfate aqueous solution (30.0 mL) was added, further, toluene (100 mL) was added, and the solution was allowed to separate. The resultant organic layer was dried over sodium sulfate, and concentrated to remove the solvent. The resultant product was re-crystallized from a mixed solvent composed of tetrahydrofuran and methanol, to obtain a compound 1-7 (3.21 g). It was identified as the target compound based on the following data.

¹H-NMR (300 MHz, THF-d₈): δ (ppm)=7.44-7.40 (m, 12H), 7.28 (d, 4H), 7.20 (s, 8H), 7.02-6.98 (m, 12H), 6.86 (d, 4H), 2.06 (s, 12H), 2.03 (s, 12H), 1.35 (s, 12H), 1.34 (s, 12H).

LC-MS (APCI, positive): [M+H]⁺ 1467.6

### Synthesis Example 4a

### Synthesis of Compound 1-11

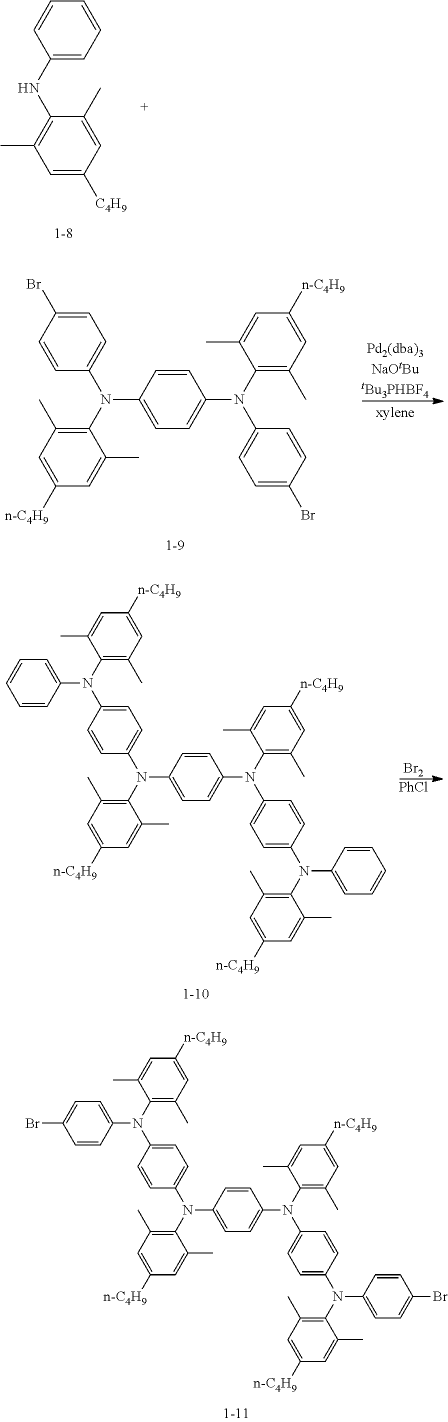

Into a 300 mL three-necked flask under an argon gas atmosphere, a compound 1-8 (9.06 g) and a compound 1-9 (12.0 g) were added, and dissolved in xylene (35.0 mL). Thereafter, to the solution were added tris(dibenzylideneacetone)dipalladium (298 mg), tri(tert-butyl)phosphine tetrafluoroborate salt (377 mg) and tert-butoxysodium (3.90 g), and the mixture was refluxed with heating. After completion of the reaction, the mixture was left to cool, water (30 mL) was added, and the solution was allowed to separate. The resultant aqueous layer was extracted with ethyl acetate (30 mL) three times. The resultant organic layer was dried over sodium sulfate, and concentrated to remove the solvent. The resultant product was purified by column chromatography (filler: hexane, developing solvent: hexane:ethyl acetate=1:0 to 50:1 (volume ratio)). After distilling off the solvent, re-crystallization was performed from a mixed solvent composed of tetrahydrofuran and 2-propanol, to obtain a compound 1-10 (16.2 g).

Next, into a 500 mL three-necked flask under an argon gas atmosphere, the compound 1-10 (15.2 g) was added, and dissolved in chlorobenzene (200 mL). Thereafter, the solution was cooled down to 0° C., a chlorobenzene solution (80.0 mL) of bromine (4.49 g) was dropped over a period of 5 hours, and the mixture was stirred at 0° C. for 4 hours. Thereafter, a chlorobenzene solution (12.0 mL) of bromine (0.63 g) was dropped at 0° C., and the mixture was reacted at 0° C. for 5 hours. After completion of the reaction, a saturated sodium thiosulfate aqueous solution (100 mL) was added, further, toluene (100 mL) was added, and the solution was allowed to separate. The resultant organic layer was dried over magnesium sulfate, and concentrated to remove the solvent. The resultant product was purified by column chromatography (filler: silica gel, developing solvent: hexane:ethyl acetate=10:1 (volume ratio)), to obtain a compound 1-11 (7.90 g).

### Synthesis Example 5

### Synthesis of Compound 1A

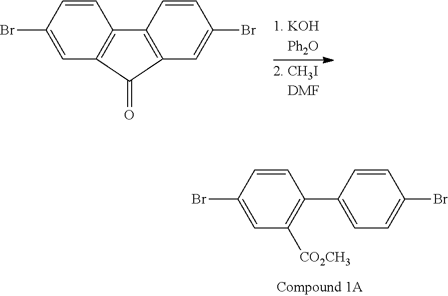 [SMILES: O=C1c2cc(Br)ccc2-c2ccc(Br)cc21 ; COC(=O)c1cc(Br)ccc1-c1ccc(Br)cc1]

A gas in a four-necked flask was purged with a nitrogen gas, then, 2,7-dibromofluorenone (16.5 g) was suspended in diphenyl ether in the flask. The resultant suspension was heated up to 120° C., and 2,7-dibromofluorenone was dissolved therein, then, to the resultant solution was added potassium hydroxide (15.5 g), the mixture was heated up to 160° C., and stirred for 2.5 hours. Thereafter, the solution was left to cool to room temperature, then, hexane was added, and the solution was filtrated, and the resultant solid was washed with hexane. Next, a gas in a separate four-necked flask was purged with a nitrogen gas, then, the product obtained above was dissolved in dehydrated N,N-dimethylformamide (hereinafter, referred to as “DMF”). Thereafter, the solution was heated up to 90° C., and methyl iodide (53.0 g) was added while following the reaction. The reaction time was 10 hours in total. Thereafter, the solution was left to cool to room temperature, dropped into water cooled to 0° C., and the reaction product was extracted with hexane twice. Thereafter, the product was filtrated through a glass filter paved with silica gel, then, concentrated. The resultant concentrate was purified by silica gel column chromatography, to obtain a compound 1A (13.3 g). It was identified as the target compound based on the following data.

¹H-NMR (300 MHz/CDCl₃): δ (ppm)=3.68 (s, 3H), 7.15 (d, 2H), 7.20 (d, 1H), 7.52 (d, 2H), 7.65 (d, 1H), 8.00 (brs, 1H).

### Synthesis Example 6

### Synthesis of Compound 1B

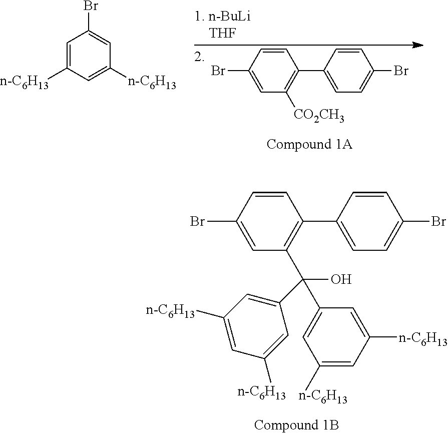

A gas in a reaction vessel was purged with an argon gas atmosphere, then, 1-bromo-3,5-di-n-hexylbenzene (20.0 g) and tetrahydrofuran were added, a homogeneous solution was prepared, and cooled down to −70° C. Thereafter, a 2.76 M n-butyllithium/hexane solution (1 molar equivalent with respect to 1-bromo-3,5-di-n-hexylbenzene) was dropped into the solution at −70° C. over a period of 1.5 hours, and further, the solution was stirred at −70° C. for 1.5 hours. Thereafter, a solution composed of the compound 1A (9.0 g) and tetrahydrofuran was dropped at −70° C. over a period of 1 hour, and the mixture was stirred at −70° C. for 2 hours. Thereafter, methanol and distilled water were added to the solution at −70° C. and the mixture was stirred, then, heated up to room temperature, and stirred at room temperature overnight. The resultant reaction mixture was filtrated, the resultant filtrate was concentrated, heptane and water were added and the mixture was stirred, and allowed to stand still to cause liquid separation, and the aqueous layer was removed from the oil layer. To the resultant oil layer was added saturated saline and the mixture was stirred, and allowed to stand still to cause liquid separation, and the aqueous layer was removed from the oil layer. To the resultant oil layer was added magnesium sulfate and the mixture was stirred, and filtrated to obtain a filtrate which was then concentrated, to obtain a compound 1B.

### Synthesis Example 7

### Synthesis of Compound 2B

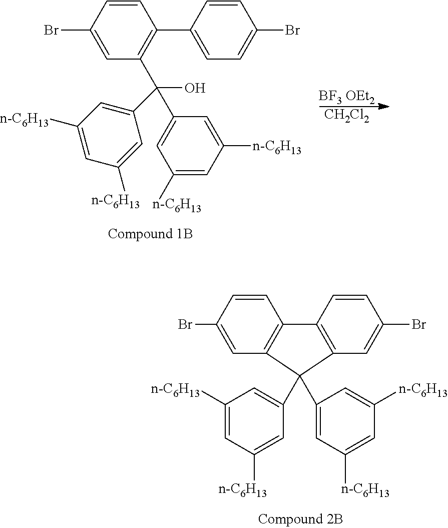

A gas in a reaction vessel was purged with an argon gas flow, then, the compound 1B (23.4 g) and dichloromethane were added, a homogeneous solution was prepared, and cooled down to −30° C. Thereafter, a boron trifluoride-diethyl ether complex (1 molar equivalent with respect to the compound 1B) was dropped into the solution at −30° C. over a period of 30 minutes, and the mixture was stirred at room temperature overnight. Thereafter, the reaction solution was cooled down to −20° C., distilled water was added, and the mixture was stirred for 1 hour, then, allowed to stand still to cause liquid separation, and the aqueous layer was removed from the oil layer. Thereafter, water was added and the mixture was stirred, and allowed to stand still to cause liquid separation, and the aqueous layer was removed from the oil layer. To the resultant oil layer was added a 10 wt % sodium hydrogen carbonate aqueous solution and the mixture was stirred, and allowed to stand still to cause liquid separation, and the aqueous layer was removed from the oil layer. The resultant oil layer was concentrated to remove the solvent. Thereafter, the oil layer was purified by silica gel column chromatography using a mixed solvent composed of toluene and heptane as a developing solvent, and concentrated to remove the solvent. Thereafter, re-crystallization was performed from a mixed solvent composed of butyl acetate and methanol, to obtain the target compound 2B (11.3 g). It was identified as the target compound based on the following data.

¹H-NMR (300 MHz/CDCl₃): δ (ppm)=0.85 (t, 12H), 1.25 (m, 24H), 1.50 (m, 8H), 2.46 (t, 8H), 6.72 (s, 4H), 6.86 (s, 2H), 7.45 (dd, 2H), 7.46 (d, 2H), 7.54 (d, 2H).

### Synthesis Example 8

### Synthesis of Compound 3B

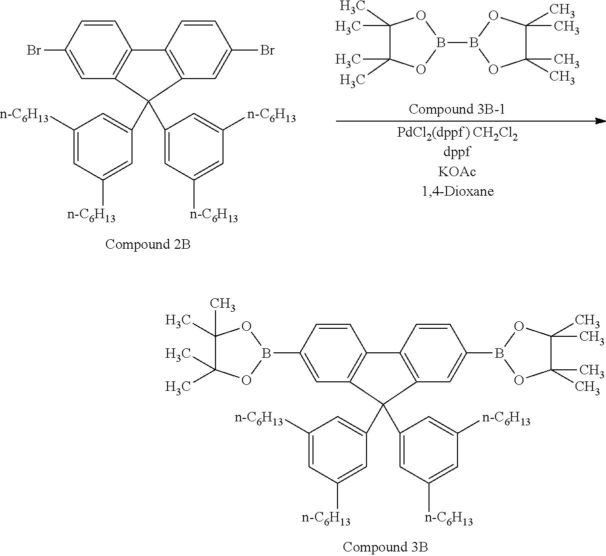

A gas in a reaction vessel was purged with an argon gas atmosphere, then, the compound 2B (9.5 g), a compound 3B-1 (6.6 g), 1,4-dioxane, potassium acetate (7.1 g), 1,1′-bis(diphenylphosphino)ferrocene (dppf, 0.1 g) and 1,1′-bis(diphenylphosphino)ferrocenedichloropalladium(II)-methylene chloride complex (PdCl₂(dppf).CH₂Cl₂, 0.15 g) were added, and the mixture was stirred at 100° C. for 5 hours. Thereafter, the resultant reaction mixture was cooled down to room temperature, then, filtrated through a filter paved with Celite and silica gel, and the resultant filtrate was concentrated to remove the solvent. Thereafter, hexane was added to prepare a solution to which activated carbon was added, and the mixture was stirred for 1 hour at a temperature for reflux of hexane. Thereafter, the mixture was cooled down to room temperature, filtrated through a filter paved with Celite, and concentrated to remove the solvent. Thereafter, re-crystallization was performed from a mixed solvent composed of toluene and acetonitrile, to obtain a target compound 3B (10.1 g). It was identified as the target compound based on the following data.

¹H-NMR (300 MHz/CDCl₃): δ (ppm)=0.85 (t, 12H), 1.27 (m, 46H), 1.48 (m, 8H), 2.43 (t, 8H), 6.81 (s, 6H), 7.79 (m, 6H).

### Synthesis Example 9

### Synthesis of Compound 1C

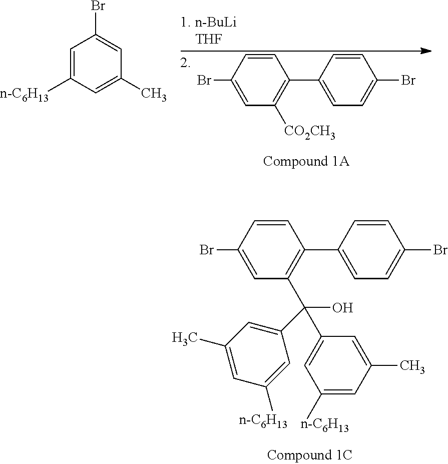

A gas in a three-necked flask was purged with an inert gas atmosphere, then, 3-n-hexyl-5-methylbromobenzene (26.2 g) and anhydrous tetrahydrofuran were added, a homogeneous solution was prepared, and cooled down to −70° C. Thereafter, a 2.5 M n-butyllithium/hexane solution (0.93 molar equivalent with respect to 3-n-hexyl-5-methylbromobenzene) was dropped into the resultant solution so that the temperature of the solution was kept at −70° C., and the mixture was stirred at the same temperature for 4 hours, to prepare a solution (hereinafter, referred to as “solution A”).

Separately, into a two-necked flask were added 2-methoxycarbonyl-4,4′-dibromobiphenyl (16.0 g) and anhydrous tetrahydrofuran, to prepare a solution (hereinafter, referred to as “solution B”).

The solution B was dropped into the solution A so that the temperature of the solution A was kept at −70° C., and the mixture was stirred. Thereafter, the reaction solution was stirred at room temperature for 15 hours. Thereafter, water was added to the reaction solution and the mixture was stirred. Thereafter, the solvent was distilled off by a concentration operation under reduced pressure, hexane and water were added to the resultant residue, and the mixture was stirred and allowed to stand still, and the generated aqueous layer was removed to obtain an oil layer. The resultant oil layer was washed with saturated saline, dried over anhydrous magnesium sulfate, then, concentrated under reduced pressure, to obtain a compound 1C as a white solid.

### Synthesis Example 10

### Synthesis of Compound 2C

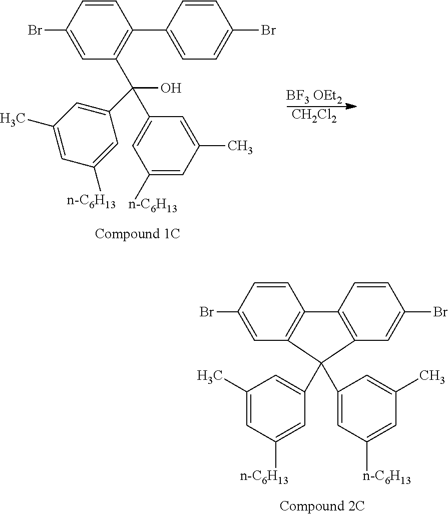

A gas in a reaction vessel was purged with an argon gas atmosphere, then, the compound 1C (30.0 g) and anhydrous dichloromethane were added, and cooled down to 5° C. A boron trifluoride-diethyl ether complex (4.2 molar equivalent with respect to the compound 1C) was dropped into the resultant mixture so that the temperature was maintained in the range of 0 to 5° C., then, the mixture was stirred at room temperature overnight. Thereafter, the reaction solution was poured into ice water carefully, the mixture was stirred for 30 minutes, and allowed to stand still to cause liquid separation, and the aqueous layer was removed from the oil layer. To the resultant oil layer was added a 10 wt % potassium phosphate aqueous solution, the mixture was stirred for 2 hours, then, allowed to stand still, and the generated aqueous layer was removed from an oil layer. The resultant oil layer was washed with water, dried over anhydrous magnesium sulfate, then, concentrated to distill off the solvent, to obtain an oily liquid. To the resultant oily liquid was added methanol, to obtain a solid. The resultant solid was re-crystallized from a mixed solvent composed of n-butyl acetate and methanol, to obtain a compound 2C (24.0 g). It was identified as the target compound based on the following data.

¹H-NMR (300 MHz/CDCl₃): δ (ppm)=0.91 (t, 6H), 1.31 (m, 12H), 1.56 (m, 4H), 2.24 (s, 6H), 2.52 (t, 4H), 6.68 (s, 2H), 6.89 (d, 4H), 7.47 (d, 1H), 7.50 (d, 1H), 7.52 (d, 2H), 7.59 (d, 2H).

### Synthesis Example 11

### Synthesis of Compound 3C

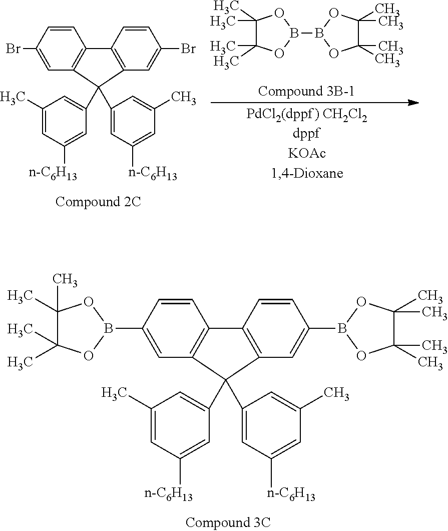

A gas in a reaction vessel was purged with an argon gas atmosphere, then, the compound 2C (8.0 g), the compound 3B-(6.6 g), 1,1′-bis(diphenylphosphino)ferrocenedichloropalladium(II)-methylene chloride complex (Pd(dppf).CH₂Cl₂, 0.15 g), 1,1′-bis(diphenylphosphino)ferrocene (0.10 g), anhydrous 1,4-dioxane and potassium acetate (7.0 g) were added, and stirred at 100° C. for 20 hours. The resultant reaction solution was cooled down to room temperature, then, allowed to pass through silica gel, the silica gel was washed with toluene, and the solvent of the resultant solution was distilled off by concentration, to obtain a brown liquid. The resultant liquid was purified by silica gel column chromatography using hexane as a developing solvent, then, concentrated. To the resultant concentrated liquid was added acetonitrile, to obtain a solid. The resultant solid was re-crystallized once from a mixed solvent composed of dichloromethane and methanol, then, dried under reduced pressure, a compound 3C (2.9 g). It was identified as the target compound based on the following data.

¹H-NMR (300 MHz/CDCl₃): δ (ppm)=0.86 (t, 6H), 1.28 (m, 36H), 1.51 (m, 4H), 2.15 (s, 6H), 2.46 (t, 4H), 6.66 (s, 2H), 6.81 (s, 2H), 6.97 (s, 2H), 7.80 (m, 6H).

### Synthesis Example 12

### Synthesis of Hole Transportable Polymer Compound 1

A gas in a reaction vessel was purged with a nitrogen gas atmosphere, then, the above-described compound 3B (17.1 g, 18.8 mmol), a compound represented by the following formula (10.4 g, 11.5 mmol) synthesized according to a method described in WO2005/049548,

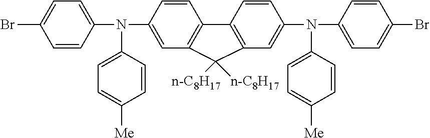

a compound represented by the following formula (2.62 g, 4.78 mmol),

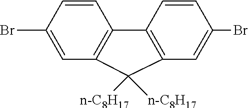

a compound represented by the following formula (1.51 g, 2.87 mmol) synthesized according to a method described in JP-A No. 2008-106241,

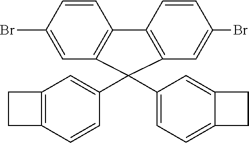 [SMILES: Brc1ccc2c(c1)C(c1ccc3c(c1)CC3)(c1ccc3c(c1)CC3)c1cc(Br)ccc1-2]

palladium acetate (4.30 mg), tri(o-anisyl)phosphine (30.0 mg) and toluene (478 mL) were mixed, and the mixture was heated at 100° C. A 20 wt % tetraethylammonium hydroxide aqueous solution (67.5 g) was dropped into the solution, and the mixture was refluxed for 4.5 hours. After the reaction, to this were added phenylboronic acid (233 mg) and dichlorobis(triphenylphosphine)palladium (13.4 mg), and the mixture was further refluxed for 14 hours. Thereafter, to this was added a sodium diethyldithiocarbamate aqueous solution, and the mixture was stirred at 80° C. for 2 hours. After cooling, the mixture was washed with water (334 mL) twice, with a 3 wt % acetic acid aqueous solution (334 mL) twice and with water (334 mL) twice in this order, the resultant solution was dropped into methanol (3.87 L), and the precipitated material was isolated by filtration. The resultant precipitated material was dissolved in toluene (788 mL), and the solution was purified by allowing it to pass through an alumina column and a silica gel column in series. The resultant solution was dropped into methanol (3.87 L), and the mixture was stirred, then, the resultant precipitated material was isolated by filtration and dried, to obtain a hole transportable polymer compound 1 (14.9 g).

The hole transportable polymer compound 1 had a polystyrene-equivalent number-average molecular weight of 7.8×10⁴ and a polystyrene-equivalent weight-average molecular weight of 3.4×10⁵.

The hole transportable polymer compound 1 is a copolymer comprising repetitions of a repeating unit represented by the following formula:

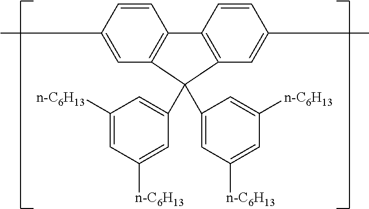

a repeating unit represented by the following formula:

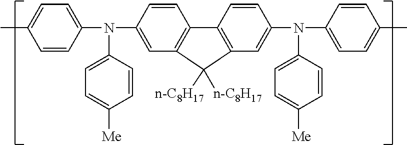

a repeating unit represented by the following formula:

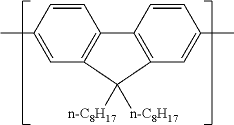

and a repeating unit represented by the following formula:

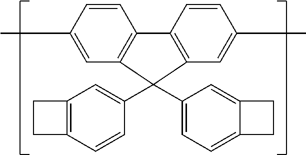

at a molar ratio of 50:30:12.5:7.5, according to the theoretical value calculated from the amounts of the charged raw materials.

### Synthesis Example 13

### Synthesis of Conjugated Polymer Compound 1

A gas in a reaction vessel was purged with a nitrogen gas atmosphere, then, the above-described compound 3C (13.4 g, 17.5 mmol), a compound represented by the following formula (3.70 g, 6.98 mmol),

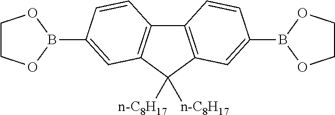

a compound represented by the following formula (16.1 g, 24.9 mmol) synthesized according to a method described in JP-A No. 2010-215886,

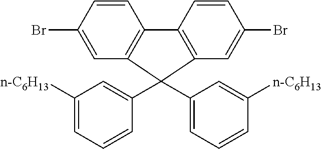

dichlorobis(triphenylphosphine)palladium (17.5 mg) and toluene (478 mL) were mixed, and the mixture was heated at 100° C. A 20 wt % tetraethylammonium hydroxide aqueous solution (83.7 g) was dropped into the solution, and the mixture was refluxed for 4.5 hours. After the reaction, to this were added phenylboronic acid (300 mg) and dichlorobis(triphenylphosphine)palladium (17.5 mg), and the mixture was further refluxed for 14 hours. Thereafter, to this was added a sodium diethyldithiocarbamate aqueous solution, and the mixture was stirred at 80° C. for 2 hours. After cooling, the mixture was washed with water (324 mL) twice, with a 3 wt % acetic acid aqueous solution (324 mL) twice and with water (324 mL) twice in this order, the resultant solution was dropped into methanol (3.87 L), and the precipitated material was isolated by filtration. The resultant precipitated material was dissolved in toluene (778 mL), and the solution was purified by allowing it to pass through an alumina column and a silica gel column in series. The resultant solution was dropped into methanol (3.87 L), and the mixture was stirred, then, the resultant precipitated material was isolated by filtration and dried, to obtain a conjugated polymer compound 1 (14.8 g). The conjugated polymer compound 1 had a polystyrene-equivalent number-average molecular weight of 6.1×10⁴ and a polystyrene-equivalent weight-average molecular weight of 2.1×10⁵.

The conjugated polymer compound 1 is a copolymer comprising repetitions of a repeating unit represented by the following formula:

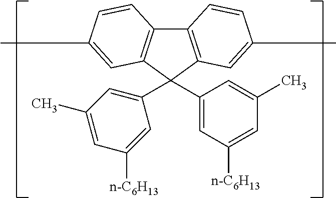

a repeating unit represented by the following formula:

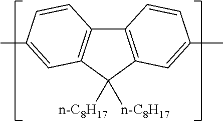

and a repeating unit represented by the following formula:

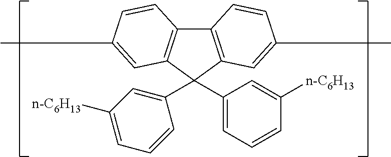

at a molar ratio of 36:14:50, according to the theoretical value calculated from the amounts of the charged raw materials.

### Example 1

### Synthesis of Polymer Compound P-1

A gas in a reaction vessel was purged with a nitrogen gas atmosphere, then, 2,7-bis(1,3,2-dioxaborolan-2-yl)-9,9-dioctylfluorene (1.08 g), the compound 1-4 (1.94 g), palladium acetate (0.62 mg), tris(o-anisyl)phosphine (3.65 mg), 1-hexene (10.3 mg) and toluene (48.0 mL) were mixed and the mixture was heated at 105° C. A 20 wt % tetraethylammonium hydroxide aqueous solution (5.70 mL) was dropped into the solution, and the mixture was refluxed for 2.5 hours. After the reaction, to this was added phenylboronic acid (20.7 mg), and the mixture was further refluxed for 18 hours. Thereafter, sodium diethyldithiocarbamate (0.94 g) and water (19.0 mL) were added, and the mixture was stirred at 80° C. for 4 hours. After cooling to room temperature, the mixture was washed with water (22.0 mL), with a 3 wt % acetic acid aqueous solution (22.0 mL) and with water (22.0 mL) in this order. The resultant toluene solution was dropped into methanol (300 mL), the mixture was stirred for 1 hour, then, the resultant solid was isolated by filtration, and dried under reduced pressure. Further, the solid was purified by allowing it to pass through an alumina column and a silica gel column. The resultant toluene solution was dropped into methanol (300 mL), the mixture was stirred for 1 hour, then, the resultant solid was isolated by filtration and dried, to obtain a polymer compound P-1 (1.59 g). The polymer compound P-1 had a polystyrene-equivalent number-average molecular weight of 4.0×10⁴ and a polystyrene-equivalent weight-average molecular weight of 1.7×10⁵.

The conjugated polymer compound P-1 is an alternative copolymer comprising repetitions of a repeating unit represented by the following formula:

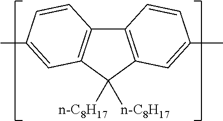

and a repeating unit represented by the following formula:

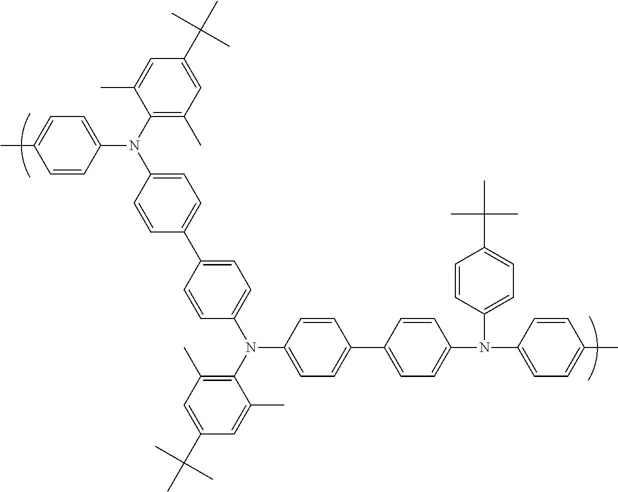

at a molar ratio of 50:50, according to the theoretical value calculated from the amounts of the charged raw materials.

### Example 2

### Synthesis of Polymer Compound P-2

A gas in a reaction vessel was purged with a nitrogen gas atmosphere, then, 2,7-bis(1,3,2-dioxaborolan-2-yl)-9,9-dioctylfluorene (0.71 g), the compound 1-7 (1.98 g), bistriphenylphosphinepalladium dichloride (1.0 mg), trioctylmethylammonium chloride (manufactured by Aldrich, trade name: Aliquat336) (0.20 g) and toluene (30.0 mL) were mixed and the mixture was heated at 105° C. A 2M sodium carbonate aqueous solution (3.00 mL) was dropped into the solution, and the mixture was refluxed for 7 hours. After the reaction, to this was added phenylboronic acid (0.20 g), and the mixture was further refluxed for 16 hours. Thereafter, sodium diethyldithiocarbamate (0.30 g) and water (5.00 mL) were added, and the mixture was stirred at 80° C. for 4 hours. After cooling to room temperature, the mixture was washed with water (17.0 mL), with a 3 wt % acetic acid aqueous solution (17.0 mL) and with water (17.0 mL). The resultant toluene solution was dropped into methanol (400 mL), the mixture was stirred for 1 hour, then, the resultant solid was isolated by filtration, and dried under reduced pressure. Further, the solid was purified by allowing it to pass through an alumina column and a silica gel column. The resultant toluene solution was dropped into methanol (400 mL), the mixture was stirred for 1 hour, then, the resultant solid was isolated by filtration and dried, to obtain a polymer compound P-2 (2.02 g). The polymer compound P-2 had a polystyrene-equivalent number-average molecular weight of 1.2×10⁴ and a polystyrene-equivalent weight-average molecular weight of 3.8×10⁴.

The conjugated polymer compound P-2 is an alternative copolymer comprising repetitions of a repeating unit represented by the following formula:

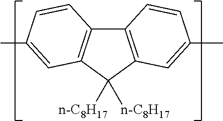

and a repeating unit represented by the following formula:

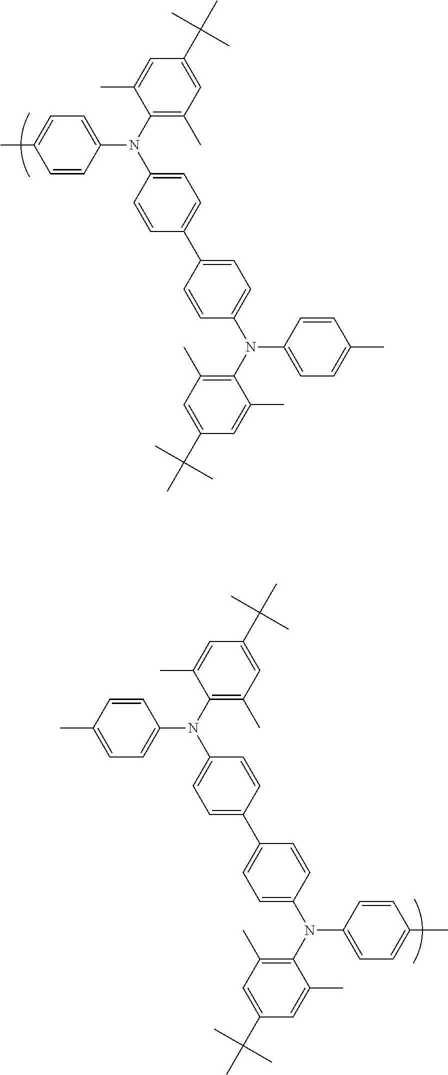

at a molar ratio of 50:50, according to the theoretical value calculated from the amounts of the charged raw materials.

### Example 3

### Synthesis of Polymer Compound P-3

A gas in a reaction vessel was purged with a nitrogen gas atmosphere, then, the above-described compound 3C (1.09 g, 1.42 mmol), a compound represented by the following formula (0.36 g, 0.56 mmol),

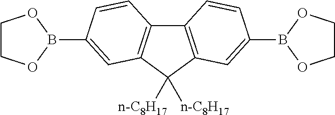

a compound represented by the following formula (1.04 g, 1.60 mmol) synthesized according to a method described in JP-A No. 2010-215886,

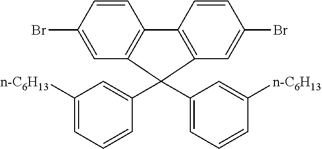

the above-described compound 1-7 (0.59 g, 0.40 mmol), dichlorobis(triphenylphosphine)palladium (1.4 mg) and toluene (50 mL) were mixed, and the mixture was heated at 100° C. A 20 wt % tetraethylammonium hydroxide aqueous solution (6.6 mL) was dropped into the reaction solution, and the mixture was refluxed for 4.5 hours. After the reaction, to this were added phenylboronic acid (24.9 mg) and dichlorobis(triphenylphosphine)palladium (1.4 mg), and the mixture was further refluxed for 14 hours. Thereafter, to this was added a sodium diethyldithiocarbamate aqueous solution, and the mixture was stirred at 80° C. for 2 hours. After cooling, the mixture was washed with water (26 mL) twice, with a 3 wt % acetic acid aqueous solution (26 mL) twice and with water (26 mL), the resultant solution was dropped into methanol (311 mL), and the precipitated material was isolated by filtration. The resultant precipitated material was dissolved in toluene (73 mL), and the solution was purified by allowing it to pass through an alumina column and a silica gel column in series. The resultant solution was dropped into methanol (327 mL), and the mixture was stirred, then, the resultant precipitated material was isolated by filtration and dried, to obtain a polymer compound P-3 (0.72 g). The polymer compound P-3 had a polystyrene-equivalent number-average molecular weight of 1.1×10⁵ and a polystyrene-equivalent weight-average molecular weight of 3.8×10⁵.

The polymer compound P-3 is a copolymer constituted of a repeating unit represented by the following formula:

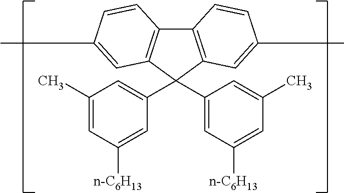

a repeating unit represented by the following formula:

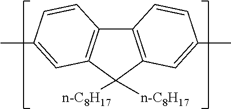

a repeating unit represented by the following formula:

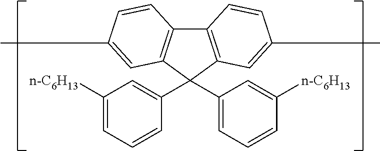

and a repeating unit represented by the following formula:

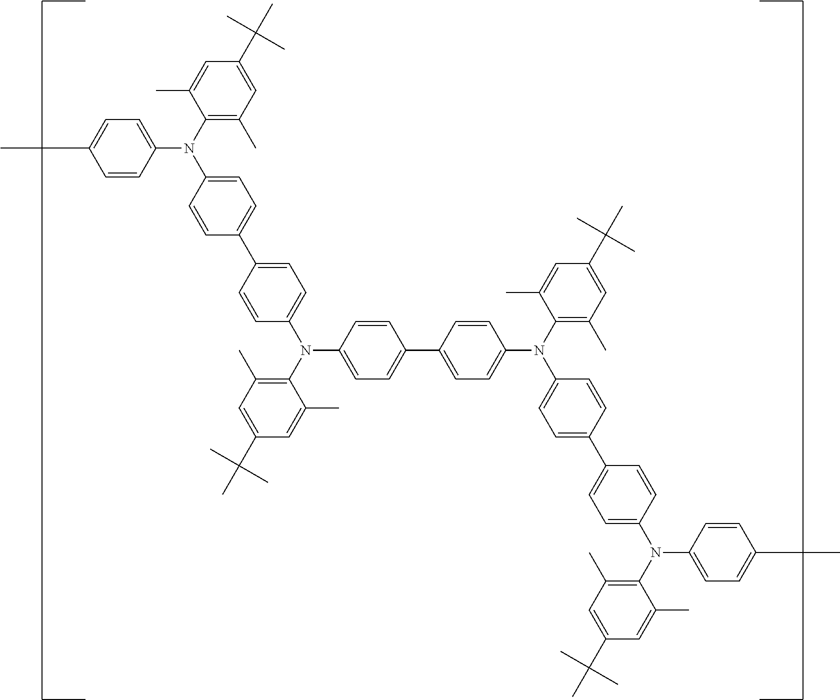

at a molar ratio of 36:14:40:10, according to the theoretical value calculated from the amounts of the charged raw materials.

### Comparative Example 1

### Synthesis of Polymer Compound CP-1

A gas in a reaction vessel was purged with a nitrogen gas atmosphere, then, a compound represented by the following formula (0.42 g),

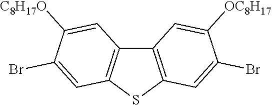

a compound represented by the following formula (0.27 g),

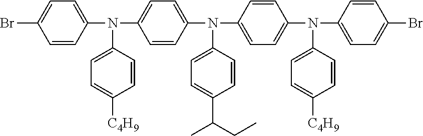

and 2,2′-bipyridyl (0.39 g) were dissolved in dehydrated tetrahydrofuran (28.0 ml), then, bubbling with a nitrogen gas was further performed to purge a gas in the reaction vessel with a nitrogen gas. Thereafter, to this solution was added bis(1,5-cyclooctadiene)nickel(0) {Ni(COD)₂} (0.69 g), the mixture was heated up to 60° C., and reacted for 3 hours while stirring. After the reaction, this reaction liquid was cooled down to room temperature (25° C.), dropped into a mixed solution of 25 wt % ammonia water (14 mL)/methanol (about 170 mL)/ion exchanged water (about 70 mL), and the mixture was stirred for 1 hour, then, the deposited precipitate was filtrated and dried under reduced pressure for 2 hours, and dissolved in toluene (40 mL). Thereafter, 40 mL of 1M hydrochloric acid was added and the mixture was stirred for 1 hour, the aqueous layer was removed to obtain an organic layer to which 2 wt % ammonia water (40 mL) was added, and the mixture was stirred for 1 hour, then, the aqueous layer was removed. To the resultant organic layer was added ion exchanged water (40 mL) and the mixture was stirred, then, the aqueous layer was removed. The resultant organic layer was dropped into methanol (200 mL) to cause precipitation, and this precipitate was collected and dried under reduced pressure, to obtain a solid. Thereafter, the resultant solid was dissolved in toluene (40 mL), and purified by allowing it to pass through an alumina column, and the recovered toluene solution was dropped into methanol (280 mL) and the mixture was stirred for 1 hour, and the deposited precipitate was filtrated and dried under reduced pressure for 2 hours, to obtain a polymer compound CP-1 (0.40 g). The polymer compound C-1 had a polystyrene-equivalent number-average molecular weight of 1.9×10⁴ and a polystyrene-equivalent weight-average molecular weight of 6.4×10⁴.

The polymer compound CP-1 is a random copolymer comprising a repeating unit represented by the following formula:

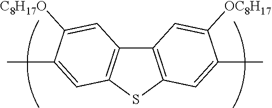

and a repeating unit represented by the following formula:

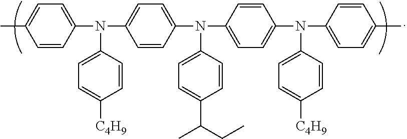

### Example 4

### Fabrication of Light Emitting Device 1

A solution of the conjugated polymer compound 1 dissolved at a concentration of 1.3 wt % in a xylene solvent (manufactured by Kanto Chemical Co., Inc., for electronic industry (EL grade)) and a solution of the polymer compound P-1 dissolved at a concentration of 1.3 wt % in a xylene solvent were mixed at a weight ratio of 90:10 (molar ratio of 95:5), to prepare a solution of a light emitting material 1.

On a glass substrate carrying thereon an ITO film with a thickness of 45 nm formed by a sputtering method, a solution of poly(3,4)ethylenedioxythiophene/polystyrenesulfonic acid (manufactured by H. C. Starck, trade name: CLEVIOS P AI4083) was spin-coated to form a film with a thickness of 35 nm, which was then dried on a hot plate at 200° C. for 10 minutes. Next, the hole transportable polymer compound 1 was spin-coated in the form of a 0.7 wt % xylene solution, to form a film with a thickness of about 20 nm. This was thermally treated on a hot plate at 180° C. for 60 minutes under a nitrogen gas atmosphere in which both the oxygen concentration and the moisture concentration were 10 ppm or less (by weight). Next, the light emitting material 1 was spin-coated in the form of a 1.3 wt % xylene solution, to form a film with a thickness of about 60 nm. This was dried on a hot plate at 130° C. for 10 minutes under a nitrogen gas atmosphere in which both the oxygen concentration and the moisture concentration were 10 ppm or less (by weight). After the degree of vacuum reached 1×10⁻⁴ Pa or less, sodium fluoride was vapor-deposited with a thickness of about 3 nm, then, aluminum was vapor-deposited with a thickness of about 80 nm on the sodium fluoride layer, as a cathode. After vapor deposition, it was sealed using a glass substrate to fabricate a light emitting device 1.

When voltage was applied to the resultant light emitting device 1, electroluminescence (EL) of blue light emission was observed. The device started light emission from 2.6 V, the light emission efficiency at a luminance of 1000 cd/m² was 4.3 cd/A, the voltage under this state was 3.8 V, and the light emission chromaticity under this state was (0.16, 0.13).

The light emitting device 1 obtained above was, after setting the current density so that the initial luminance was 1000 cd/m², driven at constant current density and the time change of luminance was measured. As a result, the luminance reduced to half after 282 hours. The results are described in Table 2.

### Example 5

### Fabrication of Light Emitting Device 2

A light emitting device 2 was fabricated in the same manner as in Example 4, excepting that the conjugated polymer compound 1 and the polymer compound P-1 in Example 4 were mixed at a weight ratio of 93.3:6.7 (molar ratio 97:3) to prepare a solution of a light emitting material 2.

When voltage was applied to the resultant light emitting device 2, electroluminescence (EL) of blue light emission was observed. The device started light emission from 2.6 V, the light emission efficiency at a luminance of 1000 cd/m² was 4.3 cd/A, the voltage under this state was 3.9 V, and the light emission chromaticity under this state was (0.16, 0.13).

The light emitting device 2 obtained above was, after setting the current density so that the initial luminance was 1000 cd/m², driven at constant current density and the time change of luminance was measured. As a result, the luminance reduced to half after 296 hours. The results are described in Table 2.

### Example 6

### Fabrication of Light Emitting Device 3

A light emitting device 3 was fabricated in the same manner as in Example 4, excepting that the polymer compound P-1 in Example 4 was changed to the polymer compound P-2, and the conjugated polymer compound 1 and the polymer compound P-2 were mixed at a weight ratio of 90:10 (molar ratio 96:4) to prepare a solution of a light emitting material 3.

When voltage was applied to the resultant light emitting device 3, electroluminescence (EL) of blue light emission was observed. The device started light emission from 2.6 V, the light emission efficiency at a luminance of 1000 cd/m² was 4.3 cd/A, the voltage under this state was 3.7 V, and the light emission chromaticity under this state was (0.16, 0.14).

The light emitting device 3 obtained above was, after setting the current density so that the initial luminance was 1000 cd/m², driven at constant current density and the time change of luminance was measured. As a result, the luminance reduced to half after 373 hours. The results are described in Table 2.

### Example 7

### Fabrication of Light Emitting Device 4

A light emitting device 4 was fabricated in the same manner as in Example 4, excepting that the polymer compound P-1 in Example 4 was changed to the polymer compound P-2, and the conjugated polymer compound 1 and the polymer compound P-2 were mixed at a weight ratio of 95:5 (molar ratio 98:2) to prepare a solution of a light emitting material 4.

When voltage was applied to the resultant light emitting device 4, electroluminescence (EL) of blue light emission was observed. The device started light emission from 2.6 V, the light emission efficiency at a luminance of 1000 cd/m² was 4.3 cd/A, the voltage under this state was 4.0 V, and the light emission chromaticity under this state was (0.16, 0.15).

The light emitting device 4 obtained above was, after setting the current density so that the initial luminance was 1000 cd/m², driven at constant current density and the time change of luminance was measured. As a result, the luminance reduced to half after 338 hours. The results are described in Table 2.

### Example 8

### Fabrication of Light Emitting Device 5

A light emitting device 5 was fabricated in the same manner as in Example 4, excepting that the polymer compound P-1 in Example 4 was changed to the polymer compound P-3, and the conjugated polymer compound 1 and the polymer compound P-3 were mixed at a weight ratio of 50:50 (molar ratio 56:44) to prepare a solution of a light emitting material 5.

When voltage was applied to the resultant light emitting device 5, electroluminescence (EL) of blue light emission was observed. The device started light emission from 2.6 V, the light emission efficiency at a luminance of 1000 cd/m² was 5.0 cd/A, the voltage under this state was 3.6 V, and the light emission chromaticity under this state was (0.15, 0.12).

The light emitting device 5 obtained above was, after setting the current density so that the initial luminance was 1000 cd/m², driven at constant current density and the time change of luminance was measured. As a result, the luminance reduced to half after 305 hours. The results are described in Table 2.

### Comparative Example 2

### Fabrication of Light Emitting device C1

A solution of the conjugated polymer compound 1 dissolved at a concentration of 1.3 wt % in a xylene solvent (manufactured by Kanto Chemical Co., Inc., for electronic industry (EL grade)) and a solution of the polymer compound CP-1 dissolved at a concentration of 1.3 wt % in a xylene solvent were mixed at a weight ratio of 83.3:16.7, to prepare a solution of a light emitting material C1.

On a glass substrate carrying thereon an ITO film with a thickness of 45 nm formed by a sputtering method, a solution of poly(3,4)ethylenedioxythiophene/polystyrenesulfonic acid (manufactured by H. C. Starck, trade name: CLEVIOS P AI4083) was spin-coated to form a film with a thickness of 35 nm, which was then dried on a hot plate at 200° C. for 10 minutes. Next, the hole transportable polymer compound 1 was spin-coated in the form of a 0.7 wt % xylene solution, to form a film with a thickness of about 20 nm. This was thermally treated on a hot plate at 180° C. for 60 minutes under a nitrogen gas atmosphere in which both the oxygen concentration and the moisture concentration were 10 ppm or less (by weight). Next, the light emitting material C1 was spin-coated in the form of a 1.3 wt % xylene solution, to form a film with a thickness of about 60 nm. This was dried on a hot plate at 130° C. for 10 minutes under a nitrogen gas atmosphere in which both the oxygen concentration and the moisture concentration were 10 ppm or less (by weight). After the degree of vacuum reached 1×10⁻⁴ Pa or less, sodium fluoride was vapor-deposited with a thickness of about 3 nm, then, aluminum was vapor-deposited with a thickness of about 80 nm on the sodium fluoride layer, as a cathode. After vapor deposition, it was sealed using a glass substrate, to fabricate a light emitting device C1.

When voltage was applied to the resultant light emitting device C1, electroluminescence (EL) of blue light emission was observed. The device started light emission from 2.6 V, the light emission efficiency at a luminance of 1000 cd/m² was 4.3 cd/A, the voltage under this state was 3.7 V, and the light emission chromaticity under this state was (0.16, 0.13).

The light emitting device C1 obtained above was, after setting the current density so that the initial luminance was 1000 cd/m², driven at constant current density and the time change of luminance was measured. As a result, the luminance reduced to half after 120 hours. The results are described in Table 2.

### Comparative Example 3

### Fabrication of Light Emitting Device C2

A light emitting device C2 was fabricated in the same manner as in Comparative Example 2, excepting that the conjugated polymer compound 1 and the polymer compound CP-1 in Comparative Example 2 were mixed at a weight ratio of 90:10 to prepare a solution of a light emitting material C2.

When voltage was applied to the resultant light emitting device C2, electroluminescence (EL) of blue light emission was observed. The device started light emission from 2.7 V, the light emission efficiency at a luminance of 1000 cd/m² was 4.4 cd/A, the voltage under this state was 3.8 V, and the light emission chromaticity under this state was (0.15, 0.13).

The light emitting device C2 obtained above was, after setting the current density so that the initial luminance was 1000 cd/m², driven at constant current density and the time change of luminance was measured. As a result, the luminance reduced to half after 90 hours. The results are described in Table 2.

TABLE 2

| | Light emitting layer | | 1000 cm/m² |
|---|---|---|---|
| | | Composition ratio | Luminance half |
| | Polymer compound | (weight ratio) | life (hr) |
| Example 4 | Conjugated polymer | 90/10 | 282 |
| | compound 1/polymer | | |
| | compound P-1 | | |
| Example 5 | Conjugated polymer | 93.3/6.7 | 296 |
| | compound 1/polymer | | |
| | compound P-1 | | |
| Example 6 | Conjugated polymer | 90/10 | 373 |
| | compound 1/polymer | | |
| | compound P-2 | | |
| Example 7 | Conjugated polymer | 95/5 | 338 |
| | compound 1/polymer | | |
| | compound P-2 | | |
| Example 8 | Conjugated polymer | 50/50 | 305 |
| | compound 1/polymer | | |
| | compound P-3 | | |
| Comparative | Conjugated polymer | 83.3/16.7 | 120 |
| Example 2 | compound 1/polymer | | |
| | compound CP-1 | | |
| Comparative | Conjugated polymer | 90/10 | 90 |
| Example 3 | compound 1/polymer | | |
| | compound CP-1 | | |

### Example 9

### Synthesis of Polymer Compound P-4

A gas in a reaction vessel was purged with a nitrogen gas atmosphere, then, a compound represented by the following formula (1.35 g, 2.00 mmol),

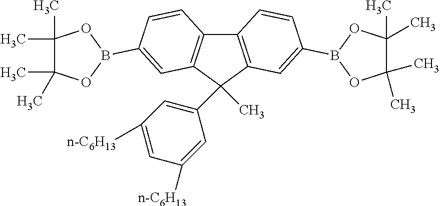

a compound represented by the following formula (0.96 g, 1.60 mmol),

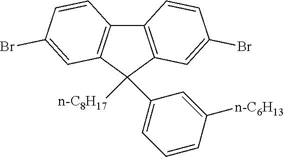

the above-described compound 1-11 (0.50 g, 0.40 mmol), dichlorobis(triphenylphosphine)palladium (1.77 mg) and toluene (50 mL) were mixed, and the mixture was heated at 100° C. A 20 wt % tetraethylammonium hydroxide aqueous solution (6.6 mL) was dropped into the reaction solution, and the mixture was refluxed for 5.5 hours. After the reaction, to this were added phenylboronic acid (26.2 mg) and dichlorobis(triphenylphosphine)palladium (1.8 mg), and the mixture was further refluxed for 12 hours. Thereafter, to this was added a sodium diethyldithiocarbamate aqueous solution, and the mixture was stirred at 85° C. for 2 hours. After cooling, the mixture was washed with water (26 mL) twice, with a 3 wt % acetic acid aqueous solution (26 mL) twice, and with water (26 mL) twice in this order, and the resultant solution was dropped into methanol (311 mL), and the precipitated material was isolated by filtration. The resultant precipitated material was dissolved in toluene (93 mL), and the solution was purified by allowing it to pass through an alumina column and a silica gel column in series. The resultant solution was dropped into methanol (400 mL), and the mixture was stirred, then, the resultant precipitated material was isolated by filtration and dried, to obtain a polymer compound P-4 (1.66 g). The polymer compound P-4 had a polystyrene-equivalent number-average molecular weight of 5.6×10⁴ and a polystyrene-equivalent weight-average molecular weight of 3.1×10⁵.

The polymer compound P-4 is a copolymer constituted of a repeating unit represented by the following formula:

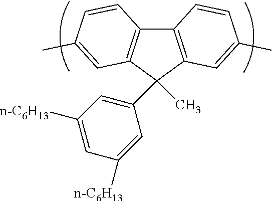

a repeating unit represented by the following formula:

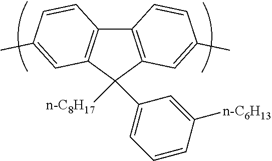

and a repeating unit represented by the following formula:

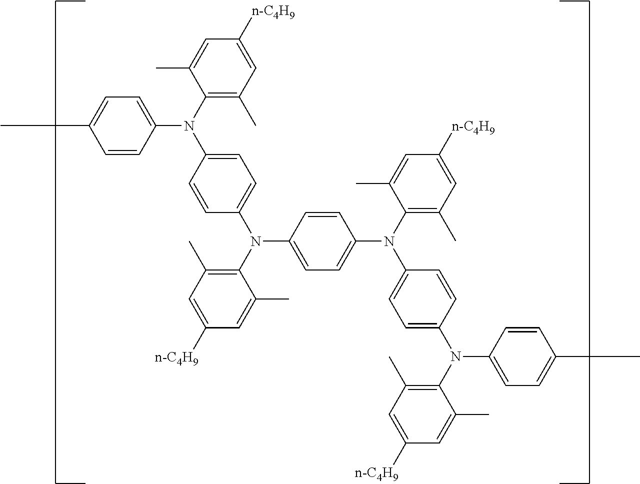

at a molar ratio of 50:40:10, according to the theoretical value calculated from the amounts of the charged raw materials.

### Synthesis Example 15

### Synthesis of Conjugated Polymer Compound 2

A gas in a reaction vessel was purged with an inert gas atmosphere, then, a compound represented by the following formula (3.1502 g, 5.94 mmol),

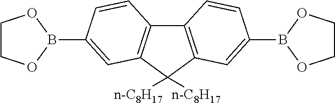

a compound represented by the following formula (2.9615 g, 5.40 mmol),

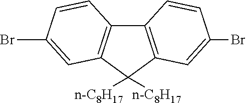

a compound represented by the following formula (0.4431 g, 0.60 mmol),

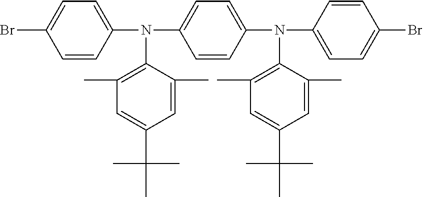 [SMILES: Cc1cc(C(C)(C)C)cc(C)c1N(c1ccc(Br)cc1)c1ccc(N(c2ccc(Br)cc2)c2c(C)cc(C(C)(C)C)cc2C)cc1]

dichlorobis(triphenylphosphine)palladium (4.3 mg), trioctylmethylammonium chloride (trade name: Aliquat 336 (manufactured by Aldrich), 0.79 g) and toluene (60 ml) were mixed and the mixture was heated at 105° C. Thereafter, a 2M sodium carbonate aqueous solution (16.3 ml) was dropped into the reaction solution, and the mixture was refluxed for 3 hours and 10 minutes. After the reaction, to this were added phenylboronic acid (73 mg), dichlorobis(triphenylphosphine)palladium (4.1 mg) and toluene (60 mL), and the mixture was further refluxed for 15.5 hours. Thereafter, to this was added a sodium diethyldithiacarbamate aqueous solution, and the mixture was stirred at 80° C. for 2 hours. After cooling, the mixture was washed with water (78 ml) twice, with a 3 wt % acetic acid aqueous solution (78 ml) twice and with water (78 ml) twice, and the resultant solution was dropped into methanol (1500 mL), and the precipitated material was isolated by filtration. The resultant precipitated material was dissolved in toluene (190 mL), and the solution was purified by allowing it to pass through an alumina column and a silica gel column in series. The resultant solution was dropped into methanol (930 ml), and the mixture was stirred, then, the resultant precipitated material was isolated by filtration and dried, to obtain 3.61 g of a conjugated polymer compound 2. The conjugated polymer compound 2 had a polystyrene-equivalent number-average molecular weight of 1.0×10⁵ and a polystyrene-equivalent weight-average molecular weight of 2.3×10⁵.

The conjugated polymer compound 2 is a copolymer constituted of a constitutional unit represented by the following formula:

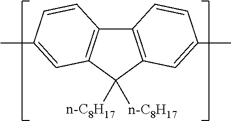

and a constitutional unit represented by the following formula:

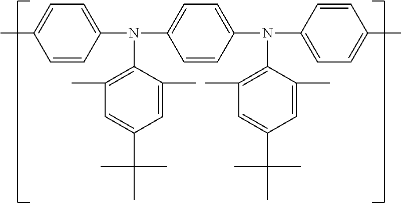

at a molar ratio of 95:5, according to the theoretical value calculated from the amounts of the charged raw materials.

### Example 10

### Fabrication of Light Emitting Device 6

A light emitting device 6 was fabricated in the same manner as in Example 4, excepting that the polymer compound P-1 in Example 4 was changed to the polymer compound P-4, and the conjugated polymer compound 1 and the polymer compound P-4 were mixed at a weight ratio of 50:50 (molar ratio 51:49) to prepare a solution of a light emitting material 6.

When voltage was applied to the resultant light emitting device 6, electroluminescence (EL) of blue light emission was observed. The device started light emission from 2.4 V, the light emission efficiency at a luminance of 1000 cd/m² was 2.4 cd/A, and the voltage under this state was 4.1 V.

The light emitting device 6 obtained above was, after setting the current density so that the initial luminance was 1000 cd/m², driven at constant current density and the time change of luminance was measured. As a result, the luminance reduced to 70% of the initial luminance after 79 hours. The results are described in Table 3.

### Example 11

### Fabrication of Light Emitting Device 7

A light emitting device 7 was fabricated in the same manner as in Example 4, excepting that the polymer compound P-1 in Example 4 was changed to the polymer compound P-4, and the conjugated polymer compound 1 and the polymer compound P-4 were mixed at a weight ratio of 75:25 (molar ratio 75:25) to prepare a solution of a light emitting material 7.

When voltage was applied to the resultant light emitting device 7, electroluminescence (EL) of blue light emission was observed. The device started light emission from 2.4 V, the light emission efficiency at a luminance of 1000 cd/m² was 2.4 cd/A, and the voltage under this state was 4.1 V.

The light emitting device 7 obtained above was, after setting the current density so that the initial luminance was 1000 cd/m², driven at constant current density and the time change of luminance was measured. As a result, the luminance reduced to 70% of the initial luminance after 57 hours. The results are described in Table 3.

### Comparative Example 4

### Fabrication of Light Emitting Device C3

The conjugated polymer compound 2 was dissolved at a concentration of 1.3 wt % in a xylene solvent (manufactured by Kanto Chemical Co., Inc., for electronic industry (EL grade)), to prepare a solution of a light emitting material C3.

On a glass substrate carrying thereon an ITO film with a thickness of 45 nm formed by a sputtering method, a solution of poly(3,4)ethylenedioxythiophene/polystyrenesulfonic acid (manufactured by H. C. Starck, trade name: CLEVIOS P AI4083) was spin-coated to form a film with a thickness of 35 nm, which was then dried on a hot plate at 200° C. for 10 minutes. Next, the hole transportable polymer compound 1 was spin-coated in the form of a 0.7 wt % xylene solution, to form a film with a thickness of about 20 nm. This was thermally treated on a hot plate at 180° C. for 60 minutes under a nitrogen gas atmosphere in which both the oxygen concentration and the moisture concentration were 10 ppm or less (by weight). Next, the light emitting material C3 was spin-coated in the form of a 1.3 wt % xylene solution, to form a film with a thickness of about 60 nm. This was dried on a hot plate at 130° C. for 10 minutes under a nitrogen gas atmosphere in which both the oxygen concentration and the moisture concentration were 10 ppm or less (by weight). After the degree of vacuum reached 1×10⁻⁴ Pa or less, sodium fluoride was vapor-deposited with a thickness of about 3 nm, then, aluminum was vapor-deposited with a thickness of about 80 nm on the sodium fluoride layer, as a cathode. After vapor deposition, it was sealed using a glass substrate, to fabricate a light emitting device C3.

When voltage was applied to the resultant light emitting device C3, electroluminescence (EL) of blue light emission was observed. The device started light emission from 2.6 V, the light emission efficiency at a luminance of 1000 cd/m² was 5.2 cd/A, and the voltage under this state was 4.0 V.

The light emitting device C3 obtained above was, after setting the current density so that the initial luminance was 1000 cd/m², driven at constant current density and the time change of luminance was measured. As a result, the luminance reduced to 70% of the initial luminance after 12 hours. The results are described in Table 3.

TABLE 3

| | | | 1000 cd/m² | | |
|---|---|---|---|---|---|
| | | | | | Lumi- |
| | Light emitting layer | | Light | | nance |
| | | Compo- | emission | Volt- | life |
| | | sition | efficiency | age | (*1) |
| | Polymer compound | ratio | (cd/A) | (V) | (hr) |
| Example 10 | Conjugated polymer | 50/50 | 2.4 | 4.1 | 79 |
| | compound 1/ | | | | |
| | polymer compound | | | | |
| | P-4 | | | | |
| Example 11 | Conjugated polymer | 75/25 | 2.4 | 4.1 | 57 |
| | compound 1/ | | | | |
| | polymer compound | | | | |
| | P-4 | | | | |
| Comparative | Conjugated polymer | 100 | 5.2 | 4.0 | 12 |
| Example 4 | compound 2 | | | | |

(*1): time necessary for reducing to 70% of the initial luminance

### Example 12

### Synthesis of Polymer Compound P-5

A gas in a reaction vessel was purged with a nitrogen gas atmosphere, then, the above-described compound 3B (1.792 g, 1.98 mmol), the above-described compound 1-11 (1.490 g, 1.20 mmol), a compound represented by the following formula (0.274 g, 0.50 mmol),

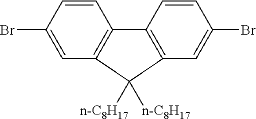

a compound represented by the following formula (0.158 g, 0.30 mmol),

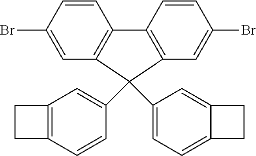 [SMILES: Brc1ccc2c(c1)C(c1ccc3c(c1)CC3)(c1ccc3c(c1)CC3)c1cc(Br)ccc1-2]

dichlorobis(tris(o-methoxyphenyl))phosphinepalladium (1.77 mg) and toluene (47 mL) were mixed, and the mixture was heated at 100° C. Thereafter, a 20 wt % tetraethylammonium hydroxide aqueous solution (6.6 mL) was dropped into the solution, and the mixture was refluxed overnight. After the reaction, to this were added phenylboronic acid (24 mg) and dichlorobis(tris(o-methoxyphenyl))phosphinepalladium (1.77 mg), and the mixture was further refluxed for 14 hours. Thereafter, to this was added a sodium diethyldithiocarbamate aqueous solution, and the mixture was stirred at 80° C. for 2 hours. After cooling, the mixture was washed with water (26 mL) twice, with a 3 wt % acetic acid aqueous solution (26 mL) twice, and with water (26 mL) twice in this order, and the resultant solution was dropped into methanol (311 mL), and the precipitated material was isolated by filtration. This precipitated material was dissolved in toluene (63 mL), and the solution was purified by allowing it to pass through an alumina column and a silica gel column in series. The resultant solution was dropped into methanol (327 mL), and the mixture was stirred, then, the resultant precipitated material was isolated by filtration and dried, to obtain a, polymer compound P-5 (2.35 g). The polymer compound P-5 had a polystyrene-equivalent number-average molecular weight of 3.0×10⁴ and a polystyrene-equivalent weight-average molecular weight of 1.2×10⁵.

The polymer compound P-5 is a copolymer comprising repetitions of a repeating unit represented by the following formula:

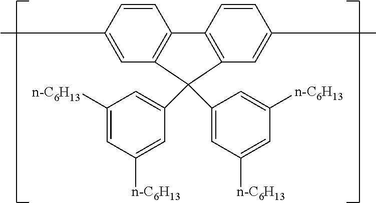

a repeating unit represented by the following formula:

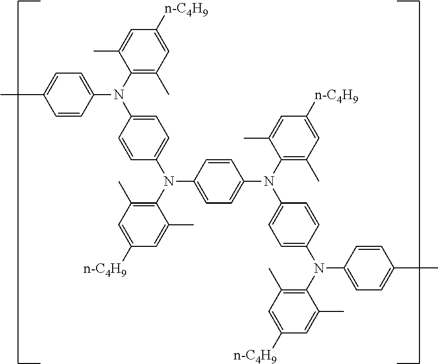

a repeating unit represented by the following formula:

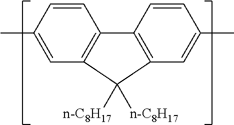

and a repeating unit represented by the following formula:

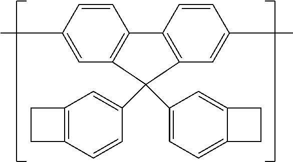

at a molar ratio of 50:30:12.5:7.5, according to the theoretical value calculated from the amounts of the charged raw materials.

### Example 13

### Fabrication of Light Emitting Device 8

On a glass substrate carrying thereon an ITO film with a thickness of 45 nm formed by a sputtering method, a solution of poly(3,4)ethylenedioxythiophene/polystyrenesulfonic acid (manufactured by H. C. Starck, trade name: CLEVIOS P AI4083) was spin-coated to form a film with a thickness of 35 nm, which was then dried on a hot plate at 200° C. for 10 minutes. Next, the polymer compound P-5 was spin-coated in the form of a 0.7 wt % xylene solution, to form a film with a thickness of about 20 nm. This was thermally treated on a hot plate at 180° C. for 60 minutes under a nitrogen gas atmosphere in which both the oxygen concentration and the moisture concentration were 10 ppm or less (by weight). Next, the conjugated polymer compound 2 was spin-coated in the form of a 1.3 wt % xylene solution, to form a film with a thickness of about 60 nm. This was dried on a hot plate at 130° C. for 10 minutes under a nitrogen gas atmosphere in which both the oxygen concentration and the moisture concentration were 10 ppm or less (by weight). After the degree of vacuum reached 1×10⁻⁴ Pa or less, sodium fluoride was vapor-deposited with a thickness of about 3 nm, then, aluminum was vapor-deposited with a thickness of about 80 nm on the sodium fluoride layer, as a cathode. After vapor deposition, it was sealed using a glass substrate, to fabricate a light emitting device 8.

When voltage was applied to the resultant light emitting device 8, the device started light emission from 2.9 V, and electroluminescence (EL) of blue light emission was observed.

The light emitting device 8 obtained above was, after setting the current density so that the initial luminance was 1000 cd/m², driven at constant current density and the time change of luminance was measured. As a result, the luminance reduced to 80% of the initial luminance after 9 hours. The results are described in Table 4.

### Comparative Example 5

### Fabrication of Light Emitting Device C4

A light emitting device C4 was fabricated in the same manner as in Example 13, excepting that the polymer compound P-5 in Example 13 was changed to the hole transportable polymer compound 1.

When voltage was applied to the resultant light emitting device C4, the device started light emission from 2.6 V, and electroluminescence (EL) of blue light emission was observed.

The light emitting device C4 obtained above was, after setting the current density so that the initial luminance was 1000 cd/m², driven at constant current density and the time change of luminance was measured. As a result, the luminance reduced to 80% of the initial luminance after 3 hours. The results are described in Table 4.

TABLE 4

| | | 1000 cd/m² |
|---|---|---|
| | Hole transporting layer | Luminance life (*2) |
| | Polymer compound | (hr) |
| Example 13 | Polymer compound P-5 | 9 |
| Comparative | Hole transportable | 3 |
| Example 5 | polymer compound 1 | |

(*2): time necessary for reducing to 80% of the initial luminance

### INDUSTRIAL APPLICABILITY

According to the polymer compound of the present invention, a light emitting device having sufficiently long luminance life (particularly, luminance half life) can be provided. Therefore, a light emitting device having a film comprising the polymer compound of the present invention can be helpfully used for a dot matrix flat panel display, a segment type display device, a curved or surface light source for illumination, back light of a liquid crystal display, and the like.

1. A polymer compound comprising a repeating unit represented by the formula (1): 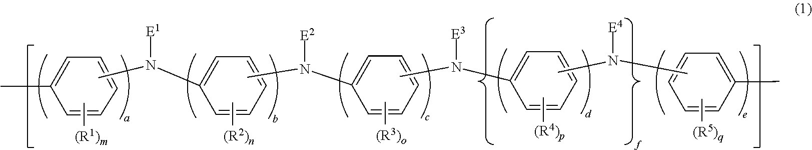
wherein,
E¹, E², E³ and E⁴ represent each independently an aryl group, a mono-valent heterocyclic group or a group represented by the formula (2), and these groups may have a substituent, and when there are a plurality of E⁴, these may be the same or different, 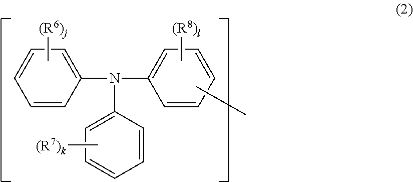
R¹, R², R³, R⁴, R⁵, R⁶, R⁷ and R⁸ represent each independently a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent, and when there are a plurality of R¹, R², R³, R⁴, R⁵, R⁶, R⁷ and R⁸, these may be the same or different, respectively,
a, b, c, d and e represent each independently 1 or 2, and f represents an integer of 0 to 3, and when f=0, then, 5≦a+b+c+e≦8 and at least one of b and c is 2, and when there are a plurality of d, these may be the same or different,
m, n, o, p, q and l represent each independently an integer of 0 to 4, and when there are a plurality of m, n, o, p and q, these may be the same or different, respectively, and
j and k represent each independently an integer of 0 to 5.

2. The polymer compound according to claim 1, further comprising a repeating unit represented by the formula (3):
Ar¹³ (3)
wherein,
Ar¹³ represents an arylene group, a di-valent heterocyclic group or a di-valent group having a metal complex structure, and these groups may have a substituent.

3. The polymer compound according to claim 2, wherein the repeating unit represented by said formula (3) is a repeating unit represented by the formula (3′): 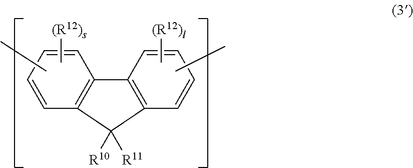
wherein,
R¹⁰ and R¹¹ represent each independently a hydrogen atom, an alkyl group, an aryl group, an arylalkyl group or a mono-valent heterocyclic group, and these groups may have a substituent, and R¹⁰ and R¹¹ may be mutually linked to form a ring,
R¹² represents a halogen atoms, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent, and when there are a plurality of R¹², these may be the same or different, and
s and t represent each independently an integer of 0 to 3.

4. The polymer compound according to claim 3, wherein at least one of R¹⁰ and R¹¹ is an alkyl group, an aryl group or an arylalkyl group, in said formula (3′).

5. The polymer compound according to claim 4, wherein R¹⁰ is an alkyl group and R¹¹ is an aryl group or an arylalkyl group, in said formula (3′).

6. The polymer compound according to claim 2, wherein the repeating unit represented by said formula (3) is a repeating unit represented by the formula (4): 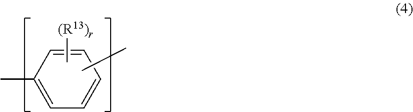
wherein,
R¹³ represents a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imine residue, a substituted amino group, a substituted silyl group, a substituted silyloxy group, a substituted silylthio group, a substituted silylamino group, a mono-valent heterocyclic group, a heteroaryloxy group, a heteroarylthio group, an arylalkenyl group, an arylalkynyl group, a substituted carboxyl group or a cyano group, and these groups may have a substituent, and when there are a plurality of R¹³, these may be the same or different, and
r represents an integer of 0 to 4.

7. The polymer compound according to claim 1, wherein E¹, E², E³ and E⁴ represent an aryl group, in said formula (1).

8. The polymer compound according to claim 1, wherein f=0 or f=1, in said formula (1).

9. The polymer compound according to claim 1, wherein all of m, n, o, p and q are 0, in said formula (1).

10. The polymer compound according to claim 3, wherein the proportion of the total number of moles of a repeating unit represented by said formula (1) and a repeating unit represented by said formula (3′) with respect to the total number of moles of all repeating units of the polymer compound is 0.7 to 1.0.

11. The polymer compound according to claim 1, further comprising at least one of a repeating unit represented by the formula (2A) and a repeating unit represented by the formula (3A): 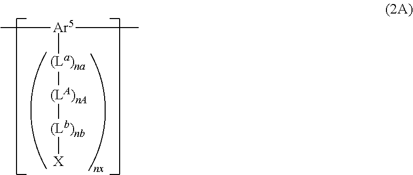
wherein,
na represents an integer of 0 to 3, nb represents an integer of 0 to 12, nA is 0 or 1 and nx represents an integer of 1 to 4,
Ar⁵ represents a (2+nx)-valent aromatic hydrocarbon group or a (2+nx)-valent heterocyclic group, and these groups may have a substituent,
L^{a} and L^{b} represent each independently an alkylene group or a phenylene group, and these groups may have a substituent, and when there are a plurality of L^{a}, these may be the same or different, and when there are a plurality of L^{b}, these may be the same or different,
L^{A} represents an oxygen atom or a sulfur atom, and when there are a plurality of L^{A}, these may be the same or different,
X represents a mono-valent cross-linkable group, and when there are a plurality of X, these may be the same or different, 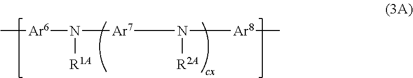
wherein,
cx represents 0 or 1,
Ar⁶ and Ar⁸ represent each independently an arylene group or a di-valent heterocyclic group, and these groups may have a substituent,
Ar⁷ represents an arylene group, a di-valent heterocyclic group or a di-valent group obtained by linking two or more identical or different groups selected from arylene groups and di-valent heterocyclic groups, and these groups may have a substituent,
R^{1A} represents a mono-valent cross-linkable group, and
R^{2A} represents a mono-valent cross-linkable group, an alkyl group, an aryl group or a mono-valent heterocyclic group, and these groups may have a substituent.

12. A composition comprising the polymer compound according to claim 1, and at least one material selected from the group consisting of hole transporting materials, electron transporting materials and light emitting materials.

13. A composition comprising the polymer compound according to claim 11, and at least one material selected from the group consisting of hole transporting materials, electron transporting materials and light emitting materials.

14. A composition comprising the polymer compound according to claim 1, and a solvent.

15. A composition comprising the polymer compound according to claim 11, and a solvent.

16. A film comprising the polymer compound according to claim 1.

17. A film comprising the polymer compound according to claim 11.

18. A film obtained by cross-linking the polymer compound according to claim 11.

19. A light emitting device having the film according to claim 16.

20. The light emitting device according to claim 19, wherein the film is a hole transporting layer.

21. The light emitting device according to claim 19, wherein the film is a light emitting layer.

22. A surface light source having the light emitting device according to claim 19.

23. A display having the light emitting device according to claim 19.
